(19) United States
(12) Patent Application Publication
(10) Pub. No.: US 2025/0246875 A1
(43) Pub. Date: Jul. 31, 2025

(54) CIRCUIT AND SYSTEM FOR DRIVING INTEGRATED SEMICONDUCTOR LASER DEVICE

(71) Applicant: Monolithic Power Systems, Inc., Kirkland, WA (US)

(72) Inventors: Zheng Luo, San Jose, CA (US); Yiming Li, Shanghai (CN); Ning-Yi Hsu, New Taipei City (TW); Junjian Zhao, San Jose, CA (US)

(21) Appl. No.: 18/987,073

(22) Filed: Dec. 19, 2024

Related U.S. Application Data
(60) Provisional application No. 63/612,172, filed on Dec. 19, 2023.

(51) Int. Cl. H01S 5/026

(52) U.S. Cl. CPC H01S 5/026

(57) ABSTRACT

A charging unit adapted to be used for driving an integrated semiconductor laser device. The charging unit may include a first input terminal adapted to receive an input driving energy, a second input terminal adapted to be configured to enable operation or disable operation of the charging unit, a third input terminal adapted to be configured to receive a charging control PWM signal, and a second plurality of output terminals. The charging unit may be adapted to be configured to switch ON or switch OFF the second plurality of output terminals based on the charging control PWM signal PWM_C in a predetermined pattern.

### CROSS-REFERENCE TO RELATED APPLICATION(S)

The present application claims the benefit of and priority to a U.S. Provisional Patent Application Ser. 63/612,172 filed Dec. 19, 2023, which is hereby incorporated fully by reference into the present application.

### TECHNICAL FIELD

This disclosure relates generally to electronic circuits, and more particularly but not exclusively relates to circuit and system for driving integrated semiconductor laser device.

### BACKGROUND

Nowadays, Lidar is widely used and incorporated for example in ADAS system for automotive applications. One of the challenges lies in driving highly integrated semiconductor laser device such as vertical-cavity surface emitting laser (“VCSEL”) semiconductor laser device having an array of laser cells integrated in the semiconductor laser device to individually control each one VCSEL cell of the array of laser cells in solid state Lidar. The semiconductor laser device requires laser driving apparatus to provide current pulses to the semiconductor emitting laser cells of the semiconductor laser device. Existing discrete driving solution based on discrete GaN field effective transistors (“FETs”) for driving the semiconductor laser device, herein after referred to as “GaN based discrete solution”, is not reliable enough for automotive or vehicle original equipment manufacturers (“OEMs”) and is too large in size to fit in limited mounting space. Moreover, Tier1s think that GaN based discrete solution is expensive, because a system for driving for example one semiconductor laser device may need more than 10 discrete drivers to correspondingly drive more than 10 discrete GaN FETs.

### BRIEF DESCRIPTION OF DRAWINGS

The following detailed description of various embodiments of the present invention can best be understood when read in conjunction with the following drawings, in which the features are not necessarily drawn to scale but rather are drawn as to best illustrate the pertinent features.

FIG. 1 illustrates a schematic diagram of a driving system 100 in accordance with an embodiment of the present invention.

FIG. 2 illustrates an exemplary schematic diagram of a charging unit 200 which may be used to implement the charging unit 102 of the driving system 100 of FIG. 1 in accordance with an exemplary embodiment of the present invention.

FIG. 3A shows an illustrative waveform diagram 300 illustrating operation waveforms of several signals of the driving system 100 of FIG. 1 in accordance with an exemplary embodiment of the present invention.

FIG. 3B shows an illustrative waveform diagram 300B illustrating operation waveforms of several signals of the driving system 100 of FIG. 1 in accordance with an alternative exemplary embodiment of the present invention.

FIG. 4 illustrates an exemplary schematic diagram of a charging unit 400 that may be used to implement the charging unit 102 of the driving system 100 of FIG. 1 in accordance with an alternative exemplary embodiment of the present disclosure.

FIG. 5A shows an illustrative waveform diagram 500 illustrating operation waveforms of several signals of the driving system 100 of FIG. 1 where the charging unit 102 employs the charging unit 400 as illustrated in FIG. 4 in accordance with an exemplary embodiment of the present invention.

FIG. 5B shows an illustrative waveform diagram 500B illustrating operation waveforms of several signals of the driving system 100 of FIG. 1 where the charging unit 102 employs the charging unit 400 as illustrated in FIG. 4 in accordance with an alternative exemplary embodiment of the present invention.

FIG. 6 shows an illustrative waveform diagram illustrating operation waveforms of several signals of the driving system 100 of FIG. 1 where the charge unit 102 employs the charging unit 400 as illustrated in FIG. 4 in accordance with an alternative exemplary embodiment of the present invention.

FIG. 7 illustrates an exemplary schematic diagram of a discharging unit 700 that may be used to implement the discharging unit 106 in FIG. 1 in accordance with an alternative exemplary embodiment of the present disclosure.

FIG. 8 illustrates a package 800 including the charging unit 102 integrated in or on an integrated circuit die/chip in accordance with an embodiment of the present invention.

FIG. 9 illustrates a package 900 including the discharging unit 106 integrated in or on an integrated circuit die/chip in accordance with an embodiment of the present invention.

FIG. 10 illustrates a package 950 including the discharging unit 700 integrated in or on an integrated circuit die/chip in accordance with an embodiment of the present invention.

FIG. 11 illustrates a schematic diagram of a driving system 150 in accordance with an embodiment of the present invention.

FIG. 12 illustrates an exemplary schematic diagram of a charging unit 250 which may be used to implement the charging unit 102 of FIG. 11 as an alternative embodiment.

FIG. 13 shows an illustrative waveform diagram 350 illustrating operation waveforms of several signals of the driving system 150 of FIG. 11 in accordance with an exemplary embodiment of the present invention.

FIG. 14 illustrates an exemplary schematic diagram of a charging unit 450 in accordance with an alternative exemplary embodiment of the present disclosure.

FIG. 15 shows an illustrative waveform diagram 550 illustrating operation waveforms of several signals of the driving system 150 of FIG. 11 in accordance with an alternative exemplary embodiment of the present invention.

FIG. 16 shows an illustrative waveform diagram 650 illustrating operation waveforms of several signals of the driving system 150 of FIG. 11 in accordance with an alternative exemplary embodiment of the present invention.

FIG. 17 illustratively shows an alternative package 850 of an IC die or chip with the charging unit 102 integrated therein in accordance with an alternative embodiment of the present invention.

FIG. 18 illustrates an application board level layout diagram corresponding to the driving system 100 of FIG. 1 or the driving system 150 of FIG. 11 in accordance with an exemplary embodiment of the present invention.

FIG. 18A to FIG. 18F illustrate layer by layer application board level layout diagrams corresponding to the driving system 100 of FIG. 1 or the driving system 150 of FIG. 11 in accordance with an exemplary embodiment of the present invention.

FIG. 18G illustrates a plan view of a top side of the 1^{st} board layer 180(1) in accordance with an alternative exemplary embodiment of the present invention.

FIG. 18H illustrates a plan view of a bottom side of the multi-layer circuit board 1800 in accordance with an alternative exemplary embodiment of the present invention.

FIG. 19 illustrates a schematic diagram of a driving system 1000 in accordance with an embodiment of the present invention.

FIG. 20 illustrates a schematic diagram of a driving system 1500 in accordance with an embodiment of the present invention.

FIG. 21A illustrates an application board level layout diagram corresponding to the driving system 1000 of FIG. 19 or the driving system 1500 of FIG. 20 in accordance with an exemplary embodiment of the present invention.

FIG. 21B to FIG. 21G illustrate layer by layer application board level layout diagrams corresponding to the driving system 1000 of FIG. 19 or the driving system 1500 of FIG. 20 in accordance with an exemplary embodiment of the present invention.

FIG. 22 illustrates a schematic diagram of a driving system 2000 in accordance with an embodiment of the present invention.

FIG. 23 shows an illustrative waveform diagram 2300 illustrating operation waveforms of several signals of the driving system 150 of FIG. 11 when operated in a parallel output mode in accordance with an exemplary embodiment of the present invention.

### DETAILED DESCRIPTION

Various embodiments of the present invention will now be described. In the following description, some specific details, such as example circuits and example values for these circuit components, are included to provide a thorough understanding of embodiments. One skilled in the relevant art will recognize, however, that the present invention can be practiced without one or more specific details, or with other methods, components, materials, etc. In other instances, well-known structures, materials, processes or operations are not shown or described in detail to avoid obscuring aspects of the present invention.

Throughout the specification and claims, the terms “left,” right,” “in,” “out,” “front,” “back,” “up,” “down, “top,” “atop”, “bottom,” “over,” “under,” “above,” “below” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The term “coupled,” as used herein, is defined as directly or indirectly connected in an electrical or non-electrical manner. When an element is described as “connected” or “coupled” to another element, it can be directly connected or coupled to the other element, or there could exist one or more intermediate elements. In contrast, when an element is referred to as “directly connected” or “directly coupled” to another element, there is no intermediate element. The terms “a,” “an,” and “the” includes plural reference, and the term “in” includes “in” and “on”. Reference to “one embodiment,” “an embodiment,” “an example,” or “examples” means: certain features, structures, or characteristics are contained in at least one embodiment of the present invention. These “one embodiment,” “an embodiment,” “an example,” and “examples” are not necessarily directed to the same embodiment or example, although it may. Furthermore, the features, structures, or characteristics may be combined in one or more embodiments or examples. The term “or” is an inclusive “or” operator, and is equivalent to the term “and/or” herein, unless the context clearly dictates otherwise. Where either a field effect transistor (“FET”) or a bipolar junction transistor (“BJT”) may be employed as an embodiment of a transistor, the scope of the words “gate”, “drain”, and “source” includes “base”, “collector”, and “emitter”, respectively, and vice versa. The term “based on” is not exclusive and allows for being based on additional factors not described, unless the context clearly dictates otherwise. The term “circuit” means at least either a single component or a multiplicity of components, either active and/or passive, that are coupled together to provide a desired function. The term “signal” means at least one current, voltage, charge, temperature, data, or other signal. Those skilled in the art should understand that the meanings of the terms identified above do not necessarily limit the terms, but merely provide illustrative examples for the terms.

The terms “comprise”, “include”, “have” and any variations thereof, are intended to cover non-exclusive inclusions, such that a process, method, article, or apparatus that comprises a list of elements is not necessarily limited to those elements but may include other elements not expressly listed or inherent to such process, method, article, or apparatus.

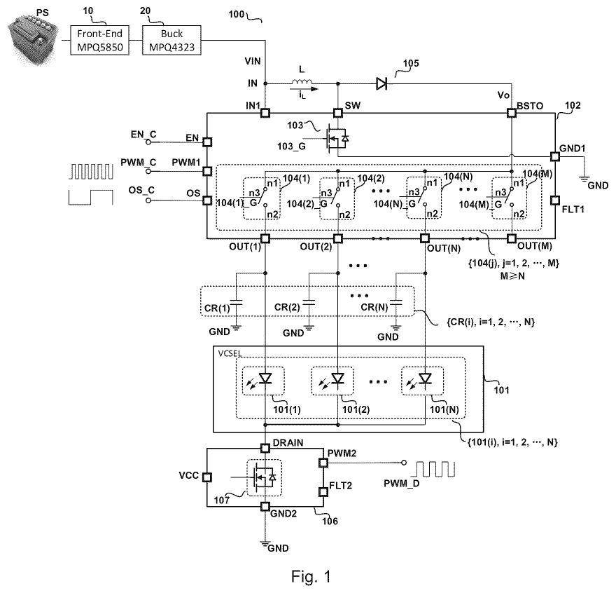

FIG. 1 illustrates a schematic diagram of a driving system 100 in accordance with an embodiment of the present invention. The driving system 100 may be adapted to be configured or used to drive an integrated semiconductor laser device 101 such as an integrated vertical-cavity surface emitting laser (“VCSEL”) unit. The integrated semiconductor laser device (e.g. semiconductor laser device) 101 may include a first plurality of (e.g. represented by an integer variable N) laser cells (e.g. VCSEL cells) 101(1), 101(2), . . . , 101(N) arranged in an array or a matrix. Herein after, the first plurality of (e.g., N) laser cells (e.g., VCSEL cells) 101(1), 101(2), . . . , 101(N) may be referred to as or represented by {101(i), i=1, 2, . . . , N}. Herein N is an integer variable no less than 1 and represents the total number of laser cells {101(i), i=1, 2, . . . , N} that the integrated semiconductor laser device 101 may include, which may be set or determined by customers/users in practical applications depending on real application requirements. That is to say, the index i is a variable traverses the integers from 1 to N. Each one of the first plurality of (e.g., N) laser cells {101(i), i=1, 2, . . . , N} may have a first terminal (e.g., an anode) and a second terminal (e.g., a cathode). In an example the integrated semiconductor laser device 101 may have 28 laser cells {101(i), i=1, 2, . . . , 28}, that is to say, in this example N=28. One of ordinary skill in the art would understand that this is just to provide an example and not intended to be limiting. The total number of laser cells {101(i), i=1, 2, . . . , N} that the integrated semiconductor laser device 101 includes may not be limited to 28 and may be of any other amount according to practical application requirement, the integer variable N is used to describe or represent the total number of laser cells {101(i), i=1, 2, . . . , N} included in the integrated semiconductor laser device 101 in the present disclosure for ease of reference and understanding.

The driving system 100 may include a driving energy input terminal IN to receive an input driving energy for instance in the form of a supply voltage VIN. However, this is just to provide an example and not intended to be limiting. One of ordinary skill in the art would understand that the input driving energy may be in other forms such as a supply current or a supply electrical force etc. that may be adaptable to be used or processed by the driving system 100. In an example, the input driving energy for instance in the form of the power supply voltage VIN may be provided by upstream power supply circuits, which may draw power from a power source PS, for instance a battery pack in automotive applications, as exemplarily illustrated in FIG. 1. Upstream power supply circuits may include in an embodiment, for instance, a front-end voltage regulator 10 and a buck voltage regulator 20, as exemplarily shown in FIG. 1. The front-end voltage regulator 10 and the buck voltage regulator 20 may, for example, respectively include a MPQ5850 and a MPQ4323 that are commercially available from Monolithic Power Systems Inc. However, one of ordinary skill in the art would understand that this is just to provide an example and not intended to be limiting. Upstream power supply circuits may be implemented with other power supply device or may include other circuit elements.

In accordance with an exemplary embodiment, the driving system 100 may further include a charging unit 102 having a first input terminal, for instance, a power supply terminal IN1, coupled to the driving energy input terminal IN. The charging unit 102 may include a second plurality of (e.g. represented by an integer variable M) output terminals OUT(1), OUT(2), . . . , OUT(M). Herein after, the second plurality of (e.g., M) output terminals OUT(1), OUT(2), . . . , OUT(M) may be referred to as or represented by {OUT(j), j=1, 2, . . . , M}. Herein M is an integer variable and represents the total number of output terminals {OUT(j), j=1, 2, . . . , M} that the charging unit 102 may include. That is to say, the index j is a variable traverses the integers from 1 to M. In accordance with an exemplary embodiment, M is no less than N, i.e. M N. In an example, the charging unit 102 may have 32 output terminals {OUT(j), j=1, 2, . . . , 32}, that is to say, in this example M=32. One of ordinary skill in the art would understand that this is just to provide an example and not intended to be limiting. The total number of output terminals {OUT(j), j=1, 2, . . . , M} that the charging unit 102 includes may not be limited to 32 and may be of any other amount according to practical application requirement, the integer variable M is used to describe or represent the total number of output terminals {OUT(j), j=1, 2, . . . , M} of the charging unit 102 in the present disclosure for ease of reference and understanding.

In accordance with an exemplary embodiment, the charging unit 102 may further include a second input terminal, for instance, an enable terminal EN that may be adapted to be configured to receive for instance an enable signal EN_C. The charging unit 102 may be adapted to be configured to be enabled for operation or be disabled to stop operation in response to the enable signal EN_C received at the enable terminal EN. In an example, when the charging unit 102 is enabled for operation, it may mean that the charging unit 102 (including all the sub-circuits or sub-elements that the charging unit 102 may comprise) is operable or is able to process signals or fulfill predetermined functions. When the charging unit 102 is disabled to stop operation, it may mean that the charging unit 102 is inoperable or shut down. In an example, the charging unit 102 may be configured to be enabled when the enable signal EN_C received at the enable terminal EN is at a first logic state (e.g. logic high) or when the enable signal EN_C reaches or goes higher than an enable threshold, and may be further configured to be disabled when the enable signal EN_C received at the enable terminal EN is at a second logic state (e.g. logic low) or when the enable signal EN_C falls below the enable threshold.

In accordance with an exemplary embodiment, the charging unit 102 may further include a third input terminal, for instance, a pulse width modulation (“PWM”) terminal PWM1 that may be adapted to be configured to receive for instance a charging control PWM signal PWM_C. The charging unit 102 may further be adapted to be configured to switch ON or switch OFF the second plurality of M output terminals {OUT(j), j=1, 2, . . . , M} based on the charging control PWM signal PWM_C in a predetermined pattern which may be customer or user programmable. In an exemplary embodiment, for each j=1, 2, . . . , M, each one of the second plurality of (e.g. M) output terminals {OUT(j), j=1, 2, . . . , M}, for instance, the j^{th} output terminal OUT(j) may be configured to provide energy in the form of for example voltage or current once being switched ON, and may further be configured to stop providing energy once being switched OFF. In an exemplary embodiment, for each j=1, 2, . . . , M, each one of the second plurality of (e.g. M) output terminals {OUT(j), j=1, 2, . . . , M}, for instance, the j^{th} output terminal OUT(j) may be switched ON for a time duration or a time window which may be referred to as a a j^{th} charging time window T_{cg}(j) for ease of description and understanding herein after.

In accordance with an exemplary embodiment, the second plurality of (e.g., M) output terminals {OUT(j), j=1, 2, . . . , M} may be switched ON successively in sequence (i.e., following the sequential order from OUT(1) to OUT(M)) according to a plurality of successive charge pulses of the charging control PWM signal PWM_C. For instance, for each j varying from 1 to M, the j^{th} output terminal OUT(j) may be switched ON during the j^{th} charging time window T_{cg}(j) following a j^{th} charge pulse of the charging control PWM signal PWM_C. However, one of ordinary skill in the art would understand that this is just to provide an example and not intended to be limiting, in alternative exemplary embodiments, the predetermined pattern or order to switch ON or switch OFF the second plurality of M output terminals {OUT(j), j=1, 2, . . . , M} may be flexibly controlled or programmed for example by customer or user, not necessarily be switched ON successively in sequence (i.e., following the sequential order from OUT(1) to OUT(M)) according to the plurality of successive charge pulses of the charging control PWM signal PWM_C. In other words, the j^{th} charging time window T_{cg}(j) during which the j^{th} output terminal OUT(j) would be switched ON may not be necessarily located following the j^{th} charge pulse of the charging control PWM signal PWM_C, for each j varying from 1 to M.

In addition, those of ordinary skill in the art should understand that, the first charge pulse of the charging control PWM signal PWM_C may not be the real time initial pulse or first pulse of the charging control PWM signal PWM_C. Rather, the first charge pulse may refer to a pulse of the charging control PWM signal PWM_C appeared or generated after a predetermined time T_{ready} since the driving system 100 or the charging unit 102 is powered on. During the predetermined time T_{ready}, the driving system 100 or the charging unit 102 may establish and get prepared for normal or steady operation. In an exemplary embodiment, the first charge pulse, the second charge pulse, . . . , the j^{th} charge pulse, and so on of the charging control PWM signal PWM_C may refer to a sequence of consecutive pulses of the charging control PWM signal PWM_C. But this is just to provide an example and not intended to be limiting. For instance, in an alternative exemplary embodiment, each of the first charge pulse, the second charge pulse, . . . , the j^{th} charge pulse, and so on may include every two or three adjacently and consecutively generated pulses of the charging control PWM signal PWM_C.

In accordance with an exemplary embodiment, the charging unit 102 may further include a reference ground terminal GND1. The charging unit 102, including all the sub-circuits or sub-elements that the charging unit 102 may comprise, may be configured to use a reference ground potential at the reference ground terminal GND1 as a ground potential of the charging unit 102. In an example, the reference ground terminal GND1 of the charging unit 102 may be connected to a reference ground GND of the driving system 100.

In accordance with an exemplary embodiment, the charging unit 102 may be coupled to the integrated semiconductor laser device 101 to provide energy to the first plurality of (e.g. N) laser cells {101(i), i=1, 2, . . . , N} in accordance with the predetermined pattern that the second plurality of (e.g. M) output terminals {OUT(j), j=1, 2, . . . , M} are switched ON or switched OFF based on the charging control PWM signal PWM_C. For instance, in an exemplary embodiment, a corresponding first plurality of (e.g., N) output terminals corresponding to the first plurality of (e.g., N) laser cells {101(i), i=1, 2, . . . , N} may be selected out from the second plurality of (e.g., M) output terminals {OUT(j), j=1, 2, . . . , M}, and may be coupled to the first plurality of (e.g. N) laser cells {101(i), i=1, 2, . . . , N} in a one-to-one correspondence manner. In other words, the corresponding first plurality of (e.g., N) output terminals that are selected out from the second plurality of (e.g. M) output terminals {OUT(j), j=1, 2, . . . , M} may match with the first plurality of (e.g. N) laser cells {101(i), i=1, 2, . . . , N} at least in amount. Herein after, the first plurality of (e.g., N) output terminals selected out from the second plurality of (e.g., M) output terminals {OUT(j), j=1, 2, . . . , M} of the charging unit 102 to be coupled to the first plurality of (e.g., N) laser cells {101(i), i=1, 2, . . . , N} may be referred to as a first plurality of (e.g., N) selected output terminals and represented by {OUT(i), i=1, 2, . . . , N} for ease of reference, description and understanding in rest of the descriptions of the present disclosure.

To provide an example, as illustrated in FIG. 1, the first consecutively indexed N output terminals {OUT(j), j=1, 2, . . . , N} may be selected out from the second plurality of (e.g., M) output terminals {OUT(j), j=1, 2, . . . , M}, and may be respectively coupled to the first plurality of (e.g., N) laser cells {101(i), i=1, 2, . . . , N}. However, this is just to provide an example and not intended to be limiting.

One of ordinary skill in the art would understand that one could randomly choose to use any N output terminals among the M output terminals {OUT(j), j=1, 2, . . . , M} of the charging unit 102 to drive the first plurality of (e.g., N) laser cells {101(i), i=1, 2, . . . , N} since the number M of the output terminals {OUT(j), j=1, 2, . . . , M} of the charging unit 102 is no less than the number N of the laser cells {101(i), i=1, 2, . . . , N}. That is to say, each one output terminal of the first plurality of (e.g., N) output terminals chosen from the second plurality of (e.g., M) output terminals {OUT(j), j=1, 2, . . . , M} of the charging unit 102 may be coupled to a corresponding one laser cell of the first plurality of (e.g., N) laser cells {101(i), i=1, 2, . . . , N}. Herein after, among the first plurality of (e.g., N) selected output terminals chosen from the second plurality of (e.g., M) output terminals {OUT(j), j=1, 2, . . . , M} of the charging unit 102, the one output terminal which is coupled to the corresponding one, e.g., the i^{th} laser cell 101(i), of the first plurality of (e.g., N) laser cells {101(i), i=1, 2, . . . , N} may be referred to as the selected i^{th} output terminal and labeled or re-indexed with OUT(i) for ease of reference, description and understanding in rest of the descriptions of the present disclosure. The selected i^{th} output terminal OUT(i) may be connected to the first terminal of the corresponding one i^{th} laser cell 101(i). It is obvious to one of ordinary skill in the art that in the exemplary embodiment where the first consecutively indexed N output terminals {OUT(j), j=1, 2, . . . , N} are selected out from the second plurality of (e.g. M) output terminals {OUT(j), j=1, 2, . . . , M} and respectively coupled to the first plurality of (e.g. N) laser cells {101(i), i=1, 2, . . . , N}, the first plurality of consecutively indexed output terminals {OUT(j), j=1, 2, . . . , N} from the second plurality of (e.g. M) output terminals {OUT(j), j=1, 2, . . . , M} and the first plurality of selected output terminals {OUT(i), i=1, 2, . . . , N} may refer to the same subject matters, and for each i=j varying from 1 to N, the j^{th} output terminal OUT(j), the i^{th} output terminal OUT(i) and the selected i^{th} output terminal OUT(i) refer to the same output terminal. However, it is also obvious to one of ordinary skill in the art that the first plurality of (e.g., N) selected output terminals {OUT(i), i=1, 2, . . . , N} may not be necessarily and always equal to the first consecutively indexed N output terminals {OUT(j), j=1, 2, . . . , N} of the second plurality of (e.g. M) output terminals {OUT(j), j=1, 2, . . . , M}, rather the first plurality of (e.g., N) selected output terminals {OUT(i), i=1, 2, . . . , N} are re-indexed according to the corresponding first plurality of laser cells {101(i), i=1, 2, . . . , N}.

In accordance with an exemplary embodiment, the first plurality of (e.g., N) selected output terminals may be switched ON successively in sequence (i.e., following the sequential order from OUT(1) to OUT(N)) according to the plurality of successive charge pulses of the charging control PWM signal PWM_C. For instance, for each i=1, 2, . . . , N, the selected i^{th} output terminal, which is coupled to the corresponding i^{th} laser cell 101(i) of the first plurality of (e.g., N) laser cells {101(i), i=1, 2, . . . , N}, may be switched ON during a window referenced as an i^{th} charging time window T_{cg}(i) herein after for ease of description. In an exemplary embodiment, for each i=1, 2, . . . , N, the i^{th} charging time window T_{cg}(i) may be located following an i^{th} charge pulse of the charging control PWM signal PWM_C. For instance, in an embodiment, for each i=1, 2, . . . , N, the i^{th} charging time window T_{cg}(i) may be located between an i^{th} charge pulse and an (i+1)^{th} charge pulse of the charging control PWM signal PWM_C. That is to say, in this example, the ON and OFF switching pattern or order of the selected i^{th} output terminal is determined by the i^{th} charge pulse of the charging control PWM signal PWM_C, for each i varying from 1 to N. However, one of ordinary skill in the art would understand that this is just to provide an example and not intended to be limiting, in alternative exemplary embodiments, for each i changing from 1 to N, the predetermined pattern or order to switch ON or switch OFF the selected i^{th} output terminal, i.e., location of the i^{th} charging time window T_{cg}(i) may be flexibly controlled or programmed, not necessarily following the i^{th} charge pulse of the charging control PWM signal PWM_C. It is obvious to one of ordinary skill in the art that in the exemplary embodiment where the first consecutively indexed N output terminals {OUT(j), j=1, 2, . . . , N} are selected out from the second plurality of (e.g. M) output terminals {OUT(j), j=1, 2, . . . , M} and respectively coupled to the first plurality of (e.g. N) laser cells {101(i), i=1, 2, . . . , N}, for each i=j varying from 1 to N, the j^{th} charging time window T_{cg}(j) associated with the j^{th} output terminal OUT(j) and the i^{th} charging time window T_{cg}(i) associated with the selected i^{th} output terminal refer to the same charging time window.

In accordance with an exemplary embodiment, the charging unit 102 may further include at least one controllable power switch 103 that may be adapted to be configured to perform ON and OFF switching when the charging unit 102 is enabled. In an exemplary embodiment, when the charging unit 102 is enabled, the at least one controllable power switch 103 may be adapted to be configured to perform ON and OFF switching in response to the charging control PWM signal PWM_C received at the third input terminal (e.g., the PWM terminal PWM1) of the charging unit 102. For instance, during each operation cycle or period T_{PWMC} of the charging control PWM signal PWM_C, the at least one controllable power switch 103 may be switched ON in response to a first transition edge (e.g. a rising edge) of the charging control PWM signal PWM_C at which the charging control PWM signal PWM_C changes from a first voltage level or logic level (e.g. logic low) to a second voltage level or logic level (e.g. logic high), and may be switched OFF in response to a second transition edge (e.g. a falling edge) of the charging control PWM signal PWM_C at which the charging control PWM signal PWM_C changes from the second voltage level or logic level (e.g. logic high) to the first voltage level or logic level (e.g. logic low). However, this is just to provide an example and not intended to be limiting, in other embodiments, the at least one controllable power switch 103 may not perform ON and OFF switching in every operation cycle or period T_{PWMC} of the charging control PWM signal PWM_C. For another instance, the at least one controllable power switch 103 may be switched ON in response to a first transition edge (e.g. a rising edge) of each charge pulse of the charging control PWM signal PWM_C at which the charging control PWM signal PWM_C changes from a first voltage level or logic level (e.g. logic low) to a second voltage level or logic level (e.g. logic high), and may be switched OFF in response to a second transition edge (e.g. a falling edge) of each charge pulse of the charging control PWM signal PWM_C at which the charging control PWM signal PWM_C changes from the second voltage level or logic level (e.g. logic high) to the first voltage level or logic level (e.g. logic low).

Ideally, the at least one controllable power switch 103 may allow a current to flow through when turned ON while cutting off the current flow when turned OFF. To provide an example, the at least one controllable power switch 103 may include a field effect transistor (“FET”), such as a metal oxide field effect transistor (“MOSFET”), or a double diffused metal oxide field effect transistor (“DMOS”), or a GaN FET or a SiC FET or a junction field effect transistor (“JFET”) etc. It would be obvious for a person of ordinary skill in the art that the at least one controllable power switch 103 may be implemented with other controllable switch device(s) such as a bipolar junction transistor (“BJT”) or an insulated gate bipolar transistor (“IGBT”) etc. Or alternatively, in other examples, the at least one controllable power switch 103 may include a combination of one or more of the aforementioned transistors. The at least one controllable power switch 103 may be used to control or regulate an amount of energy transmitted from the driving energy input terminal IN to the charging unit 102. For instance, in an embodiment, the at least one controllable power switch 103 may be used to control or regulate an amount of energy transmitted from the driving energy input terminal IN to a power output terminal BSTO of the charging unit 102. By doing so, the charging unit 102 may be adapted to be used for being configured to convert the power supply voltage VIN to a regulated output voltage Vo that may be provided at the power output terminal BSTO.

In accordance with an exemplary embodiment, the charging unit 102 may further include a switch terminal SW that may be adapted to be configured to provide for instance a switching signal. The charging unit 102 may be adapted to be configured to function as part of a power conversion apparatus when an inductive energy storage device L is coupled to the switch terminal SW of the charging unit 102. In an example, as shown in FIG. 1, the at least one controllable power switch 103 may be coupled between the switch terminal SW and the power output terminal BSTO. The inductive energy storage device L may be coupled between the first input terminal (e.g., the power supply terminal) IN1 and the switch terminal SW of the charging unit 102. The power conversion apparatus may further include a second power switch 105 that may be coupled between the switch terminal SW and the power output terminal BSTO as shown in the example of FIG. 1. The second power switch 105 may include a diode in an example. In an alternative example, the second power switch 105 may include a controllable power transistor such as a MOSFET or a DMOS or a GaN FET, or a SiC FET, or a BJT, or an IGBT, etc. The second power switch 105 may either be a discrete device placed outside the charging unit 102 or be an integrated device placed inside the charging unit 102. In an exemplary embodiment, the second power switch 105 may be configured to perform ON and OFF switching in a complimentary manner with the at least one controllable power switch 103. That is to say, when the at least one controllable power switch 103 is switched ON, the second power switch 105 is OFF, and when the at least one controllable power switch 103 is switched OFF, the second power switch 105 is ON. For the example illustrated in FIG. 1, it is exemplarily illustrated that the charging unit 102 is configured to function as part of the power conversion apparatus having a boost converter topology. One of ordinary skill in the art would understand that, this is just to provide an example and not intended to be limiting. In other embodiments, the charging unit 102 may be configured to function as at least part of a power conversion apparatus having other types of power conversion topologies such as buck converter topology, buck-boost power converter topology, fly-back power converter topology etc.

In accordance with an exemplary embodiment, the charging unit 102 may further include a corresponding second plurality of (e.g., M) charging path control circuits 104(1), 104(2), . . . , 104(M) corresponding to the second plurality of (e.g., M) output terminals {OUT(j), j=1, 2, . . . , M}. Herein after, the corresponding second plurality of (e.g., M) charging path control circuits 104(1), 104(2), . . . , 104(M) may be referred to as or represented by {104(j), j=1, 2, . . . , M}. In other words, the corresponding second plurality of (e.g., M) charging path control circuits {104(j), j=1, 2, . . . , M} may match with the second plurality of (e.g., M) output terminals {OUT(j), j=1, 2, . . . , M} at least in amount. In an embodiment, the corresponding second plurality of (e.g., M) charging path control circuits {104(j), j=1, 2, . . . , M} may be coupled to the second plurality of (e.g., M) output terminals {OUT(j), j=1, 2, . . . , M} in a one-to-one correspondence manner. That is to say, each one charging path control circuit of the corresponding second plurality of (e.g., M) charging path control circuits {104(j), j=1, 2, . . . , M} may be coupled to a corresponding one output terminal of the second plurality of (e.g., M) output terminals {OUT(j), j=1, 2, . . . , M}. Or in other words, for each j=1, 2, . . . , M, each one charging path control circuit, for instance the j^{th} charging path control circuit 104(j), of the corresponding second plurality of (e.g., M) charging path control circuits {104(j), j=1, 2, . . . , M} may be coupled to the corresponding one output terminal, for instance the j^{th} output terminal OUT(j) of the second plurality of (e.g., M) output terminals {OUT(j), j=1, 2, . . . , M}. Herein the integer variable M is also used to describe or represent the total number of charging path control circuits {104(j), j=1, 2, . . . , M} that the charging unit 102 may include in the present disclosure for ease of reference and understanding. In other words, the total number of the charging path control circuits {104(j), j=1, 2, . . . , M} that the charging unit 102 may include should be matching with or identical to the total number of the output terminals {OUT(j), j=1, 2, . . . , M} that the charging unit 102 may have. For instance, in the example where the charging unit 102 has 32 output terminals {OUT(j), j=1, 2, . . . , 32}, the charging unit 102 may include 32 charging path control circuits {104(j), j=1, 2, . . . , 32}corresponding to the 32 output terminals {OUT(j), j=1, 2, . . . , 32} and respectively coupled to the 32 output terminals {OUT(j), j=1, 2, . . . , 32}.

In accordance with an exemplary embodiment, for each j=1, 2, . . . , M, each one charging path control circuit, for instance the j^{th} charging path control circuit 104(j), of the corresponding second plurality of (e.g. M) charging path control circuits {104(j), j=1, 2, . . . , M} may be switched ON or switched OFF in response to the charging control PWM signal PWM_C received at the third input terminal (e.g. the PWM terminal PWM1) of the charging unit 102. For each j=1, 2, . . . , M, each one charging path control circuit (i.e., the j^{th} charging path control circuit 104(j)) of the corresponding second plurality of (e.g. M) charging path control circuits {104(j), j=1, 2, . . . , M} may be configured to enable an energy transfer/transmission path from the power output terminal BSTO to the corresponding one output terminal (i.e. the j^{th} output terminal OUT(j)) of the second plurality of (e.g. M) output terminals {OUT(j), j=1, 2, . . . , M}, once being switched ON, and may further be configured to disable or cut off the energy transfer/transmission path from the power output terminal BSTO to the corresponding one output terminal, for instance, the j^{th} output terminal OUT(j) once being switched OFF. That is to say, for each j=1, 2, . . . , M, the j^{th} charging path control circuit 104(j) may be configured to enable the energy transfer/transmission path from the power output terminal BSTO to the corresponding one j^{th} output terminal OUT(j) once being switched ON, and may further be configured to disable or cut off the energy transfer/transmission path from the power output terminal BSTO to the corresponding one j^{th} output terminal OUT(j) once being switched OFF. It may be understood by one of ordinary skill in the art that when the j^{th} charging path control circuit 104(j) enables the energy transfer/transmission path from the power output terminal BSTO to the corresponding one j^{th} output terminal OUT(j), the enabled energy transfer/transmission path may be ready or adapted to transmit energy from the output terminal BSTO to the corresponding one j^{th} output terminal OUT(j), for each j=1, 2, . . . , M. In other words, for each j=1, 2, . . . , M, once the energy transfer/transmission path from the power output terminal BSTO to the corresponding one j^{th} output terminal OUT(j) is enabled, it is not required that this enabled energy transfer/transmission path immediately begins with energy transferring, although it may, but means that the enabled energy transfer/transmission path is in a status ready for or adaptable for transferring energy (for example is conductive). For instance, in an embodiment, for each j=1, 2, . . . , M, when the j^{th} charging path control circuit 104(j) is switched ON and enables the energy transfer/transmission path from the power output terminal BSTO to the corresponding one j^{th} output terminal OUT(j), the charging unit 102 may wait for other condition(s) to be met to begin with energy transferring/transmission from the power output terminal BSTO to the corresponding one j^{th} output terminal OUT(j) through the enabled energy transfer/transmission path. Energy transfer/transmission may be in the form of for example voltage or current or electrical charges etc. On the contrary, for each j=1, 2, . . . , M, when the j^{th} charging path control circuit 104(j) is switched OFF to disable or cut off the energy transfer/transmission path from the power output terminal BSTO to the corresponding one j^{th} output terminal OUT(j), the disabled energy transfer/transmission path may no longer be adaptable for transmitting energy from the output terminal BSTO to the corresponding one j^{th} output terminal OUT(j), which means that the disabled energy transfer/transmission path is in a status blocking energy transmission (for example is not conductive or disconnecting the power output terminal BSTO from the corresponding one j^{th} output terminal OUT(j)).

In accordance with an exemplary embodiment, for each j=1, 2, . . . , M, each one charging path control circuit, for instance the j^{th} charging path control circuit 104(j), of the corresponding second plurality of (e.g., M) charging path control circuits {104(j), j=1, 2, . . . , M} may have a first terminal n1, a second terminal n2 and a control terminal n3. In an exemplary embodiment, first terminals n1 of the corresponding second plurality of (e.g., M) charging path control circuits {104(j), j=1, 2, . . . , M} may be coupled together to the power output terminal BSTO. The second terminal n2 of each one charging path control circuit, for instance the j^{th} charging path control circuit 104(j), of the corresponding second plurality of (e.g., M) charging path control circuits {104(j), j=1, 2, . . . , M} may be coupled to the corresponding one output terminal, for instance the j^{th} output terminal OUT(j), of the second plurality of M output terminals {OUT(j), j=1, 2, . . . , M}. The control terminals n3 of the charging path control circuits {104(j), j=1, 2, . . . , M} may be controlled based on pulses of the charging control PWM signal PWM_C to switch the charging path control circuits {104(j), j=1, 2, . . . , M} ON or OFF in a predetermined pattern or order which may be customer or user programmable.

In accordance with an exemplary embodiment, for each i=1, 2, . . . , N, the charging unit 102 may be configured to switch ON the charging path control circuit which is coupled to the selected i^{th} output terminal OUT(i) among the first plurality of (e.g. N) output terminals chosen from the second plurality of (e.g. M) output terminals {OUT(j), j=1, 2, . . . , M} of the charging unit 102, during an on time window Tₒₙ(i) which will be referred to as a selected i^{th} on time window Tₒₙ(i) associated with the charging path control circuit that is coupled to the selected i^{th} output terminal OUT(i). The charging unit 102 may further be configured to keep the charging path control circuit which is coupled to the selected i^{th} output terminal OUT(i) OFF outside the selected i^{th} on time window Tₒₙ(i). The charging unit 102 may be configured to control the selected i^{th} on time window Tₒₙ(i) associated with the charging path control circuit which is coupled to the selected i^{th} output terminal OUT(i) based on the pulses of the charging control PWM signal PWM_C, for instance based on the charge pulses of the charging control PWM signal PWM_C.

In accordance with an exemplary embodiment, for each i=1, 2, . . . , N, the charging unit 102 may be configured to switch ON the charging path control circuit which is coupled to the selected i^{th} output terminal OUT(i) at a moment located within a time duration when the controllable power switch 103 is kept ON for instance in response to the present i^{th} charge pulse of the charging control PWM signal PWM_C in an example. That is, the moment when the charging path control circuit coupled to the selected i^{th} output terminal OUT(i) is switched ON is no earlier than a moment when the controllable power switch 103 is switched ON in response to the present i^{th} charge pulse of the charging control PWM signal PWM_C and no later than a moment when the controllable power switch 103 is switched OFF in response to the present i^{th} charge pulse of the charging control PWM signal PWM_C. And it can be easily understood by those of ordinary skill in the art that the moment when the controllable power switch 103 is switched OFF in response to the present i^{th} charge pulse of the charging control PWM signal PWM_C is a moment when the i^{th} charging time window T_{cg}(i) associated with the selected i^{th} output terminal OUT(i) begins so that the selected i^{th} output terminal OUT(i) is switched ON to begin charging the corresponding one energy storage devices CR(i) that is coupled to the selected i^{th} output terminal OUT(i).

For each i=1, 2, . . . , N, the charging unit 102 may further be configured to switch OFF the charging path control circuit which is coupled to the selected i^{th} output terminal OUT(i) at a moment no later than a moment when the controllable power switch 103 is switched OFF in response to the next (i+1)^{th} charge pulse of the charging control PWM signal PWM_C in an example. And it can be easily understood by those of ordinary skill in the art that the moment when the controllable power switch 103 is switched OFF in response to the next (i+1)^{th} charge pulse of the charging control PWM signal PWM_C is actually the moment when a charging time window Tcg(s) associated with the next selected output terminal OUT(s) which would be switched ON following the selected i^{th} output terminal OUT(i) begins, herein s is a variable representing an index or label number of the selected output terminal OUT(s) which would be switched ON following the selected i^{th} output terminal OUT(i), and s could be chosen from 1 to N. In an example, the next selected output terminal OUT(s) that would be switched ON following the selected i^{th} output terminal OUT(i) may be the selected (i+1)^{th} output terminal OUT(i+1) for embodiments where the first plurality of (e.g., N) selected output terminals {OUT(i), i=1, 2, . . . , N} would be successively sequentially switched ON, i.e., following the sequential order from OUT(1) to OUT(N). In another example, the next selected output terminal OUT(s) that would be switched ON following the selected i^{th} output terminal OUT(i) may not necessarily be the selected (i+1)^{th} output terminal OUT(i+1) for embodiments where the first plurality of (e.g., N) selected output terminals {OUT(i), i=1, 2, . . . , N} would not be successively sequentially switched ON.

In other words, the charging unit 102 may be configured to control the selected i^{th} on time window Tₒₙ(i) of the charging path control circuit that is coupled to the selected i^{th} output terminal OUT(i) to begin at a moment located within the time duration when the controllable power switch 103 is kept ON for instance in response to the present i^{th} charge pulse of the charging control PWM signal PWM_C and to end at a moment no later than the moment when the controllable power switch 103 is switched OFF in response to the next (i+1)^{th} charge pulse of the charging control PWM signal PWM_C in an example. In this fashion, the charging unit 102 may be configured to flexibly adjust the selected i^{th} on time window Tₒₙ(i) to ensure that the charging path control circuit coupled to the selected i^{th} output terminal OUT(i) is switched ON to enable the energy transfer/transmission path from the power output terminal BSTO to the selected i^{th} output terminal OUT(i) no later than the moment when the i^{th} charging time window T_{cg}(i) associated with the selected i^{th} output terminal OUT(i) begins and that the charging path control circuit coupled to the selected i^{th} output terminal OUT(i) is switched OFF to disable the energy transfer/transmission path from the power output terminal BSTO to the selected i^{th} output terminal OUT(i) no later than the moment when the charging time window Tcg(s) associated with the next selected output terminal OUT(s) which would be switched ON following the selected i^{th} output terminal OUT(i) begins.

In accordance with an exemplary embodiment, for each i=1, 2, . . . , N, the charging unit 102 may be configured to let the charging path control circuit which is coupled to the selected i^{th} output terminal among the first plurality of (e.g. N) output terminals chosen from the second plurality of (e.g. M) output terminals {OUT(j), j=1, 2, . . . , M} of the charging unit 102 being ON, during the i^{th} charging time window T_{cg}(i) located between the i^{th} charge pulse and the (i+1)^{th} charge pulse of the charging control PWM signal PWM_C. One of ordinary skill in the art would understand that this is just to provide an example and not intended to be limiting, the charging unit 102 may be configured to let the charging path control circuit coupled to the selected i^{th} output terminal being ON with various other alternative manners that cannot be exhaustively addressed here yet do not depart from the spirit and scope of various embodiments of the present disclosure, as long as the selected i^{th} on time window Tₒₙ(i) of the charging path control circuit that is coupled to the selected i^{th} output terminal OUT(i) can be controlled as described in the above paragraphs.

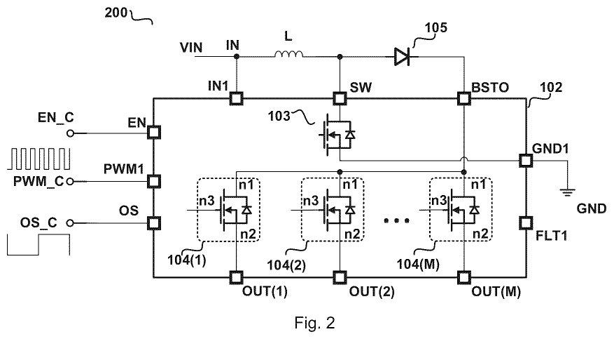

In accordance with an exemplary embodiment, for each j=1, 2, . . . , M, each one charging path control circuit, for instance the j^{th} charging path control circuit 104(j), of the corresponding second plurality of (e.g., M) charging path control circuits {104(j), j=1, 2, . . . , M} may include at least one switch as illustrated in FIG. 1. In an example, as shown in FIG. 2 illustrating an exemplary schematic diagram of a charging unit 200 which may be used to implement the charging unit 102, the at least one switch in each one charging path control circuit for instance the j^{th} charging path control circuit 104(j) may include a controllable transistor, such as a MOSFET or a DMOS or a GaN FET, or a SiC FET, or a BJT, or an IGBT, etc.

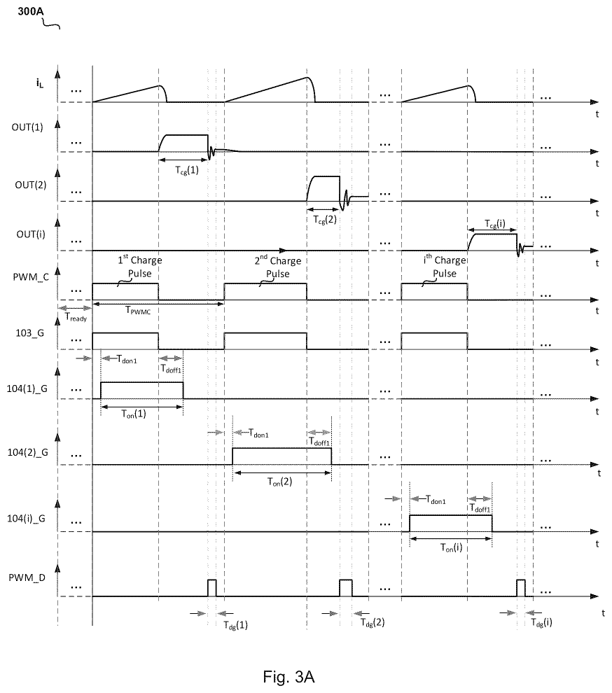

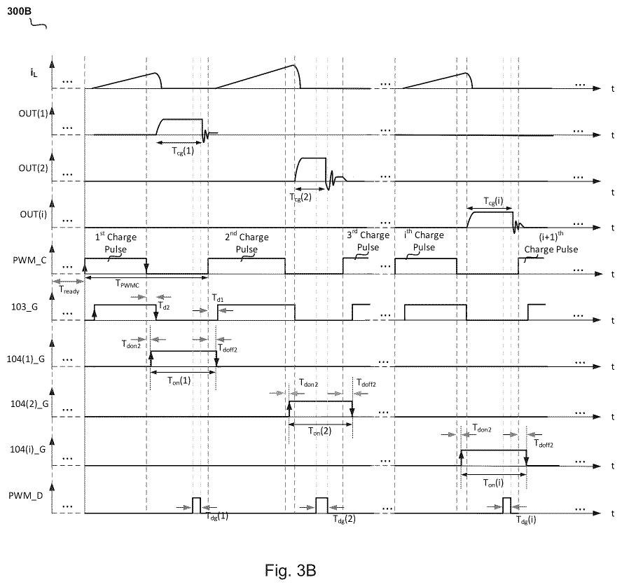

FIG. 3A shows an illustrative waveform diagram 300A illustrating operation waveforms of several signals of the driving system 100 of FIG. 1 in accordance with an exemplary embodiment of the present invention. FIG. 3B shows an illustrative waveform diagram 300B illustrating operation waveforms of several signals of the driving system 100 of FIG. 1 in accordance with an alternative exemplary embodiment of the present invention. It can be seen from FIG. 3A and FIG. 3B, that in this example the selected i^{th} output terminal OUT(i), which is coupled to the corresponding i^{th} laser cell 101(i) of the first plurality of (e.g., N) laser cells {101(i), i=1, 2, . . . , N}, may be switched ON during the i^{th} charging time window T_{cg}(i) located between an i^{th} charge pulse and an (i+1)^{th} charge pulse of the charging control PWM signal PWM_C, for each i=1, 2, . . . , N.

In the illustrative waveform diagram shown in FIG. 3A and FIG. 3B, the plot labeled with 103_G may represent an illustrative waveform of a control signal (also referenced by 103_G for simplicity and ease of understanding) for controlling the at least one controllable power switch 103, which may for instance be applied or provided to a gate control terminal of the least one controllable power switch 103 for the example where the at least one controllable power switch includes a field effect transistor (“FET”). One of ordinary skill in the art would understand that, for the examples illustrated in FIG. 3A and FIG. 3B, the logic high level in the plot of the waveform of the control signal 103_G may indicate that the at least one controllable power switch 103 is switched ON, and an inductor current i_{L} flowing through the inductive energy storage device L may gradually rise up, thereby energy being stored in the inductive energy storage device L and the power output terminal BSTO being charged up. The logic low level in the plot of the waveform of the control signal 103_G may indicate that the at least one controllable power switch 103 is switched OFF, and the inductor current i_{L} flowing through the inductive energy storage device L may gradually falls down.

The control signal 103_G may be provided or generated based on the charging control PWM signal PWM_C. For instance, in an exemplary embodiment referring to FIG. 3A, the control signal 103_G may be synchronized and in phase with the charging control PWM signal PWM_C. The at least one controllable power switch 103 may be switched ON in response to each first transition edge (e.g., each rising edge) of the charging control PWM signal PWM_C, and may be switched OFF in response to each second transition edge (e.g., each falling edge) of the charging control PWM signal PWM_C.

For another instance, in an alternative exemplary embodiment referring to FIG. 3B, the control signal 103_G may not be ideally synchronized and in phase with the charging control PWM signal PWM_C considering there would be some time needed for physical implementation circuits to respond in practical integrated circuits, therefore, a first time delay td1 may be introduced in between each first transition edge (e.g., each rising edge) of the charging control PWM signal PWM_C and a corresponding first transition edge (e.g., rising edge) of the control signal 103_G and a second time delay td2 may be introduced in between each second transition edge (e.g., each falling edge) of the charging control PWM signal PWM_C and a corresponding second transition edge (e.g., falling edge) of the control signal 103_G during each operation cycle or period T_{PWMC} of the charging control PWM signal PWM_C. For this situation, it can be understood that the at least one controllable power switch 103 may be switched ON in response to each first transition edge (e.g., each rising edge) of the charging control PWM signal PWM_C with the first time delay td1, and may be switched OFF in response to each second transition edge (e.g., each falling edge) of the charging control PWM signal PWM_C with the second time delay td2. One of ordinary skill in the art would understand that “in response to each first transition edge (e.g. the rising edge) of the charging control PWM signal PWM_C with the first time delay td1” may refer to “in response to the moment or at the moment when the first time delay td1 has elapsed since the moment at each first transition edge (e.g. each rising edge) of the charging control PWM signal PWM_C”. Similarly, “in response to each second transition edge (e.g. each falling edge) of the charging control PWM signal PWM_C with the second time delay td2” may refer to “in response to the moment or at the moment when the second time delay td2 has elapsed since the moment at each second transition edge (e.g. each falling edge) of the charging control PWM signal PWM_C”.

For still another instance, the control signal 103_G may not need to be responsive to each pulse, or alternatively speaking each first transition edge (e.g., each rising edge) and each second transition edge (e.g., each falling edge), of the charging control PWM signal PWM_C. Instead, the control signal 103_G may be configured to be responsive to the i^{th} charge pulse of the charging control PWM signal PWM_C for each i=1, 2, . . . , N. For instance, for each i from 1 to N, in response to a first transition edge (e.g., a rising edge) of the i^{th} charge pulse the charging control PWM signal PWM_C with the first time delay td1, a corresponding first transition edge (e.g., a rising edge) of the control signal 103_G may be generated and in response to a second transition edge (e.g., a falling edge) of the i^{th} charge pulse the charging control PWM signal PWM_C with the second time delay td2, a corresponding second transition edge (e.g., a falling edge) of the control signal 103_G may be generated. This could still be understood with reference to FIG. 3B, exemplarily showing the plurality of charge pulses include a sequence of consecutive pulses of the charging control PWM signal PWM_C. For this situation, it can be understood that the at least one controllable power switch 103 may be switched ON in response to the first transition edge (e.g., the rising edge) of the i^{th} charge pulse of the charging control PWM signal PWM_C with the first time delay td1, and may be switched OFF in response to second transition edge (e.g., a falling edge) of the i^{th} charge pulse the charging control PWM signal PWM_C with the second time delay td2. One of ordinary skill in the art would understand that “in response to the first transition edge (e.g. the rising edge) of the i^{th} charge pulse of the charging control PWM signal PWM_C with the first time delay td1” may refer to “in response to the moment or at the moment when the first time delay td1 has elapsed since the moment at the first transition edge (e.g. the rising edge) of the i^{th} charge pulse of the charging control PWM signal PWM_C”. Similarly, “in response to the second transition edge (e.g. the falling edge) of the i^{th} charge pulse of the charging control PWM signal PWM_C with the second time delay td2” may refer to “in response to the moment or at the moment when the second time delay td2 has elapsed since the moment at the second transition edge (e.g. the falling edge) of the i^{th} charge pulse of the charging control PWM signal PWM_C”.

In the illustrative waveform diagrams shown in FIG. 3A and FIG. 3B, for each i=1, 2, . . . , N, the plot labeled with 104(i)_G may represent an illustrative waveform of a control signal (also referenced by 104(i)_G for simplicity and ease of understanding) for controlling the i^{th} charging path control circuit 104(i) among the second plurality of (e.g. M) charging path control circuits {104(j), j=1, 2, . . . , M} and may for instance be applied or provided to the control terminal n3 of the i^{th} charging path control circuit 104(i), the i^{th} charging path control circuit 104(i) is the one which is coupled to the selected i^{th} output terminal OUT(i). One of ordinary skill in the art would understand that, in the examples as illustrated in FIG. 3A and FIG. 3B, for each i=1, 2, . . . , N, the logic high level in the plot of the waveform of the control signal 104(i)_G may indicate that the i^{th} charging path control circuit 104(i) is ON to enable the energy transfer/transmission path from the power output terminal BSTO to the selected i^{th} output terminal OUT(i), and the logic low level in the plot of the waveform of the control signal 104(i)_G may indicate that the i^{th} charging path control circuit 104(i) is OFF to disable the energy transfer/transmission path from the power output terminal BSTO to the selected i^{th} output terminal OUT(i). The control signal 104(i)_G may be provided or generated based on the charging control PWM signal PWM_C.

For instance, in an exemplary embodiment referring to FIG. 3A, for each i varying from 1 to N, the control signal 104(i)_G may, in response to the first transition edge (e.g. the rising edge) of the i^{th} charge pulse of the charging control PWM signal PWM_C with a predetermined on-delay time T_{don}, change from a first control voltage level or a first control logic level (e.g. logic low) to a second control voltage level or a second control logic level (e.g. logic high), i.e., generate a first transition edge for instance a rising edge of the control signal 104(i)_G to switch the i^{th} charging path control circuit 104(i) ON and enable the energy transfer/transmission path from the power output terminal BSTO to the selected i^{th} output terminal OUT(i), and the control signal 104(i)_G may, in response to the second transition edge (e.g. the falling edge) of the i^{th} charge pulse of the charging control PWM signal PWM_C with a predetermined off-delay time T_{doff}, change from the second control voltage level or the second control logic level (e.g. logic high) to the first control voltage level or the first control logic level (e.g. logic low), i.e., generate a second transition edge for instance a falling edge of the control signal 104(i)_G to switch the i^{th} charging path control circuit 104(i) OFF and disable the energy transfer/transmission path from the power output terminal BSTO to the selected i^{th} output terminal OUT(i). In this fashion, the selected i^{th} on time window Tₒₙ(i) of the i^{th} charging path control circuit 104(i) may be adaptively adjusted and flexibly controlled based on the charging control PWM signal PWM_C. One of ordinary skill in the art would understand that “in response to the first transition edge (e.g. the rising edge) of the i^{th} charge pulse of the charging control PWM signal PWM_C with a predetermined on-delay time T_{don1}” may refer to “in response to the moment or at the moment when the predetermined on-delay time T_{don1} has elapsed since the moment at the first transition edge (e.g. the rising edge) of the i^{th} charge pulse of the charging control PWM signal PWM_C”. Similarly, “in response to the second transition edge (e.g. the falling edge) of the i^{th} charge pulse of the charging control PWM signal PWM_C with a predetermined off-delay time T_{doff1}” may refer to “in response to the moment or at the moment when the predetermined off-delay time T_{doff1} has elapsed since the moment at the second transition edge (e.g. the falling edge) of the i^{th} charge pulse of the charging control PWM signal PWM_C”. The predetermined on-delay time T_{don1} may help to reduce the risk of

That is: still referencing to the exemplary illustration in FIG. 3A, in response to the first transition edge (e.g. the rising edge) of the 1^{st} charge pulse of the charging control PWM signal PWM_C with a predetermined on-delay time T_{don1} (i.e., at the moment when the predetermined on-delay time T_{don1} has elapsed since the moment at the first transition edge (e.g. the rising edge) of the 1^{st} charge pulse of the charging control PWM signal PWM_C), the control signal 104(1)_G for controlling the 1^{st} charging path control circuit 104(1) which is coupled to the selected 1^{st} output terminal OUT(1) that is adapted to be coupled to the first laser cell 101(1) may change from the first control logic level (e.g. logic low) to the second control logic level (e.g. logic high) to switch ON the 1^{st} charging path control circuit 104(1) and enable the energy transfer/transmission path from the power output terminal BSTO to the selected 1^{st} output terminal OUT(1); and in response to the second transition edge (e.g. the falling edge) of the 1^{st} charge pulse of the charging control PWM signal PWM_C with a predetermined off-delay time T_{doff1} (i.e., at the moment when the predetermined off-delay time T_{doff1} has elapsed since the moment at the second transition edge (e.g. the falling edge) of the 1^{st} charge pulse of the charging control PWM signal PWM_C), the control signal 104(1)_G may change from the second control logic level (e.g. logic high) to the first control logic level (e.g. logic low) to switch OFF the 1^{st} charging path control circuit 104(1) and disable the energy transfer/transmission path from the power output terminal BSTO to the selected 1^{st} output terminal OUT(1). It is obvious to one of ordinary skill in the art that descriptions analogous to those above for the control signal 104(1)_G apply to the control signals 104(2)_G, . . . , 104(N)_G and will not be repeated here.

For another instance, in an exemplary embodiment referring to FIG. 3B, for each i varying from 1 to N, the control signal 104(i)_G may, in response to the second transition edge (e.g. the falling edge) of the i^{th} charge pulse of the charging control PWM signal PWM_C with a predetermined on-delay time T_{don2}, change from a first control voltage level or a first control logic level (e.g. logic low) to a second control voltage level or a second control logic level (e.g. logic high), i.e., generate a first transition edge for instance a rising edge of the control signal 104(i)_G to switch the i^{th} charging path control circuit 104(i) ON and enable the energy transfer/transmission path from the power output terminal BSTO to the selected i^{th} output terminal OUT(i), and the control signal 104(i)_G may, in response to the first transition edge (e.g. the rising edge) of the next charge pulse, i.e., the (i+1)^{th} charge pulse of the charging control PWM signal PWM_C with a predetermined off-delay time T_{doff2}, change from the second control voltage level or the second control logic level (e.g. logic high) to the first control voltage level or the first control logic level (e.g. logic low), i.e., generate a second transition edge for instance a falling edge of the control signal 104(i)_G to switch the i^{th} charging path control circuit 104(i) OFF and disable the energy transfer/transmission path from the power output terminal BSTO to the selected i^{th} output terminal OUT(i). One of ordinary skill in the art would understand that “in response to the second transition edge (e.g. the falling edge) of the i^{th} charge pulse of the charging control PWM signal PWM_C with a predetermined on-delay time T_{don2}” may refer to “in response to the moment or at the moment when the predetermined on-delay time T_{don2} has elapsed since the moment at the second transition edge (e.g. the falling edge) of the i^{th} charge pulse of the charging control PWM signal PWM_C”. Similarly, “in response to the first transition edge (e.g. the rising edge) of the (i+1)^{th} charge pulse of the charging control PWM signal PWM_C with a predetermined off-delay time T_{doff2}” may refer to “in response to the moment or at the moment when the predetermined off-delay time T_{doff2} has elapsed since the moment at the first transition edge (e.g. the rising edge) of the (i+1)^{th} charge pulse of the charging control PWM signal PWM_C”.

One of ordinary skill in the art would understand that the charging unit 102 configured to provide the control signal 104(i)_G to control the i^{th} charging path control circuit 104(i) with changes in a control voltage level or a control logic level of the control signal 104(i)_G in response to the charging control PWM signal PWM_C as described with reference to the examples of FIG. 3A and FIG. 3B are just exemplary and not intended to be limiting, the charging unit 102 may be configured to provide the control signal 104(i)_G with the control voltage level or the control logic level of the control signal 104(i)_G changing in response to the charging control PWM signal PWM_C with various other alternative manners that cannot be exhaustively addressed here yet do not depart from the spirit and scope of various embodiments of the present disclosure, as long as the selected i^{th} on time window Tₒₙ(i) of the charging path control circuit that is coupled to the selected i^{th} output terminal OUT(i) can be controlled to begin at a moment located within the time duration when the controllable power switch 103 is kept ON for instance in response to the present i^{th} charge pulse of the charging control PWM signal PWM_C and to end at a moment no later than the moment when the controllable power switch 103 is switched OFF in response to the next (i+1)^{th} charge pulse of the charging control PWM signal PWM_C.

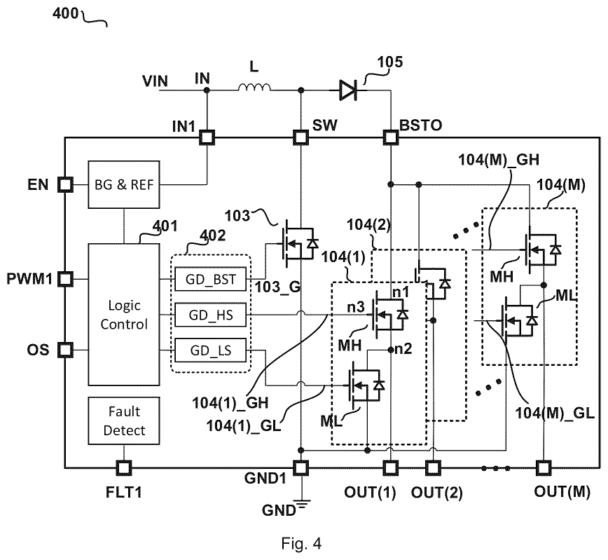

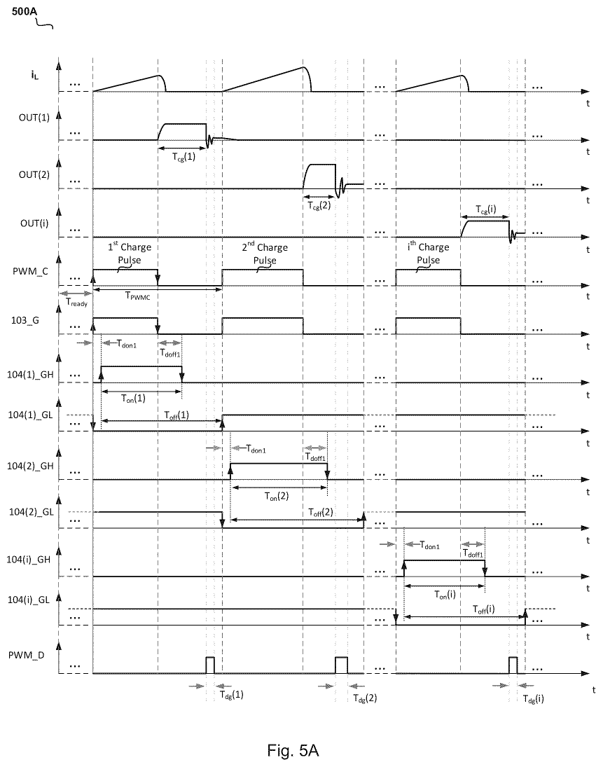

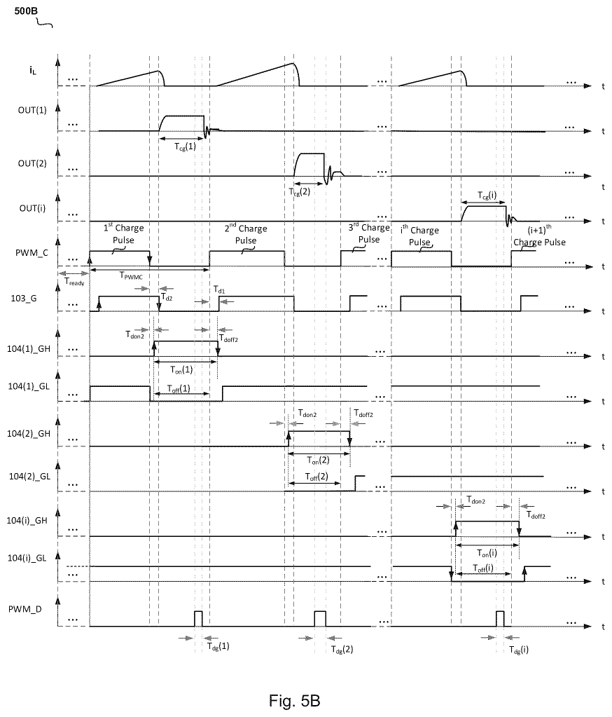

FIG. 4 illustrates an exemplary schematic diagram of a charging unit 400 in accordance with an alternative exemplary embodiment of the present disclosure. The charging unit 400 may be used to implement the charging unit 102 in FIG. 1 as an alternative embodiment. In the example of FIG. 4, for each j=1, 2, . . . , M, each one charging path control circuit, for instance the j^{th} charging path control circuit 104(j), of the corresponding second plurality of (e.g., M) charging path control circuits {104(j), j=1, 2, . . . , M} may include a high side switch MH and a low side switch ML. Each of the high side switch MH and the low side switch ML may comprise a controllable transistor such as a MOSFET or a DMOS or a GaN FET, or a SiC FET, or a BJT, or an IGBT, etc. For this exemplary embodiment, the j^{th} charging path control circuit 104(j) may be referred to as switched ON when the high side switch MH of the j^{th} charging path control circuit 104(j) is switched ON, and the j^{th} charging path control circuit 104(j) may be referred to as switched OFF when the high side switch MH of the j^{th} charging path control circuit 104(j) is switched OFF, for each j varying from 1 to M. FIG. 5A shows an illustrative waveform diagram 500A illustrating operation waveforms of several signals of the driving system 100 of FIG. 1 where the charging unit 102 employs the charging unit 400 as illustrated in FIG. 4 in accordance with an exemplary embodiment of the present invention. FIG. 5B shows an illustrative waveform diagram 500B illustrating operation waveforms of several signals of the driving system 100 of FIG. 1 where the charging unit 102 employs the charging unit 400 as illustrated in FIG. 4 in accordance with an alternative exemplary embodiment of the present invention. It can be seen from FIG. 5A and FIG. 5B, that in these examples the selected i^{th} output terminal OUT(i), which is coupled to the corresponding i^{th} laser cell 101(i) of the first plurality of (e.g. N) laser cells {101(i), i=1, 2, . . . , N}, may be switched ON during the i^{th} charging time window T_{cg}(i) located between an i^{th} charge pulse and an (i+1)^{th} charge pulse of the charging control PWM signal PWM_C, for each i=1, 2, . . . , N.

In the illustrative waveform diagrams shown in FIG. 5A and FIG. 5B, similarly as described with reference to FIG. 3A and FIG. 3B, the plot labeled with 103_G may represent an illustrative waveform of a control signal (also referenced by 103_G for simplicity and ease of understanding) for controlling the at least one controllable power switch 103, which may for instance be applied or provided to a gate control terminal of the least one controllable power switch 103 for the example where the at least one controllable power switch includes a field effect transistor (“FET”). One of ordinary skill in the art would understand that substantial descriptions related to the control signal 103_G made with reference to FIG. 3A and FIG. 3B are applicable to the examples of FIG. 5A and FIG. 5B and need not to be addressed again here for simplicity.

In the illustrative waveform diagrams shown in FIG. 5A and FIG. 5B, for each i=1, 2, . . . , N, the plot labeled with 104(i)_GH may represent an illustrative waveform of a high side control signal (also referenced by 104(i)_GH for simplicity and ease of understanding) for controlling the high side switch MH in the i^{th} charging path control circuit 104(i) among the second plurality of (e.g. M) charging path control circuits {104(j), j=1, 2, . . . , M} and may for instance be applied or provided to the control terminal n3 of the high side switch MH in the i^{th} charging path control circuit 104(i), the i^{th} charging path control circuit 104(i) is the one which is coupled to the selected i^{th} output terminal OUT(i). One of ordinary skill in the art would understand that, in this example, for each i=1, 2, . . . , N, the logic high level in the plot of the waveform of the high side control signal 104(i)_GH may indicate that the high side switch MH in the i^{th} charging path control circuit 104(i) is switched ON to enable the energy transfer/transmission path from the power output terminal BSTO to the selected i^{th} output terminal OUT(i), and the logic low level in the plot of the waveform of the high side control signal 104(i)_GH may indicate that the high side switch MH in the i^{th} charging path control circuit 104(i) is switched OFF to disable the energy transfer/transmission path from the power output terminal BSTO to the selected i^{th} output terminal OUT(i). The high side control signal 104(i)_GH may be provided or generated based on the charging control PWM signal PWM_C.

One of ordinary skill in the art would understand that substantial descriptions related to changes in a control voltage level or a control logic level of the control signal 104(i)_G made with reference to FIG. 3A and FIG. 3B in response to the charging control PWM signal PWM_C according to various exemplary embodiments are applicable to the high side control signal 104(i)_GH of the examples of FIG. 5A and FIG. 5B and need not to be addressed again here for simplicity. The i^{th} charging path control circuit 104(i) may be referred to as switched ON when the high side switch MH of the i^{th} charging path control circuit 104(i) is switched ON, and the i^{th} charging path control circuit 104(i) may be referred to as switched OFF when the high side switch MH of the i^{th} charging path control circuit 104(i) is switched OFF, for each i varying from 1 to N. In this fashion, the on time window Tₒₙ(i) of the i^{th} charging path control circuit 104(i) may be adaptively adjusted and flexibly controlled based on the charging control PWM signal PWM_C, for each i varying from 1 to N.

Continuing with the illustrative waveform diagrams shown in FIG. 5A and FIG. 5B, for each i=1, 2, . . . , N, the plot labeled with 104(i)_GL may represent an illustrative waveform of a low side control signal (also referenced by 104(i)_GL for simplicity and ease of understanding) for controlling the low side switch ML in the i^{th} charging path control circuit 104(i) among the second plurality of (e.g. M) charging path control circuits {104(j), j=1, 2, . . . , M} and may for instance be applied or provided to the control terminal of the low side switch ML in the i^{th} charging path control circuit 104(i), the i^{th} charging path control circuit 104(i) is the one which is coupled to the selected i^{th} output terminal OUT(i). One of ordinary skill in the art would understand that, in the examples as illustrated in FIG. 5A and FIG. 5B, for each i=1, 2, . . . , N, the logic high level in the plot of the waveform of the low side control signal 104(i)_GL may indicate that the low side switch ML in the i^{th} charging path control circuit 104(i) is switched ON to discharge energy from the selected i^{th} output terminal OUT(i) to the reference ground terminal GND1 of the charging unit 400, and the logic low level in the plot of the waveform of the low side control signal 104(i)_GL may indicate that the low side switch ML in the i^{th} charging path control circuit 104(i) is switched OFF to disable the energy discharge from the selected i^{th} output terminal OUT(i) to the reference ground terminal GND1 of the charging unit 400. The low side control signal 104(i)_GL may be provided or generated based on the charging control PWM signal PWM_C.

For instance, in an exemplary embodiment referring to FIG. 5A, for each i varying from 1 to N, the low side control signal 104(i)_GL may change, in response to the first transition edge (e.g. the rising edge) of the i^{th} charge pulse of the charging control PWM signal PWM_C, from a third control voltage level or a third control logic level (e.g., logic high) to a fourth control voltage level or a fourth control logic level (e.g., logic low), i.e., generate a first transition edge for instance a falling edge of the low side control signal 104(i)_GL to switch OFF the low side switch ML of the i^{th} charging path control circuit 104(i) and disable the energy discharge from the selected i^{th} output terminal OUT(i) to the reference ground terminal GND1 of the charging unit 400, and the low side control signal 104(i)_GL may change, in response to the first transition edge (e.g. the rising edge) of the (i+1)^{th} charge pulse of the charging control PWM signal PWM_C, from the fourth control voltage level or the fourth control logic level (e.g. logic low) to the third control voltage level or the third control logic level (e.g. logic high), i.e., generate a second transition edge for instance a rising edge of the low side control signal 104(i)_GL to switch ON the low side switch ML of the i^{th} charging path control circuit 104(i) and enable the energy discharge from the selected i^{th} output terminal OUT(i) to the reference ground terminal GND1 of the charging unit 400. This would advantageously help to discharge energy/charges left on the selected i^{th} output terminal OUT(i) to the reference ground terminal GND1 of the charging unit 400 before the i^{th} charging path control circuit 104(i) is switched ON or before the energy transfer/transmission path from the power output terminal BSTO to the selected i^{th} output terminal OUT(i) is enabled while making sure that energy discharge from the selected i^{th} output terminal OUT(i) to the reference ground terminal GND1 is disabled during the period from the moment when the first transition edge (e.g. the rising edge) of the i^{th} charge pulse of the charging control PWM signal PWM_C comes till the moment when the first transition edge (e.g. the rising edge) of the (i+1)^{th} charge pulse of the charging control PWM signal PWM_C comes. The predetermined on-delay time T_{don1} may help to reduce the risk of causing any damage due to the high side switch MH and the low side switch ML in the i^{th} charging path control circuit 104(i) being switched ON at the same time. The predetermined off-delay time T_{doff1} may help to reduce the risk of causing any damage due to the high side switch MH and the low side switch ML in the i^{th} charging path control circuit 104(i) being switched ON at the same time.

That is: still referencing to the exemplary illustration in FIG. 5A, in response to the first transition edge (e.g. the rising edge) of the 1^{st} charge pulse of the charging control PWM signal PWM_C (i.e., at the moment at the first transition edge (e.g., the rising edge) of the 1^{st} charge pulse of the charging control PWM signal PWM_C), the low side control signal 104(1)_GL for controlling the low side switch ML in the 1^{st} charging path control circuit 104(1) which is coupled to the selected 1^{st} output terminal OUT(1) that is adapted to be coupled to the first laser cell 101(1) may change from the third control logic level (e.g. logic high) to the fourth control logic level (e.g. logic low) to switch OFF the low side switch ML in the 1^{st} charging path control circuit 104(1) and disable or stop the energy discharge from the selected 1^{st} output terminal OUT(1) to the reference ground terminal GND1 of the charging unit 400; and in response to the first transition edge (e.g., the rising edge) of the 2^{nd} charge pulse of the charging control PWM signal PWM_C (i.e., at the moment at the first transition edge (e.g. the rising edge) of the 2^{nd} charge pulse of the charging control PWM signal PWM_C), the low side control signal 104(1)_GL may change from the fourth control logic level (e.g. logic low) to the third control logic level (e.g. logic high) to switch ON the low side switch ML in the 1^{st} charging path control circuit 104(1) and enable energy discharge from the selected 1^{st} output terminal OUT(1) to the reference ground terminal GND1 of the charging unit 400. It is obvious to one of ordinary skill in the art that descriptions analogous to those for the low side control signal 104(1)_GL here apply to the low side control signals 104(2)_GL, . . . , 104(N)_GL and will not be repeated here.

For another instance, in an exemplary embodiment referring to FIG. 5B, for each i varying from 1 to N, the low side control signal 104(i)_GL may change, in response to the second transition edge (e.g. the falling edge) of the i^{th} charge pulse of the charging control PWM signal PWM_C, from the third control voltage level or the third control logic level (e.g., logic high) to the fourth control voltage level or the fourth control logic level (e.g., logic low), i.e., generate the first transition edge for instance the falling edge of the low side control signal 104(i)_GL to switch OFF the low side switch ML of the i^{th} charging path control circuit 104(i) and disable the energy discharge from the selected i^{th} output terminal OUT(i) to the reference ground terminal GND1 of the charging unit 400, and the low side control signal 104(i)_GL may change, in response to the first transition edge (e.g. the rising edge) of the (i+1)^{th} charge pulse of the charging control PWM signal PWM_C, from the fourth control voltage level or the fourth control logic level (e.g. logic low) to the third control voltage level or the third control logic level (e.g. logic high), i.e., generate a second transition edge for instance a rising edge of the low side control signal 104(i)_GL to switch ON the low side switch ML of the i^{th} charging path control circuit 104(i) and enable the energy discharge from the selected i^{th} output terminal OUT(i) to the reference ground terminal GND1 of the charging unit 400. This would advantageously help to discharge energy/charges left on the selected i^{th} output terminal OUT(i) to the reference ground terminal GND1 of the charging unit 400 before the i^{th} charging path control circuit 104(i) is switched ON or before the energy transfer/transmission path from the power output terminal BSTO to the selected i^{th} output terminal OUT(i) is enabled while making sure that energy discharge from the selected i^{th} output terminal OUT(i) to the reference ground terminal GND1 is disabled at least during a period from the moment when the second transition edge (e.g. the falling edge) of the i^{th} charge pulse of the charging control PWM signal PWM_C comes till the moment when the first transition edge (e.g. the rising edge) of the (i+1)^{th} charge pulse of the charging control PWM signal PWM_C comes. The predetermined on-delay time T_{don2} may help to reduce the risk of causing any damage due to the high side switch MH and the low side switch ML in the i^{th} charging path control circuit 104(i) being switched ON at the same time. The predetermined off-delay time T_{doff2} may help to reduce the risk of causing any damage due to the high side switch MH and the low side switch ML in the i^{th} charging path control circuit 104(i) being switched ON at the same time.

That is: still referencing to the exemplary illustration in FIG. 5B, in response to the second transition edge (e.g. the falling edge) of the 1^{st} charge pulse of the charging control PWM signal PWM_C (i.e., at the moment at the second transition edge (e.g., the falling edge) of the 1^{st} charge pulse of the charging control PWM signal PWM_C), the low side control signal 104(1)_GL for controlling the low side switch ML in the 1^{st} charging path control circuit 104(1) which is coupled to the selected 1^{st} output terminal OUT(1) that is adapted to be coupled to the first laser cell 101(1) may change from the third control logic level (e.g. logic high) to the fourth control logic level (e.g. logic low) to switch OFF the low side switch ML in the 1^{st} charging path control circuit 104(1) and disable or stop the energy discharge from the selected 1^{st} output terminal OUT(1) to the reference ground terminal GND1 of the charging unit 400; and in response to the first transition edge (e.g., the rising edge) of the 2^{nd} charge pulse of the charging control PWM signal PWM_C (i.e., at the moment at the first transition edge (e.g. the rising edge) of the 2^{nd} charge pulse of the charging control PWM signal PWM_C), the low side control signal 104(1)_GL may change from the fourth control logic level (e.g. logic low) to the third control logic level (e.g. logic high) to switch ON the low side switch ML in the 1^{st} charging path control circuit 104(1) and enable energy discharge from the selected 1^{st} output terminal OUT(1) to the reference ground terminal GND1 of the charging unit 400. It is obvious to one of ordinary skill in the art that descriptions analogous to those for the low side control signal 104(1)_GL here apply to the low side control signals 104(2)_GL, . . . , 104(N)_GL and will not be repeated here.

One of ordinary skill in the art would understand that the charging unit 400 configured to provide the low side control signal 104(i)_GL to control the low side switch ML of the i^{th} charging path control circuit 104(i) with changes in a control voltage level or a control logic level of the control signal 104(i)_GL in response to the charging control PWM signal PWM_C as described with reference to the examples of FIG. 5A and FIG. 5B are just exemplary and not intended to be limiting, the charging unit 400 may be configured to provide the low side control signal 104(i)_GL with various other alternative manners that cannot be exhaustively addressed here yet do not depart from the spirit and scope of various embodiments of the present disclosure, as long as the low side control signal 104(i)_GL at least keeps the low side switch ML of the i^{th} charging path control circuit 104(i) OFF during a period Toff(i) from the moment when the high side switch MH of the i^{th} charging path control circuit 104(i) is turned ON based on the i^{th} charge pulse of the charging control PWM signal PWM_C till the moment when the first transition edge (e.g. the rising edge) of the (i+1)^{th} charge pulse of the charging control PWM signal PWM_C comes to ensure that energy discharge from the selected i^{th} output terminal OUT(i) to the reference ground terminal GND1 is disabled during the period Toff(i), and the low side control signal 104(i)_GL at least switch the low side switch ML of the i^{th} charging path control circuit 104(i) ON for a predetermined time window located outside the period Toff(i) to discharge energy/charges left on the selected i^{th} output terminal OUT(i) to the reference ground terminal GND1 of the charging unit 400.

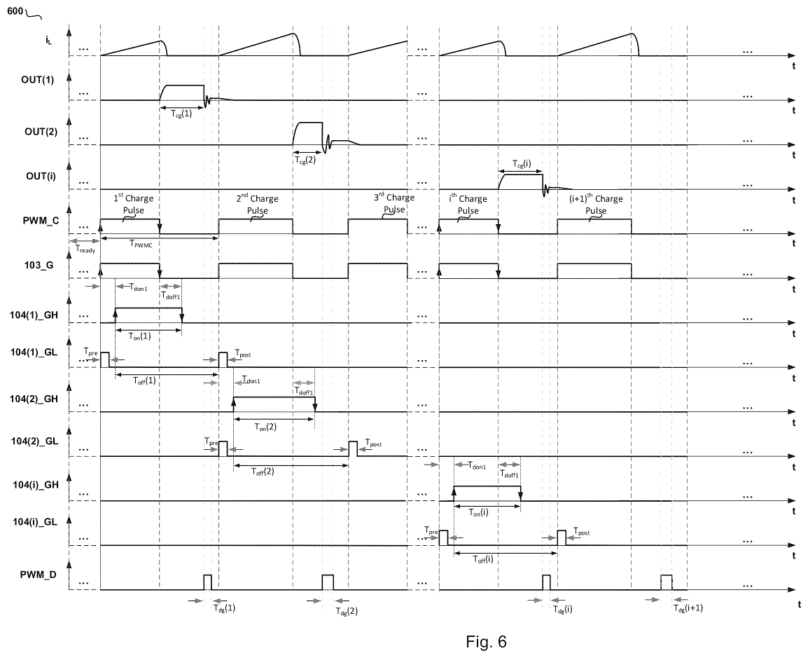

To provide another example, FIG. 6 shows an illustrative waveform diagram illustrating operation waveforms of several signals of the driving system 100 of FIG. 1 where the charge unit 102 employs the charging unit 400 as illustrated in FIG. 4 in accordance with an alternative exemplary embodiment of the present invention. Difference of the exemplary embodiment shown in FIG. 6 from the exemplary embodiments shown in FIG. 5A and FIG. 5B may lie in one aspect that the control logics for the low side control signals 104(i)_GL may be changed. For instance, in the example of FIG. 6, for each i varying from 1 to N, in response to the first transition edge (e.g. the rising edge) of the i^{th} charge pulse of the charging control PWM signal PWM_C, the low side control signal 104(i)_GL may be adapted to provide a predetermined pre-discharge time window Tₚᵣₑ, during which the low side control signal 104(i)_GL may have the third control logic level (e.g. logic high) to control the low side switch ML in the i^{th} charging path control circuit 104(i) being ON and be adapted to enable energy discharge from the selected i^{th} output terminal OUT(i) to the reference ground terminal GND1 of the charging unit 400. In an embodiment, for each i varying from 1 to N, the low side control signal 104(i)_GL may be adapted to generate a pre-discharge pulse having a predetermined pre-discharge pulse width Tₚᵣₑ to define the predetermined pre-discharge time window Tₚᵣₑ. For each i varying from 1 to N, the low side control signal 104(i)_GL may be adapted to control the low side switch ML in the i^{th} charging path control circuit 104(i) being OFF outside the predetermined pre-discharge time window Tₚᵣₑ. In this fashion, energy/charges left on the selected i^{th} output terminal OUT(i) may be discharged before the high side switch MH in the i^{th} charging path control circuit 104(i) is switched ON or before the energy transfer/transmission path from the power output terminal BSTO to the selected i^{th} output terminal OUT(i) is enabled, which may advantageously help to improve control accuracy of the charging unit 400. The predetermined pre-discharge time window Tₚᵣₑ may be shorter than the predetermined on-delay time T_{don1}.

In an embodiment, for instance, still referring to FIG. 6, for each i varying from 1 to N, in response to the first transition edge (e.g. the rising edge) of the (i+1)^{th} charge pulse of the charging control PWM signal PWM_C, the low side control signal 104(i)_GL may be adapted to provide a predetermined post-discharge time window Tₚₒₛₜ, during which the low side control signal 104(i)_GL may have the third control logic level (e.g. logic high) and may be adapted to control the low side switch ML in the i^{th} charging path control circuit 104(i) being ON and enable energy discharge from the selected i^{th} output terminal OUT(i) to the reference ground terminal GND1 of the charging unit 400. In an embodiment, for each i varying from 1 to N, the low side control signal 104(i)_GL may be adapted to generate a post-discharge pulse having a predetermined post-discharge pulse width Tₚₒₛₜ to define the predetermined post-discharge time window Tₚₒₛₜ. For each i varying from 1 to N, the low side control signal 104(i)_GL may be adapted to control the low side switch ML in the i^{th} charging path control circuit 104(i) being OFF outside the predetermined post-discharge time window Tₚₒₛₜ. This would advantageously further help to discharge energy/charges left on the selected i^{th} output terminal OUT(i) before the high side switch MH in the i^{th} charging path control circuit 104(i) is switched ON next time or before the energy transfer/transmission path from the power output terminal BSTO to the selected i^{th} output terminal OUT(i) is enabled next time, which may advantageously help to improve control accuracy of the charging unit 400. The predetermined post-discharge time window Tₚₒₛₜ may be shorter than the predetermined on-delay time T_{don1}.

In an embodiment, for each i varying from 1 to N, the low side control signal 104(i)_GL may be adapted to provide both the predetermined pre-discharge time window Tₚᵣₑ and the predetermined post-discharge time window Tₚₒₛₜ respectively in response to the first transition edge (e.g. the rising edge) of the i^{th} charge pulse of the charging control PWM signal PWM_C and the first transition edge (e.g. the rising edge) of the (i+1)^{th} charge pulse of the charging control PWM signal PWM_C. During both the predetermined pre-discharge time window Tₚᵣₑ and the predetermined post-discharge time window Tₚₒₛₜ, the low side control signal 104(i)_GL may be adapted to control the low side switch ML in the i^{th} charging path control circuit 104(i) being ON and enable energy discharge from the selected i^{th} output terminal OUT(i) to the reference ground terminal GND1 of the charging unit 400, for each i varying from 1 to N. For each i varying from 1 to N, the low side control signal 104(i)_GL may further be adapted to control the low side switch ML in the i^{th} charging path control circuit 104(i) being OFF outside predetermined pre-discharge time window Tₚᵣₑ and the predetermined post-discharge time window Tₚₒₛₜ.

Person of ordinary skill in the art would understand that embodiments of the charging unit 102 may not be limited to those examples described above in connection with FIG. 1 to FIG. 6.

In accordance with an exemplary embodiment, the charging unit 102 may further include a logic control circuit and a driving circuitry block. The logic control circuit and the driving circuitry block may together be adapted to be configured to control the at least one controllable power switch 103 and the second plurality of (e.g., M) charging path control circuits {104(j), j=1, 2, . . . , M} based on the charging control PWM signal PWM_C. In the example of FIG. 4, a logic control circuit 401 and a driving circuitry block 402 are exemplarily illustrated.

In accordance with an exemplary embodiment, the charging unit 102 may further include a fourth input terminal (e.g., a chip-selection terminal) OS. The fourth input terminal OS may be adapted to be configured to receive for instance a chip-selection signal OS_C. The charging unit 102 may be adapted to be configured to activate or deactivate operation of the at least one controllable power switch 103 and the second plurality of (e.g., M) charging path control circuits 104(1), 104(2), . . . , 104(M) in response to the chip-selection signal OS_C received at the fourth input terminal OS. In an example, when the charging unit 102 activates operation of the at least one controllable power switch 103 and the second plurality of (e.g., M) charging path control circuits 104(1), 104(2), . . . , 104(M), it may mean that the at least one controllable power switch 103 and the second plurality of (e.g., M) charging path control circuits 104(1), 104(2), . . . , 104(M) are operable or are able to process signals or fulfill their functionalities. When the charging unit 102 deactivates operation of the at least one controllable power switch 103 and the second plurality of (e.g., M) charging path control circuits 104(1), 104(2), . . . , 104(M), it may mean that when the charging unit 102 deactivates operation of the at least one controllable power switch 103 and the second plurality of (e.g., M) charging path control circuits 104(1), 104(2), . . . , 104(M) are inoperable or disabled. In an example, the charging unit 102 may be configured to activate operation of the at least one controllable power switch 103 and the second plurality of (e.g., M) charging path control circuits 104(1), 104(2), . . . , 104(M) when the chip-selection signal OS_C received at the fourth input terminal OS is at a first logic state (e.g. logic high) or when the chip-selection signal OS_C reaches or goes higher than an activation threshold, and may be further configured to deactivate operation of the at least one controllable power switch 103 and the second plurality of (e.g., M) charging path control circuits 104(1), 104(2), . . . , 104(M) when the chip-selection signal OS_C received at the fourth input terminal OS is at a second logic state (e.g. logic low) or when the chip-selection signal OS_C falls below the activation threshold. Herein after, the charging unit 102 may be referred to as being ON if both the charging unit 102 is enabled to be operable and the at least one controllable power switch 103 and the second plurality of (e.g., M) charging path control circuits {104(j), j=1, 2, . . . , M} are activated (operable), and the charging unit 102 may be referred to as being OFF if either the charging unit 102 is disabled to be inoperable or the at least one controllable power switch 103 and the second plurality of (e.g., M) charging path control circuits {104(j), j=1, 2, . . . , M} are deactivated (inoperable).

In accordance with an embodiment, operability of the charging unit 102, the at least one controllable power switch 103 and the second plurality of charging path control circuits {104(j), j=1, 2, . . . , M} in relation to the logic status of the enable signal EN_C and the chip-selection signal OS_C may be as shown in the table below.

| | | | At Least One | Charging Path Control |
|---|---|---|---|---|
| | | | Controllable | Circuits {104(j), j = 1, |
| EN_C | OS_C | Charging Unit 102 | Power Switch 103 | 2, . . . , M} |
| Logic Low | N/A | Disabled (OFF) | Inoperable | Inoperable |
| Logic High | Logic Low | Enabled (yet OFF) | Inoperable | Inoperable |
| Logic High | Logic High | Enabled (ON) | Operable | Operable |

In accordance with an exemplary embodiment, referring back to FIG. 1, the driving system 100 may further include a corresponding first plurality of (e.g. N) capacitive energy storage devices CR(1), CR(2), . . . , CR(N) corresponding to the first plurality of (e.g. N) laser cells {101(i), i=1, 2, . . . , N}. Herein after, the corresponding first plurality of (e.g. N) capacitive energy storage devices CR(1), CR(2), . . . , CR(N) may be referred to as or represented by {CR(i), i=1, 2, . . . , N}. In other words, the corresponding first plurality of (e.g., N) capacitive energy storage devices {CR(i), i=1, 2, . . . , N} may match with the first plurality of (e.g., N) laser cells {101(i), i=1, 2, . . . , N} at least in amount. In an example, the corresponding first plurality of (e.g. N) capacitive energy storage devices {CR(i), i=1, 2, . . . , N} may comprise capacitors such as 0402 NP0 capacitors or other types of capacitors that are compatible with and can meet the application requirements. In an embodiment, the corresponding first plurality of (e.g., N) capacitive energy storage devices {CR(i), i=1, 2, . . . , N} may be coupled to the first plurality of (e.g., N) laser cells {101(i), i=1, 2, . . . , N} in a one-to-one correspondence manner. That is to say, each one capacitive energy storage device of the corresponding first plurality of (e.g., N) capacitive energy storage devices {CR(i), i=1, 2, . . . , N} may be coupled to a corresponding one laser cell (e.g., a VCSEL cell) of the first plurality of (e.g., N) laser cells {101(i), i=1, 2, . . . , N}. Or in other words, for each i=1, 2, . . . , N, each one capacitive energy storage device, for instance the i^{th} capacitive energy storage device CR(i), of the corresponding first plurality of (e.g., N) capacitive energy storage devices {CR(i), i=1, 2, . . . , N} may be coupled to the corresponding one laser cell, for instance the i^{th} laser cell 101(i) of the first plurality of (e.g., N) laser cells {101(i), i=1, 2, . . . , N}. For instance, for each i from 1 to N, a first terminal of the i^{th} capacitive energy storage device CR(i) may be coupled to the first terminal (e.g., anode) of the corresponding i^{th} laser cell 101(i) and a second terminal of the i^{th} capacitive energy storage device CR(i) may be connected to the reference ground GND of the driving system 100. Herein the integer variable N is also used to describe or represent the total number of capacitive energy storage devices {CR(i), i=1, 2, . . . , N} that the driving system 100 may include in the present disclosure for ease of reference and understanding. In other words, the total number of the capacitive energy storage devices {CR(i), i=1, 2, . . . , N} that the driving system 100 may include should be matching with or identical to the total number of the laser cells {101(i), i=1, 2, . . . , N} that the integrated semiconductor laser device 101 may include. For instance, in the example where the integrated semiconductor laser device 101 has 28 laser cells {101(i), i=1, 2, . . . , 28}, the driving system 100 may include 28 capacitive energy storage devices {CR(i), i=1, 2, . . . , 28} corresponding to the 28 laser cells {101(i), i=1, 2, . . . , 28} and respectively coupled to the 28 laser cells {101(i), i=1, 2, . . . , 28}.

In accordance with an exemplary embodiment, the driving system 100 may further include a discharging unit 106. The discharging unit 106 may be adapted to be configured to sink or discharge energy from the integrated semiconductor laser device 101 to the reference ground GND of the driving system 100. In an exemplary embodiment, the discharging unit 106 may be adapted to be configured to sink or discharge energy from the integrated semiconductor laser device 101 to the reference ground GND with a predetermined pattern in response to a discharging control PWM signal PWM_D, which may be customer or user programmable.

In accordance with an exemplary embodiment, the discharging unit 106 may be configured to sink or discharge energy from the integrated semiconductor laser device 101 to the reference ground GND during a discharging time window (for instance, referenced as an i^{th} discharging time window T_{dg}(i)) following the end of each of the i^{th} charging time window T_{cg}(i), for each i=1, 2, . . . , N. That is to say, the driving system 100 or the discharging unit 106 may be adapted to operate with a first plurality of (e.g., N) discharging time windows corresponding to the first plurality of (e.g., N) laser cells {101(i), i=1, 2, . . . , N} or the first plurality of (e.g., N) capacitive energy storage devices {CR(i), i=1, 2, . . . , N}. Herein after, the first plurality of (e.g., N) discharging time windows T_{dg}(1), T_{dg} (2), . . . , T_{dg}(N) may be referred to as or represented by {T_{dg}(i), i=1, 2, . . . , N}. Herein N is an integer variable no less than 1 and may be set or determined by customers/users in practical applications depending on real application requirements. In an example, the discharging unit 106 may be configured to sink or discharge energy from the integrated semiconductor laser device 101 to the reference ground GND during an i^{th} discharging time window T_{dg}(i) located between the i^{th} charging time window T_{cg}(i) and the (i+1)^{th} charging time window T_{cg}(i+1), for each i=1, 2, . . . , N. In an alternative example, the discharging unit 106 may be configured to sink or discharge energy from the integrated semiconductor laser device 101 to the reference ground GND during an i^{th} discharging time window T_{dg}(i) located between the i^{th} charging time window T_{cg}(i) and the (i+1)^{th} charge pulse of the charging control PWM signal PWM_C, for each i=1, 2, . . . , N. In accordance with an exemplary embodiment, the discharging control PWM signal PWM_D may have a plurality of pulses adapted to be used or configured to control the first plurality of (e.g., N) discharging time windows {T_{dg}(i), i=1, 2, . . . , N}. In an exemplary embodiment, the first discharging time window T_{dg}(1), the second discharging time window T_{dg}(2), . . . , the i^{th} discharging time window T_{dg}(i), and so on may be respectively controlled or determined by a sequence of consecutive pulses of the discharging control PWM signal PWM_D. But this is just to provide an example and not intended to be limiting.

In an exemplary embodiment, the discharging unit 106 may have a first input terminal, for instance an energy input terminal DRAIN. The first input terminal DRAIN of the discharging unit 106 may be coupled to the integrated semiconductor laser device 101. In an example, the first input terminal DRAIN of the discharging unit 106 may be coupled to second terminals of the first plurality of (e.g., N) laser cells {101(i), i=1, 2, . . . , N} of the integrated semiconductor laser device 101.

In accordance with an exemplary embodiment, the discharging unit 106 may further include a reference ground terminal GND2. The discharging unit 106, including all the sub-circuits or sub-elements that the discharging unit 106 may comprise, may be configured to use a reference ground potential at the reference ground terminal GND2 as a ground potential of the discharging unit 106. In an example, the reference ground terminal GND2 of the discharging unit 106 may be connected to the reference ground GND of the driving system 100.

In accordance with an exemplary embodiment, the discharging unit 106 may further include a second input terminal, for instance a PWM terminal PWM2. The second input terminal PWM2 of the discharging unit 106 may be adapted to be configured to receive for instance the discharging control PWM signal PWM_D. Although in the illustrative example of FIG. 1, the second input terminal PWM2 of the discharging unit 106 is shown as a single terminal, this is not intended to be limiting.

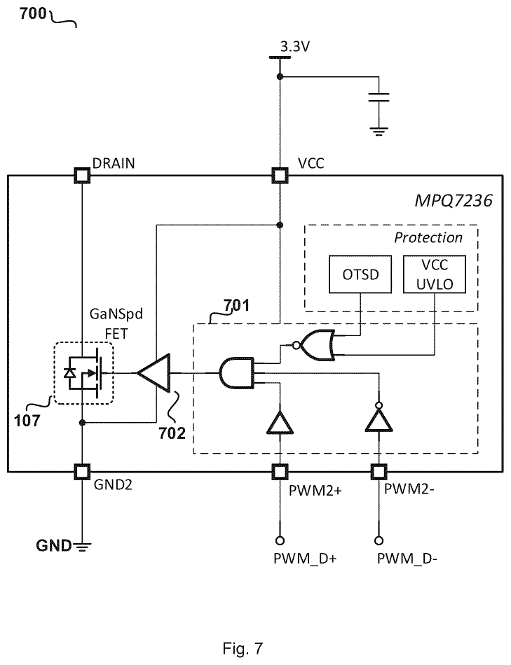

In accordance with an alternative exemplary embodiment, the second input terminal (e.g., the PWM terminal) PWM2 of the discharging unit 106 may include a second positive input terminal PWM2+ and a second negative input terminal PWM2−, as shown in FIG. 7. FIG. 7 illustrates an exemplary schematic diagram of a discharging unit 700 in accordance with an exemplary embodiment of the present disclosure. The discharging unit 700 may be used to implement the discharging unit 106 in FIG. 1 as an alternative embodiment. The second positive input terminal PWM2+ of the discharging unit 106 may be adapted to be configured to receive for instance a first discharging control signal PWM_D+. The second negative input terminal PWM2− of the discharging unit 106 may be adapted to be configured to receive for instance a second discharging control signal PWM_D−. For this situation, the first discharging control signal PWM_D+ and the second discharging control signal PWM_D− define or determine the discharging control PWM signal PWM_D. One of ordinary skill in the art would understand that using the first discharging control signal PWM_D+ and the second discharging control signal PWM_D− may advantageously make the first plurality of (e.g., N) discharging time windows {T_{dg}(i), i=1, 2, . . . , N} more flexible and easily to be adjusted or controlled. For instance, each of the plurality of pulses of the discharging control PWM signal PWM_D may have a narrower pulse width (representing a narrower or shorter discharging time window) than it could be realized without using the first discharging control signal PWM_D+ and the second discharging control signal PWM_D−. Narrower pulse width of the discharging control PWM signal PWM_D or narrower discharging time window may be a practical need for laser driving applications.

In accordance with an exemplary embodiment, the discharging unit 106 may further include a discharging path switching circuit 107. The discharging path switching circuit 107 may be adapted to be configured to perform ON and OFF switching in response to the discharging control PWM signal PWM_D or in response to the first discharging control signal PWM_D+ and the second discharging control signal PWM_D−. The discharging path switching circuit 107 may be configured to enable energy transfer/transmission from the first terminal DRAIN of the discharging unit 106 to the reference ground terminal GND2 of the discharging unit 106 once being switched ON and may further be configured to stop or cut off the energy transfer/transmission from the first terminal DRAIN to the reference ground terminal GND2 once being switched OFF. Energy transfer/transmission may be in the form of for example voltage or current or electrical charges etc. In accordance with an exemplary embodiment, the discharging path switching circuit 107 may be switched ON during each of the first plurality of (e.g., N) discharging time windows, i.e., during the i^{th} discharging time window T_{dg}(i) for each i=1, 2, . . . , N. The discharging path switching circuit 107 may be OFF outside the first plurality of (e.g., N) discharging time windows {T_{dg}(i), i=1, 2, . . . , N}.

In accordance with an exemplary embodiment, the discharging path switching circuit 107 may include a controllable transistor. The controllable transistor may have a first terminal coupled to the first terminal DRAIN of the discharging unit 106, a second terminal coupled to the reference ground terminal GND2 of the discharging unit 106, and a control terminal adapted to be configured to receive a control signal. In the example of FIG. 1, the discharging path switching circuit 107 is illustrated to include a metal oxide field effect transistor (MOSFET). However, this is just to provide an example and not intended to be limiting. In other embodiments, the discharging path switching circuit 107 may alternatively include other types of controllable transistor such as a DMOS or a GaN FET, or a SiC FET, or a BJT, or an IGBT or any combination thereof, etc.

In accordance with an exemplary embodiment, the discharging unit 106 may further include a control circuit adapted to be configured to control the discharging path switching circuit 107. In an embodiment, the discharging unit 106 may further include a driver circuit coupled between the control circuit and the discharging path switching circuit 107. The driver circuit may be adapted to be configured to drive a control terminal of the discharging path switching circuit 107 based on an output signal from the control circuit. For instance, the driver circuit may be adapted to provide the control signal to the control terminal of the controllable transistor of the discharging path switching circuit 107. In the example of FIG. 7, a control circuit 701 and a driver circuit 702 are exemplarily illustrated.

In accordance with an exemplary embodiment, the discharging unit 106 may further include a third input terminal for instance a discharging unit power supply terminal VCC. The discharging unit power supply terminal VCC may be adapted to receive a supply voltage suitable for providing operation power to the discharging unit 106. For instance, in the example of FIG. 7, a supply voltage of 3.3V is provided to the discharging unit power supply terminal VCC. However, this is just to provide an example and not intended to be limiting.

In accordance with an exemplary embodiment, the discharging unit 106 may further include a fault reporting terminal FLT2 adapted to be configured to report any fault status such as under voltage (VCC UVLO), over temperature (OTSD), and so on. The discharging unit 106 may further include protection circuits adapted to implement for under voltage (VCC UVLO), over temperature (OTSD) and/or other fault protections as exemplarily and illustratively shown in the example of FIG. 7. If applications do not require the discharging unit 106 to provide fault reporting, the fault reporting terminal FLT2 may be omitted.

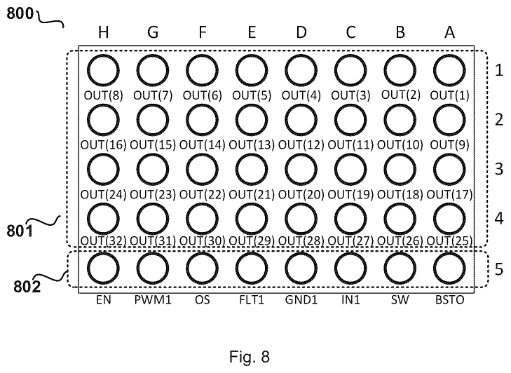

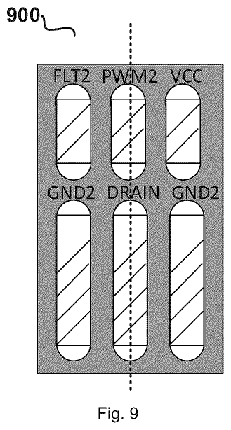

In accordance with an exemplary embodiment, the charging unit 102 may be integrated in or on an integrated circuit (“IC”) die or chip and may be wrapped in a package 800 as illustratively shown in FIG. 8. In an example, the IC die or chip with the charging unit 102 integrated therein may include a flip chip die or chip and accordingly the package 800 may be implemented as a flip chip package. The second plurality of (e.g., M) output terminals {OUT(j), j=1, 2, . . . , M}, for instance in the form of a corresponding second plurality of (e.g., M) electrically conductive pads, of the charging unit 102 may be arranged in an output terminal matrix 801 of X by Y and disposed on an active surface of the package 800. The variables X and Y are integers no less than 1 and respectively represent a total number of rows and a total number of columns of the output terminal matrix 801, and meet the equation X*Y=M. For instance, in the example of FIG. 8, the package 800 is illustrated to include a charging unit 102 having 32 output terminals {OUT(j), j=1, 2, . . . , 32} arranged in an output terminal matrix 801 of 4 by 8. That is to say, in this particular example, M=32, X=4 and Y=8. In the example of FIG. 8, other terminals such as the first input terminal (e.g. a power supply terminal) IN1, the second input terminal (e.g. an enable terminal) EN, the third input terminal (e.g. a PWM terminal) PWM1, the reference ground terminal GND1, the fourth input terminal (e.g. a selection terminal) OS, the indication terminal (e.g. a fault indication terminal) FLT1, the switch terminal SW, the power output terminal BSTO etc. of the charging unit 102 may be arranged in one or more other-terminal arrays being disposed on the active surface of the package 800. In accordance with an exemplary embodiment, the one or more other-terminal arrays may be in the form of a plurality of electrically conductive pads arrays. In accordance with an exemplary embodiment, the one or more other-terminal arrays may be placed at one or more sides of the output terminal matrix 801. In the example of FIG. 8, it is exemplarily illustrated that the other terminals of the charging unit 102 is arranged in an other-terminal array 802 placed at a bottom side of the output terminal matrix 801. One of ordinary skill in the art would understand that this is just to provide an example and not intended to be limiting.

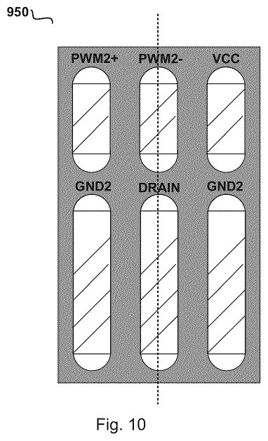

In accordance with an exemplary embodiment, the discharging unit 106 may be integrated in or on an integrated circuit (“IC”) die or chip and may be wrapped in a package 900 as illustratively shown in FIG. 9. In an example, the IC die or chip with the discharging unit 106 integrated therein may include a flip chip die or chip and accordingly the package 900 may be implemented as a flip chip package. The first input terminal (e.g., the energy input terminal) DRAIN, the reference ground terminal GND2, the second input terminal (e.g., the PWM terminal) PWM2, the third input terminal (e.g., the discharging unit power supply terminal) VCC, and the fault reporting terminal FLT2 (if any) of the discharging unit 106 may be implemented in the form of a corresponding plurality of electrically conductive pads and may be disposed on an active surface of the package 900. In an embodiment, for the reference ground terminal GND2, at least two electrically conductive pads may be formed and arranged symmetrically on both sides of a middle line (indicated by a dash line in FIG. 9) of the discharging unit 106 wrapped in the package 900 to enhance its energy discharging ability.

FIG. 10 illustrates a package 950 including the discharging unit 700 integrated in or on an integrated circuit die/chip in accordance with an embodiment of the present invention. Substantial descriptions made with reference to FIG. 9 for the discharging unit 106 in the package 900 may apply to the discharging unit 700 wrapped in the package 950 since as mentioned previously, the discharging unit 700 can be considered as an implementation to the discharging unit 106. In the example of FIG. 10, the second input terminal PWM is embodied as the second positive input terminal PWM2+ and the second negative input terminal PWM2− and the fault reporting terminal FLT2 may be omitted on the active surface of the package 950.

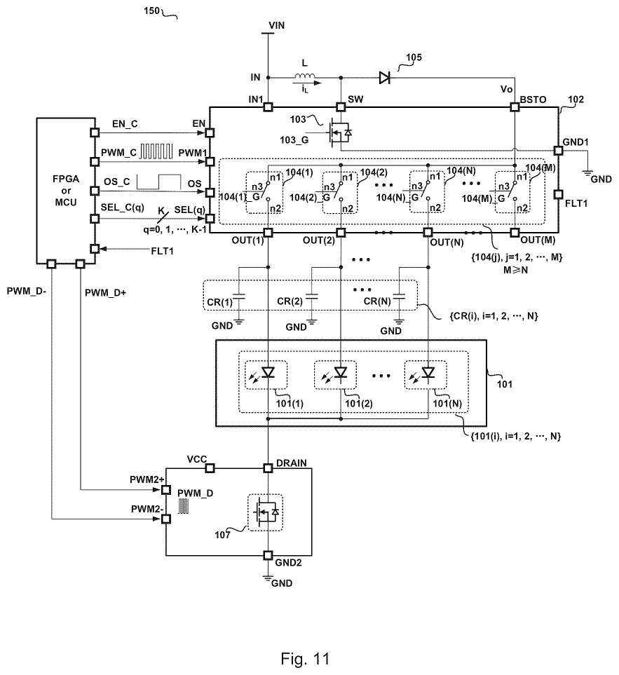

FIG. 11 illustrates a schematic diagram of a driving system 150 in accordance with an embodiment of the present invention. The driving system 150 may be different from the driving system 100 in one aspect that the charging unit 102 may further include a plurality of (e.g., represented by an integer variable K) selection terminals SEL(0), SEL(1), . . . , SEL(K−1). Herein after, the plurality of (e.g., K) selection terminals SEL(0), SEL(1), . . . , SEL(K−1) may be referred to as or represented by {SEL(q), q=0, 1, . . . , K−1}. Herein K is an integer variable and represents the total number of selection terminals {SEL(q), q=0, 1, . . . , K−1} that the charging unit 102 may include. That is to say, the index q is a variable traverses the integers from 0 to K−1. The plurality of (e.g., K) selection terminals {SEL(q), q=0, 1, . . . , K−1} may be adapted to be configured to control or program the predetermined pattern or order to switch ON or switch OFF the second plurality of (e.g., M) output terminals {OUT(j), j=1, 2, . . . , M}. In an embodiment, the plurality of (e.g., K) selection terminals {SEL(q), q=0, 1, . . . , K−1} may be adapted to be configured to control the predetermined pattern or order to switch ON or switch OFF the second plurality of (e.g., M) charging path control circuits {104(j), j=1, 2, . . . , M} of the charging unit 102. That is to say, unlike the examples described with reference to FIG. 3A, FIG. 3B, FIG. 5A, FIG. 5B and FIG. 6, where the second plurality of (e.g., M) output terminals {OUT(j), j=1, 2, . . . , M} may be switched ON successively in sequence (i.e., following the order from OUT(1) to OUT(M)) according to the successive charge pulses of the charging control PWM signal PWM_C, in the example of FIG. 11, the ON and OFF switching pattern or order of the selected i^{th} output terminal OUT(i) may be controlled or programmed through the plurality of (e.g., K) selection terminals {SEL(q), q=0, 1, . . . , K−1}. In an embodiment, to make the ON and OFF switching pattern or switching order of each of the second plurality of (e.g., M) output terminals {OUT(j), j=1, 2, . . . , M}programmable/controllable, the number K of the plurality of selection terminals may satisfy 2^{K}≥M.

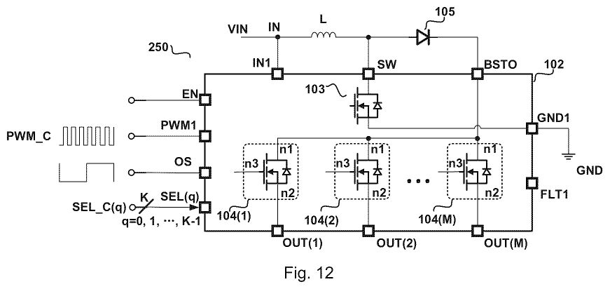

FIG. 12 illustrates an exemplary schematic diagram of a charging unit 250 which may be used to implement the charging unit 102 of FIG. 11 as an alternative embodiment. Compared to the charging unit 200 as exemplarily illustrated in FIG. 2, the charging unit 250 illustrated in the example of FIG. 12 further includes the plurality of (e.g., K) selection terminals {SEL(q), q=0, 1, . . . , K−1}. One of ordinary skill in the art would understand that substantial descriptions related to the embodiments of FIG. 1 and FIG. 2 may apply to the embodiments of FIG. 11 and FIG. 12 except that in the embodiments of FIG. 11 and FIG. 12, the ON and OFF switching pattern or switching order of each of the second plurality of (e.g., M) output terminals {OUT(j), j=1, 2, . . . , M} may be controlled/programmed via the plurality of (e.g., K) selection terminals {SEL(q), q=0, 1, . . . , K−1}.

In accordance with an exemplary embodiment, the plurality of (e.g., K) selection terminals {SEL(q), q=0, 1, . . . , K−1} may be adapted to receive a corresponding plurality of (e.g., K) selection control signals {SEL_C(q), q=0, 1, . . . , K−1}. The plurality of (e.g., K) selection control signals {SEL_C(q), q=0, 1, . . . , K−1} may be implemented in an embodiment as a K-bit command signal, each one selection control signal, e.g., the q^{th} selection control signal SEL_C(q) may be a corresponding one bit, e.g., the q^{th} bit of the K-bit command signal. In this fashion, it may be available for customers or users to program or control which of the second plurality of (e.g., M) output terminals {OUT(j), j=1, 2, . . . , M} or which of the second plurality of (e.g., M) charging path control circuits {104(j), j=1, 2, . . . , M} of the charging unit 102 to be switched ON at the beginning of each charge pulse of the charging control PWM signal PWM_C. For instance, the plurality of (e.g., K) selection control signals {SEL_C(q), q=0, 1, . . . , K−1} may comprise logic signals. At the beginning of each charge pulse of the charging control PWM signal PWM_C, the charging unit 102 may check logic status of the plurality of (e.g., K) selection control signals {SEL_C(q), q=0, 1, K−1} and determine which of the second plurality of (e.g., M) output terminals {OUT(j), j=1, 2, M} or which of the second plurality of (e.g., M) charging path control circuits {104(j), j=1, 2, . . . , M} should be switched ON. Suppose the s^{th} output terminal OUT(s) among the second plurality of (e.g., M) output terminals {OUT(j), j=1, 2, . . . , M} or the s^{th} charging path control circuit 104(s) among the second plurality of (e.g., M) charging path control circuits {104(j), j=1, 2, . . . , M} should be switched ON, wherein s is an integer variable, then the integer variable s may be expressed with the equation (1) below. And in the equation (1) below, for each q=0, 1, . . . , K−1, SEL_C(q)=0 if the selection control signal SEL_C(q) is at logic low at the beginning of each charge pulse of the charging control PWM signal PWM_C, and SEL_C(q)=1 if the selection control signal SEL_C(q) is at logic high at the beginning of each charge pulse of the charging control PWM signal PWM_C. Herein after, for ease of description and understanding, the s^{th} output terminal OUT(s) among the second plurality of (e.g., M) output terminals {OUT(j), j=1, 2, . . . , M} that would be programmed to be switched ON according to the equation (1) can be referred to as the programmed s^{th} output terminal OUT(s), the s^{th} charging path control circuit 104(s) associated with the s^{th} output terminal OUT(s) among the second plurality of (e.g., M) charging path control circuits {104(j), j=1, 2, . . . , M} that would be programmed to be switched ON according to the equation (1) can be referred to as the programmed s^{th} charging path control circuit 104(s).

$$s = 1 + {\sum }_{q = 0}^{K - 1} SEL\_C ( q ) * {2}^{q} \qquad ( 1 )$$

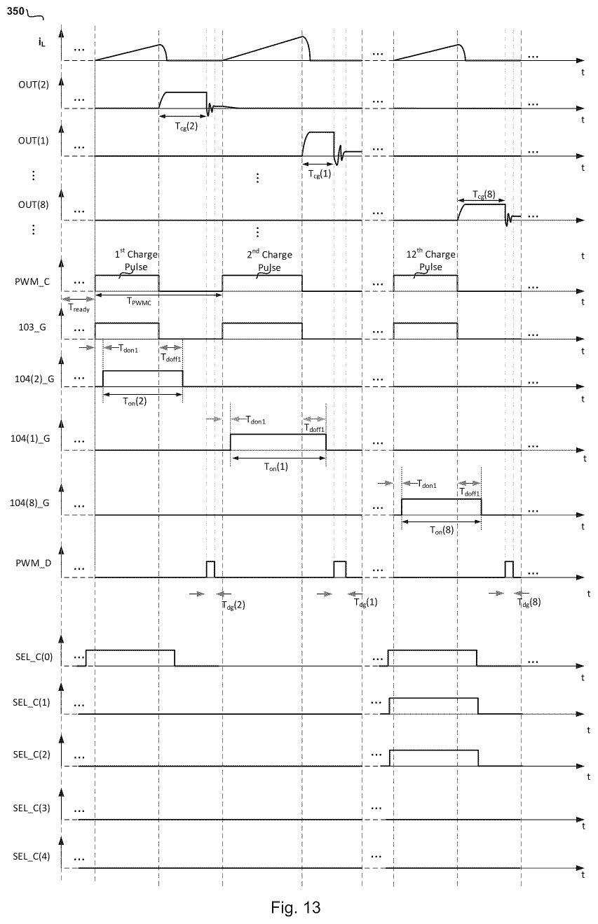

For instance, FIG. 13 shows an illustrative waveform diagram 350 illustrating operation waveforms of several signals of the driving system 150 of FIG. 11 in accordance with an exemplary embodiment of the present invention. In this example, the charging unit 102 may be considered to comprise the charging unit 250 as illustrated in FIG. 12 and is illustrated to have five selection terminals {SEL(q), q=0, 1, . . . , 4} as an example, that is to say, K=5. One of ordinary skill in the art would understand that substantial descriptions related to the waveforms illustratively and exemplarily shown in FIG. 3A and FIG. 3B may apply to the example shown in FIG. 13, except that in the example of FIG. 13, the ON and OFF switching pattern or switching order of each of the second plurality of (e.g., M) output terminals {OUT(j), j=1, 2, . . . , M} may be controlled/programmed via the plurality of (e.g., K) selection terminals {SEL(q), q=0, 1, . . . , K−1} wherein K=5 for the example shown in FIG. 13. That is to say, an order or a location of the j^{th} charging time window T_{cg}(j) during which the j^{th} output terminal OUT(j) would be switched ON may be controlled/programmed via the plurality of (e.g., K) selection terminals {SEL(q), q=0, 1, . . . , K−1}, for each j varying from 1 to M. Therefore, in the exemplary embodiment where the first plurality of selected output terminals {OUT(i), i=1, 2, . . . , N} are chosen from the second plurality of (e.g. M) output terminals {OUT(j), j=1, 2, . . . , M} to respectively drive the first plurality of (e.g. N) laser cells {101(i), i=1, 2, . . . , N}, for each i varying from 1 to N, the i^{th} charging time window T_{cg}(i) during which the selected i^{th} output terminal OUT(i) may be switched ON may no longer necessarily be located following the i^{th} charge pulse of the charging control PWM signal PWM_C as shown in the example of FIG. 3A and FIG. 3B. In contrast, an order or a location of the i^{th} charging time window T_{cg}(i) during which the selected i^{th} output terminal OUT(i) may be switched ON can be controlled/programmed via the plurality of (e.g., K) selection terminals {SEL(q), q=0, 1, . . . , K−1} wherein K=5 for the example shown in FIG. 13.

It can be seen from FIG. 13, that in this example, at the 1^{st} charge pulse of the charging control PWM signal PWM_C, the selection control signals {SEL_C(0), SEL_C(1), SEL_C(2), SEL_C (3), SEL_C (4)} respectively provided to the selection terminals {SEL(0), SEL(1), SEL(2), SEL(3), SEL(4)} may respectively have the logic status {1, 0, 0, 0, 0}, which means that s=1+1*2⁰+0*2¹+0*2²+0*2³+0*2⁴=2. Therefore, it is controlled or programmed in this example that the 2^{nd} output terminal OUT(2) among the second plurality of (e.g., M) output terminals {OUT(j), j=1, 2, . . . , M} or the 2^{nd} charging path control circuit 104(2) among the second plurality of (e.g., M) charging path control circuits {104(j), j=1, 2, . . . , M} would be switched ON based on the 1^{st} charge pulse of the charging control PWM signal PWM_C. Thus, in response to the first transition edge (e.g., the rising edge) of the 1^{st} charge pulse of the charging control PWM signal PWM_C with the predetermined on-delay time T_{don1} (analogous to descriptions made with reference to FIG. 3A) or in response to the second transition edge (e.g., the falling edge) of the 1^{st} charge pulse of the charging control PWM signal PWM_C with the predetermined on-delay time T_{don2} (analogous to descriptions made with reference to FIG. 3B), the control signal 104(2)_G for controlling the 2^{nd} charging path control circuit 104(2) among the second plurality of (e.g. M) charging path control circuits {104(j), j=1, 2, . . . , M} may change for instance from the first control voltage level or the first control logic level (e.g. logic low) to the second control voltage level or the second control logic level (e.g. logic high) to switch the 2^{nd} charging path control circuit 104(2) ON and enable the energy transfer/transmission path from the power output terminal BSTO to the 2^{nd} output terminal OUT(2). And in response to the second transition edge (e.g. the falling edge) of the 1^{st} charge pulse of the charging control PWM signal PWM_C with the predetermined off-delay time T_{doff1} (analogous to descriptions made with reference to FIG. 3A) or in response to the first transition edge (e.g., the rising edge) of the next charge pulse that is the 2^{nd} charge pulse of the charging control PWM signal PWM_C with the predetermined off-delay time T_{doff2} (analogous to descriptions made with reference to FIG. 3B), the control signal 104(2)_G may change from the second control voltage level or the second control logic level (e.g. logic high) to the first control voltage level or the first control logic level (e.g. logic low to switch the 2^{nd} charging path control circuit 104(2) OFF and disable the energy transfer/transmission path from the power output terminal BSTO to the 2nd output terminal OUT(2). In this fashion, it may be controlled or programmed via the selection terminals {SEL(0), SEL(1), SEL(2), SEL(3), SEL(4)} that the 2^{nd} output terminal OUT(2) is switched ON during the 2^{nd} charging time window Tcg(2) following the 1^{st} charge pulse of the charging control PWM signal PWM_C in this example.

Similarly, in the example of FIG. 13, at the 2^{nd} charge pulse of the charging control PWM signal PWM_C, the selection control signals {SEL_C(0), SEL_C(1), SEL_C(2), SEL_C (3), SEL_C (4)}respectively provided to the selection terminals {SEL(0), SEL(1), SEL(2), SEL(3), SEL(4)} may respectively have the logic status {0, 0, 0, 0, 0}, which means that s=1+0*2⁰+0*2¹+0*2²+0*2³+0*2⁴=1. Therefore, it is controlled or programmed in this example that the 1^{st} output terminal OUT(1) among the second plurality of (e.g., M) output terminals {OUT(j), j=1, 2, . . . , M} or the 1^{st} charging path control circuit 104(1) among the second plurality of (e.g., M) charging path control circuits {104(j), j=1, 2, . . . , M} would be switched ON at the 2^{nd} charge pulse of the charging control PWM signal PWM_C. Thus, in response to the first transition edge (e.g., the rising edge) of the 2^{nd} charge pulse of the charging control PWM signal PWM_C with the predetermined on-delay time T_{don1} (analogous to descriptions made with reference to FIG. 3A) or in response to the second transition edge (e.g., the falling edge) of the 2^{nd} charge pulse of the charging control PWM signal PWM_C with the predetermined on-delay time T_{don2} (analogous to descriptions made with reference to FIG. 3B), the control signal 104(1)_G for controlling the 1^{st} charging path control circuit 104(1) among the second plurality of (e.g. M) charging path control circuits {104(j), j=1, 2, . . . , M} may change for instance from the first control voltage level or the first control logic level (e.g. logic low) to the second control voltage level or the second control logic level (e.g. logic high) to switch the 1^{st} charging path control circuit 104(1) ON and enable the energy transfer/transmission path from the power output terminal BSTO to the 1^{st} output terminal OUT(1). And in response to the second transition edge (e.g. the falling edge) of the 2^{nd} charge pulse of the charging control PWM signal PWM_C with the predetermined off-delay time T_{doff1} (analogous to descriptions made with reference to FIG. 3A) or in response to the first transition edge (e.g., the rising edge) of the next charge pulse that is the 3^{rd} charge pulse of the charging control PWM signal PWM_C with the predetermined off-delay time T_{doff2} (analogous to descriptions made with reference to FIG. 3B), the control signal 104(1)_G may change from the second control voltage level or the second control logic level (e.g. logic high) to the first control voltage level or the first control logic level (e.g. logic low to switch the 1^{st} charging path control circuit 104(1) OFF and disable the energy transfer/transmission path from the power output terminal BSTO to the 1^{st} output terminal OUT(1). In this fashion, it may be controlled or programmed via the selection terminals {SEL(0), SEL(1), SEL(2), SEL(3), SEL(4)} that the 1^{st} output terminal OUT(1) is switched ON during the 1^{st} charging time window Tcg(1) following the 2^{nd} charge pulse of the charging control PWM signal PWM_C in this example.

At the 12^{th} charge pulse of the charging control PWM signal PWM_C, the selection control signals {SEL_C(0), SEL_C(1), SEL_C(2), SEL_C (3), SEL_C (4)} respectively provided to the selection terminals {SEL(0), SEL(1), SEL(2), SEL(3), SEL(4)} may respectively have the logic status {1, 1, 1, 0, 0}, which means that s=1+1*2⁰+1*2¹+1*2²+0*2³+0*2⁴=8. Therefore, it is controlled or programmed in this example that the 8^{th} output terminal OUT(8) among the second plurality of (e.g., M) output terminals {OUT(j), j=1, 2, . . . , M} or the 8^{th} charging path control circuit 104(8) among the second plurality of (e.g., M) charging path control circuits {104(j), j=1, 2, . . . , M} would be switched ON at the 12^{th} charge pulse of the charging control PWM signal PWM_C. Thus, in response to the first transition edge (e.g., the rising edge) of the 12^{th} charge pulse of the charging control PWM signal PWM_C with the predetermined on-delay time T_{don1} (analogous to descriptions made with reference to FIG. 3A) or in response to the second transition edge (e.g., the falling edge) of the 12^{th} charge pulse of the charging control PWM signal PWM_C with the predetermined on-delay time T_{don2} (analogous to descriptions made with reference to FIG. 3B), the control signal 104(8)_G for controlling the 8^{th} charging path control circuit 104(8) among the second plurality of (e.g. M) charging path control circuits {104(j), j=1, 2, . . . , M} may change for instance from the first control voltage level or the first control logic level (e.g. logic low) to the second control voltage level or the second control logic level (e.g. logic high) to switch the 8^{th} charging path control circuit 104(8) ON and enable the energy transfer/transmission path from the power output terminal BSTO to the 8^{th} output terminal OUT(8). And in response to the second transition edge (e.g. the falling edge) of the 12^{th} charge pulse of the charging control PWM signal PWM_C with the predetermined off-delay time T_{doff1} (analogous to descriptions made with reference to FIG. 3A) or in response to the first transition edge (e.g., the rising edge) of the next charge pulse that is the 13^{th} charge pulse of the charging control PWM signal PWM_C with the predetermined off-delay time T_{doff2} (analogous to descriptions made with reference to FIG. 3B), the control signal 104(8)_G may change from the second control voltage level or the second control logic level (e.g. logic high) to the first control voltage level or the first control logic level (e.g. logic low to switch the 8^{th} charging path control circuit 104(8) OFF and disable the energy transfer/transmission path from the power output terminal BSTO to the 8^{th} output terminal OUT(8). In this fashion, it may be controlled or programmed via the selection terminals {SEL(0), SEL(1), SEL(2), SEL(3), SEL(4)} that the 8^{th} output terminal OUT(8) is switched ON during the 8^{th} charging time window Tcg(8) following the 12^{th} charge pulse of the charging control PWM signal PWM_C in this example.

One of ordinary skill in the art would understand that regarding the examples of FIG. 12 and FIG. 13, descriptions analogous to those above apply to more generic situation where the s^{th} output terminal OUT(s) among the second plurality of (e.g., M) output terminals {OUT(j), j=1, 2, . . . , M} or the s^{th} charging path control circuit 104(s) associated with the s^{th} output terminal OUT(s) among the second plurality of (e.g., M) charging path control circuits {104(j), j=1, 2, . . . , M} would be programmed to be switched ON according to the equation (1) at an i^{th} charge pulse of the charging control PWM signal PWM_C. For example, in response to the first transition edge (e.g., the rising edge) of the i^{th} charge pulse of the charging control PWM signal PWM_C with the predetermined on-delay time T_{don1} (analogous to descriptions made with reference to FIG. 3A) or in response to the second transition edge (e.g., the falling edge) of the i^{th} charge pulse of the charging control PWM signal PWM_C with the predetermined on-delay time T_{don2} (analogous to descriptions made with reference to FIG. 3B), the control signal 104(s)_G for controlling the programmed s^{th} charging path control circuit 104(s) may change for instance from the first control voltage level or the first control logic level (e.g. logic low) to the second control voltage level or the second control logic level (e.g. logic high) to switch the programmed s^{th} charging path control circuit 104(s) ON and enable the energy transfer/transmission path from the power output terminal BSTO to the programmed s^{th} output terminal OUT(s). And in response to the second transition edge (e.g. the falling edge) of the i^{th} charge pulse of the charging control PWM signal PWM_C with the predetermined off-delay time T_{doff1} (analogous to descriptions made with reference to FIG. 3A) or in response to the first transition edge (e.g., the rising edge) of the next charge pulse that is the (i+1)^{th} charge pulse of the charging control PWM signal PWM_C with the predetermined off-delay time T_{doff2} (analogous to descriptions made with reference to FIG. 3B), the control signal 104(s)_G may change from the second control voltage level or the second control logic level (e.g. logic high) to the first control voltage level or the first control logic level (e.g., logic low) to switch the programmed s^{th} charging path control circuit 104(s) OFF and disable the energy transfer/transmission path from the power output terminal BSTO to the programmed s^{th} output terminal OUT(s). In this fashion, it may be controlled or programmed via the selection terminals {SEL(q), q=0, 1, . . . , K−1} that the programmed s^{th} output terminal OUT(s) may be switched ON during the s^{th} charging time window Tcg(s) following the i^{th} charge pulse of the charging control PWM signal PWM_C, for any i varying from 1 to M.

One of ordinary skill in the art would further understand that regarding the examples of FIG. 12 and FIG. 13, the charging unit 250 configured to provide the control signal 104(s)_G to control the programmed s^{th} charging path control circuit 104(s) with changes in a control voltage level or a control logic level of the control signal 104(s)_G in response to the charging control PWM signal PWM_C as described with reference to the example of FIG. 13 is just exemplary and not intended to be limiting, the charging unit 250 may be configured to provide the control signal 104(s)_G with the control voltage level or the control logic level of the control signal 104(s)_G changing in response to the charging control PWM signal PWM_C with various other alternative manners that cannot be exhaustively addressed here yet do not depart from the spirit and scope of various embodiments of the present disclosure, as long as the s^{th} on time window Tₒₙ(s) of the charging path control circuit 104(s) that is coupled to the programmed s^{th} output terminal OUT(s) which is programmed to be switched ON at the i^{th} charge pulse of the charging control PWM signal PWM_C can be controlled to begin at a moment located within the time duration when the controllable power switch 103 is kept ON for instance in response to the present i^{th} charge pulse of the charging control PWM signal PWM_C and to end at a moment no later than the moment when the controllable power switch 103 is switched OFF in response to the next (i+1)^{th} charge pulse of the charging control PWM signal PWM_C. In this fashion, the charging unit 250 may be configured to flexibly adjust the s^{th} on time window Tₒₙ(s) to ensure that the charging path control circuit 104(s) coupled to the programmed s^{th} output terminal OUT(s) is switched ON to enable the energy transfer/transmission path from the power output terminal BSTO to the programmed s^{th} output terminal OUT(s) no later than the moment when the s^{th} charging time window T_{cg}(s) associated with the programmed s^{th} output terminal OUT(s) begins and that the charging path control circuit 104(s) coupled to the programmed s^{th} output terminal OUT(s) is switched OFF to disable the energy transfer/transmission path from the power output terminal BSTO to the programmed s^{th} output terminal OUT(s) no later than the moment when the charging time window Tcg(s) associated with the next programmed s^{th} output terminal OUT(s) which would be switched ON following the current programmed s^{th} output terminal OUT(s) begins.

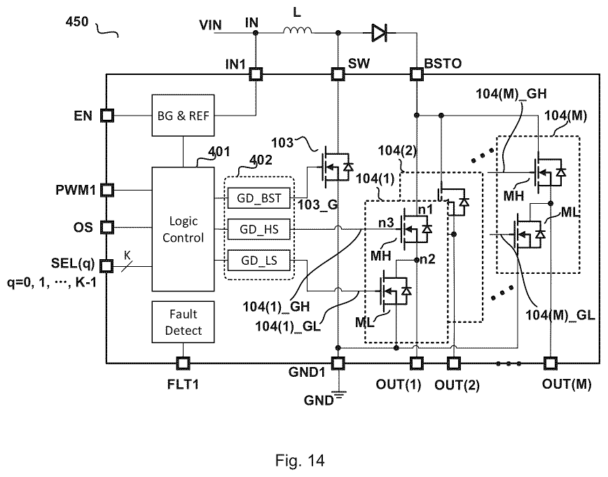

FIG. 14 illustrates an exemplary schematic diagram of a charging unit 450 in accordance with an alternative exemplary embodiment of the present disclosure. The charging unit 450 may be used to implement the charging unit 102 of FIG. 11 as an alternative embodiment. Compared to the charging unit 400 as exemplarily illustrated in FIG. 4, the charging unit 450 illustrated in the example of FIG. 14 further include the plurality of (e.g., K) selection terminals {SEL(q), q=0, 1, . . . , K−1}. One of ordinary skill in the art would understand that substantial descriptions related to the embodiments of FIG. 1 and FIG. 4 may apply to the embodiments of FIG. 11 and FIG. 14 except that in the embodiments of FIG. 11 and FIG. 14, the ON and OFF switching pattern or switching order of each of the second plurality of (e.g., M) output terminals {OUT(j), j=1, 2, . . . , M} may be controlled/programmed via the plurality of (e.g., K) selection terminals {SEL(q), q=0, 1, . . . , K−1}.

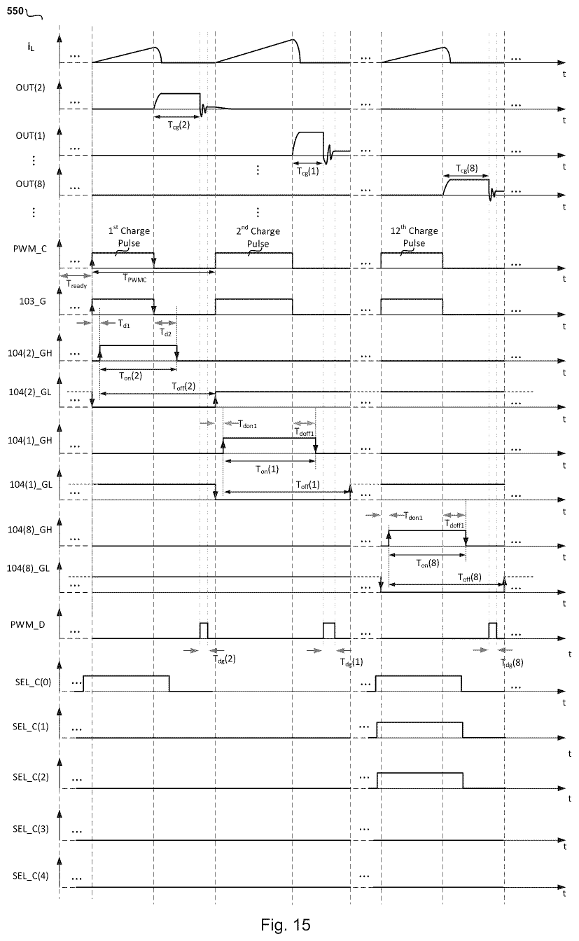

FIG. 15 shows an illustrative waveform diagram 550 illustrating operation waveforms of several signals of the driving system 150 of FIG. 11 in accordance with an alternative exemplary embodiment of the present invention. In this example, the charging unit 102 may be considered to comprise the charging unit 450 as illustrated in FIG. 14 and is illustrated to have five selection terminals {SEL(q), q=0, 1, . . . , 4}, that is to say, K=5. One of ordinary skill in the art would understand that substantial descriptions related to the waveforms illustratively and exemplarily shown in FIG. 5A and FIG. 5B may apply to the example shown in FIG. 15, except that in the example of FIG. 15, the ON and OFF switching pattern or switching order of each of the second plurality of (e.g., M) output terminals {OUT(j), j=1, 2, . . . , M} may be controlled/programmed via the plurality of (e.g., K) selection terminals {SEL(q), q=0, 1, . . . , K−1} wherein K=5 for the example shown in FIG. 15. An order or a location of the j^{th} charging time window T_{cg}(j) during which the j^{th} output terminal OUT(j) would be switched ON may be controlled/programmed via the plurality of (e.g., K) selection terminals {SEL(q), q=0, 1, . . . , K−1}, for each j varying from 1 to M. Therefore, in the exemplary embodiment where the first plurality of selected output terminals {OUT(i), i=1, 2, . . . , N} are chosen from the second plurality of (e.g. M) output terminals {OUT(j), j=1, 2, . . . , M} to respectively drive the first plurality of (e.g. N) laser cells {101(i), i=1, 2, . . . , N}, for each i varying from 1 to N, the i^{th} charging time window T_{cg}(i) during which the selected i^{th} output terminal OUT(i) may be switched ON may no longer necessarily be located following the i^{th} charge pulse of the charging control PWM signal PWM_C as shown in the examples of FIG. 5A and FIG. 5B. In contrast, an order or a location of the i^{th} charging time window T_{cg}(i) during which the selected i^{th} output terminal OUT(i) may be switched ON can be controlled/programmed via the plurality of (e.g., K) selection terminals {SEL(q), q=0, 1, . . . , K−1} wherein K=5 for the example shown in FIG. 15.

Analogous to the waveforms illustrated in the example of FIG. 13, it can be seen from the example of FIG. 15 that, at the 1^{st} charge pulse of the charging control PWM signal PWM_C, the selection control signals {SEL_C(0), SEL_C(1), SEL_C(2), SEL_C (3), SEL_C (4)} respectively provided to the selection terminals {SEL(0), SEL(1), SEL(2), SEL(3), SEL(4)} may respectively have the logic status {1, 0, 0, 0, 0}, which means that s=1+1*2°+0*2¹+0*2²+0*2³+0*2⁴=2. Therefore, it is controlled or programmed in this example that the 2^{nd} output terminal OUT(2) among the second plurality of (e.g., M) output terminals {OUT(j), j=1, 2, . . . , M} or the 2^{nd} charging path control circuit 104(2) among the second plurality of (e.g., M) charging path control circuits {104(j), j=1, 2, . . . , M} would be switched ON at the 1^{st} charge pulse of the charging control PWM signal PWM_C. At the 2^{nd} charge pulse of the charging control PWM signal PWM_C, the selection control signals {SEL_C(0), SEL_C(1), SEL_C(2), SEL_C (3), SEL_C (4)} respectively provided to the selection terminals {SEL(0), SEL(1), SEL(2), SEL(3), SEL(4)} may respectively have the logic status {0, 0, 0, 0, 0}, which means that s=1+0*2⁰+0*2¹+0*2²+0*2³+0*2⁴=1. Therefore, it is controlled or programmed in this example that the 1^{st} output terminal OUT(1) among the second plurality of (e.g., M) output terminals {OUT(j), j=1, 2, . . . , M} or the 1^{st} charging path control circuit 104(1) among the second plurality of (e.g., M) charging path control circuits {104(j), j=1, 2, . . . , M} would be switched ON at the 2^{nd} charge pulse of the charging control PWM signal PWM_C. At the 12^{th} charge pulse of the charging control PWM signal PWM_C, the selection control signals {SEL_C(0), SEL_C(1), SEL_C(2), SEL_C (3), SEL_C (4)} respectively provided to the selection terminals {SEL(0), SEL(1), SEL(2), SEL(3), SEL(4)} may respectively have the logic status {1, 1, 1, 0, 0}, which means that s=1+1*2⁰+1*2¹+1*2²+0*2³+0*2⁴=8. Therefore, it is controlled or programmed in this example that the 8^{th} output terminal OUT(8) among the second plurality of (e.g., M) output terminals {OUT(j), j=1, 2, . . . , M} or the 8^{th} charging path control circuit 104(8) among the second plurality of (e.g., M) charging path control circuits {104(j), j=1, 2, . . . , M} would be switched ON at the 12^{th} charge pulse of the charging control PWM signal PWM_C.

And more specifically, for the examples in FIG. 14 and FIG. 15, the ON and OFF switching of the programmed output terminal OUT(s) which is programmed to be switched ON via the plurality of (e.g., K) selection terminals {SEL(q), q=0, 1, . . . , K−1} may be realized by controlling the high side switch MH and the low side switch ML in the charging path control circuit 104(s) coupled to or associated with the programmed output terminal OUT(s). The charging unit 450 provides a high side control signal 104(s)_GH and a low side control signal 104(s)_GL to respectively control the high side switch MH and the low side switch ML in the charging path control circuit 104(s). One of ordinary skill in the art would understand that substantial descriptions related to changes in the control voltage level or the control logic level of the control signal 104(s)_G made with reference to the examples of FIG. 12 and FIG. 13 in response to the charging control PWM signal PWM_C according to various exemplary embodiments are applicable to the high side control signal 104(s)_GH of the examples of FIG. 14 and FIG. 15 and need not to be addressed again here for simplicity.

Regarding the low side control signal 104(s)_GL, it can be understood that descriptions analogous to those made to the low side control signal 104(i)_GL for the low side switch ML in the i^{th} charging path control circuit 104(i) with reference to the examples of FIG. 5A and FIG. 5B are applicable to the low side control signal 104(s)_GL for the low side switch ML of the programmed s^{th} charging path control circuit 104(s) in the examples of FIG. 14 and FIG. 15. That is, the low side control signal 104(s)_GL at least keeps the low side switch ML of the programmed s^{th} charging path control circuit 104(s) OFF during a period Toff(s) from the moment when the high side switch MH of the programmed s^{th} charging path control circuit 104(s) is turned ON based on the i^{th} charge pulse of the charging control PWM signal PWM_C till the moment when the first transition edge (e.g. the rising edge) of the (i+1)^{th} charge pulse of the charging control PWM signal PWM_C comes to ensure that energy discharge from the programmed s^{th} output terminal OUT(s) to the reference ground terminal GND1 is disabled during the period Toff(s), and the low side control signal 104(s)_GL at least switch the low side switch ML of the programmed s^{th} charging path control circuit 104(s) ON for a predetermined time window located outside the period Toff(s) to discharge energy/charges left on the programmed s^{th} output terminal OUT(s) to the reference ground terminal GND1 of the charging unit 450.

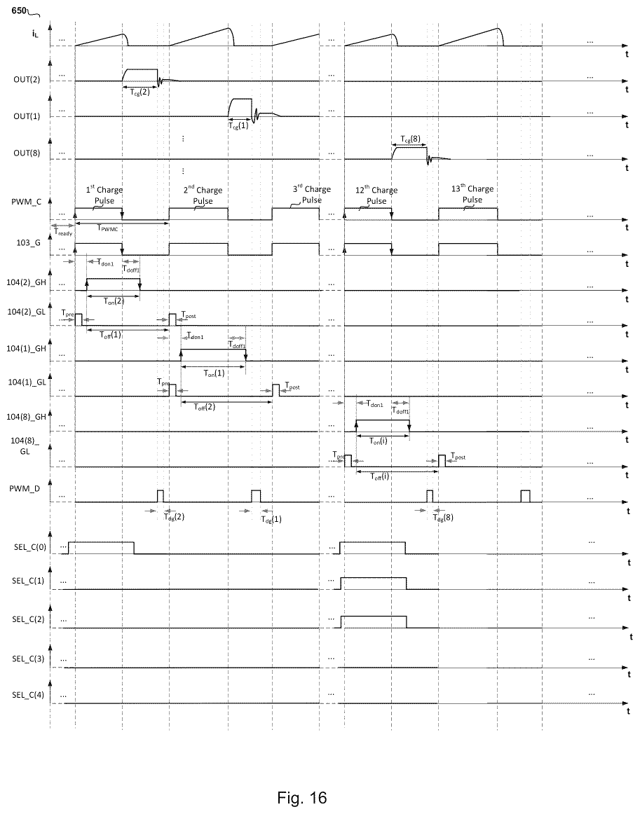

FIG. 16 shows an illustrative waveform diagram 650 illustrating operation waveforms of several signals of the driving system 150 of FIG. 11 in accordance with an alternative exemplary embodiment of the present invention. In this example, the charging unit 102 may still be considered to comprise the charging unit 450 as illustrated in FIG. 14 and is illustrated to have five selection terminals {SEL(q), q=0, 1, . . . , 4}, that is to say, K=5. Difference of the exemplary embodiment shown in FIG. 16 from the exemplary embodiment shown in FIG. 15 may lie in one aspect that the control logics for the low side control signal 104(s)_GL may be changed while control logics of the high side control signal 104(s)_GH may be the same as those described with reference to FIG. 15. One of ordinary skill in the art would understand that control logics for the low side control signal 104(s)_GL in the example of FIG. 16 may be analogous to those described with reference to the example of FIG. 6. That is, in accordance with the example of FIG. 16 for the situation where the s^{th} output terminal OUT(s) among the second plurality of (e.g., M) output terminals {OUT(j), j=1, 2, . . . , M} or the s^{th} charging path control circuit 104(s) associated with the s^{th} output terminal OUT(s) among the second plurality of (e.g., M) charging path control circuits {104(j), j=1, 2, . . . , M} would be programmed to be switched ON according to the equation (1) at any one charge pulse (e.g, an i^{th} charge pulse for any i varying from 1 to M) of the charging control PWM signal PWM_C, then in an embodiment, in response to the first transition edge (e.g., the rising edge) of the i^{th} charge pulse of the charging control PWM signal PWM_C, the low side control signal 104(s)_GL may be adapted to provide a predetermined pre-discharge time window Tₚᵣₑ during which the low side control signal 104(s)_GL may have the third control logic level (e.g., logic high) to control the low side switch ML in the programmed s^{th} charging path control circuit 104(s) being ON and be adapted to enable energy discharge from the programmed s^{th} output terminal OUT(s) to the reference ground terminal GND1 of the charging unit 450, and the low side control signal 104(s)_GL may be adapted to control the low side switch ML in the programmed s^{th} charging path control circuit 104(s) being OFF outside the predetermined pre-discharge time window Tₚᵣₑ. In an alternative embodiment, in response to the first transition edge (e.g., the rising edge) of the next charge pulse (i.e., the (i+1)^{th} charge pulse here) following the i^{th} charge pulse of the charging control PWM signal PWM_C, the low side control signal 104(s)_GL may be adapted to provide a predetermined post-discharge time window Tₚₒₛₜ during which the low side control signal 104(2)_GL may have the third control logic level (e.g. logic high) and may be adapted to control the low side switch ML in the programmed s^{th} charging path control circuit 104(s) being ON and enable energy discharge from the programmed s^{th} output terminal OUT(s) to the reference ground terminal GND1 of the charging unit 450, and the low side control signal 104(s)_GL may be adapted to control the low side switch ML in the programmed s^{th} charging path control circuit 104(s) being OFF outside the predetermined post-discharge time window Tₚₒₛₜ. In still an alternative embodiment, the low side control signal 104(s)_GL may be adapted to provide both the predetermined pre-discharge time window Tₚᵣₑ and the predetermined post-discharge time window Tₚₒₛₜ respectively in response to the first transition edge (e.g., the rising edge) of the i^{th} charge pulse of the charging control PWM signal PWM_C and the first transition edge (e.g., the rising edge) of the (i+1)^{th} charge pulse of the charging control PWM signal PWM_C.

For instance, it can be seen from the exemplary and illustrative waveforms shown in FIG. 16 that at the 1^{st} charge pulse of the charging control PWM signal PWM_C with the selection control signals {SEL_C(0), SEL_C(1), SEL_C(2), SEL_C (3), SEL_C (4)} respectively set to have the logic status {1, 0, 0, 0, 0}, which means that s=1+1*2°+0*2¹+0*2²+0*2³+0*2⁴=2, to control or program the 2^{nd} output terminal OUT(2) or the 2^{nd} charging path control circuit 104(2) being switched ON, the control logics of the high side control signal 104(2)_GH for controlling the high side switch MH in the 2^{nd} charging path control circuit 104(2) may be the same as described in the example of FIG. 15, while for the low side control signal 104(2)_GL, in response to the first transition edge (e.g., the rising edge) of the 1^{st} charge pulse of the charging control PWM signal PWM_C, the low side control signal 104(2)_GL may be adapted to provide the predetermined pre-discharge time window Tₚᵣₑ during which the low side control signal 104(2)_GL may have the third control logic level (e.g., logic high) to control the low side switch ML in the 2^{nd} charging path control circuit 104(2) being ON and be adapted to enable energy discharge from the 2^{nd} output terminal OUT(2) to the reference ground terminal GND1 of the charging unit 450. The low side control signal 104(2)_GL may further be adapted to provide the predetermined post-discharge time window Tₚₒₛₜ in response to the first transition edge (e.g., the rising edge) of the next charge pulse (i.e., the 2^{nd} charge pulse here) following the 1^{st} charge pulse of the charging control PWM signal PWM_C to control the low side switch ML in the 2^{nd} charging path control circuit 104(2) being ON and enable energy discharge from the 2^{nd} output terminal OUT(2) to the reference ground terminal GND1 of the charging unit 450 during the predetermined post-discharge time window Tₚₒₛₜ. Analogous descriptions apply to the low side control signal 104(1)_GL in the example shown that at the 2^{nd} charge pulse of the charging control PWM signal PWM_C with the selection control signals {SEL_C(0), SEL_C(1), SEL_C(2), SEL_C (3), SEL_C (4)}respectively set to have the logic status {0, 0, 0, 0, 0}, which means that s=1+0*2⁰+0*2¹+0*2²+0*2³+0*2⁴=1, to control or program the 1^{st} output terminal OUT(1) or the 1^{st} charging path control circuit 104(1) being switched ON, and to the low side control signal 104(8)_GL in the example shown that at the 12^{th} charge pulse of the charging control PWM signal PWM_C with the selection control signals {SEL_C(0), SEL_C(1), SEL_C(2), SEL_C (3), SEL_C (4)} respectively set to have the logic status {1, 1, 1, 0, 0}, which means that s=1+1*2⁰+1*2¹+1*2²+0*2³+0*2⁴=8, to control or program the 8^{th} output terminal OUT(8) or the 8^{th} charging path control circuit 104(8) being switched ON.

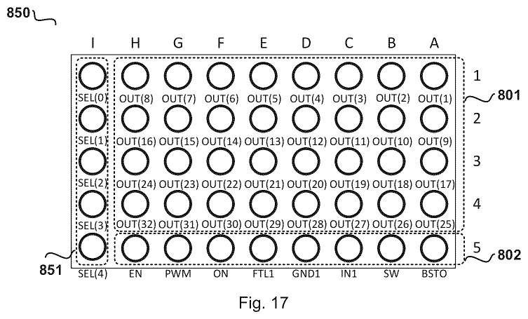

FIG. 17 illustratively shows an alternative package 850 of an IC die or chip with the charging unit 102 integrated therein in accordance with an alternative embodiment of the present invention. Difference of the exemplary embodiment of the package 850 shown in FIG. 17 from the exemplary embodiment of the package 800 shown in FIG. 8 may lie in one aspect that the package 850 may further include the plurality of (e.g., K) selection terminals {SEL(q), q=0, 1, . . . , K−1}, for instance in the form of a corresponding plurality of (e.g., K) electrically conductive pads, arranged in a selection terminal array 851 and disposed on the active surface of the package 850. In the example of FIG. 17, the charging unit 102 packaged into the package 850 may comprise the charging unit 250 as illustrated in the example of FIG. 12 or the charging unit 450 as illustrated in the example of FIG. 14 and is exemplarily illustrated to have 32 output terminals {OUT(j), j=1, 2, . . . , 32} arranged in an output terminal matrix 801 of 4 by 8 (i.e., M=32, X=4 and Y=8 in this example). Therefore, to make the ON and OFF switching pattern or switching order of each of the 32 output terminals {OUT(j), j=1, 2, . . . , 32} programmable/controllable, the number K may be set to 5 in this example according to 2^{K} M=32.

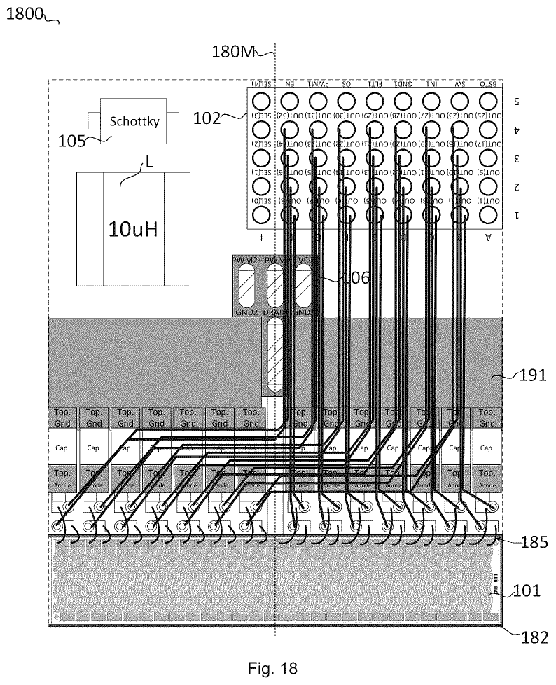

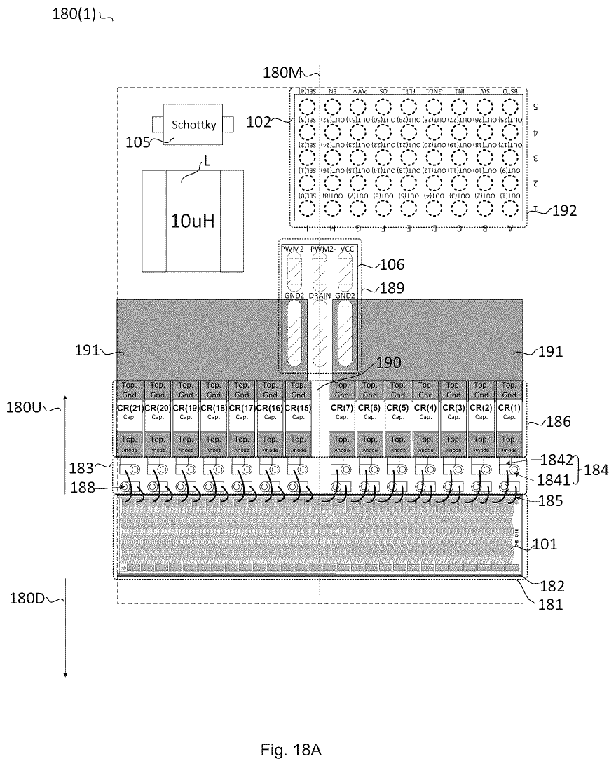

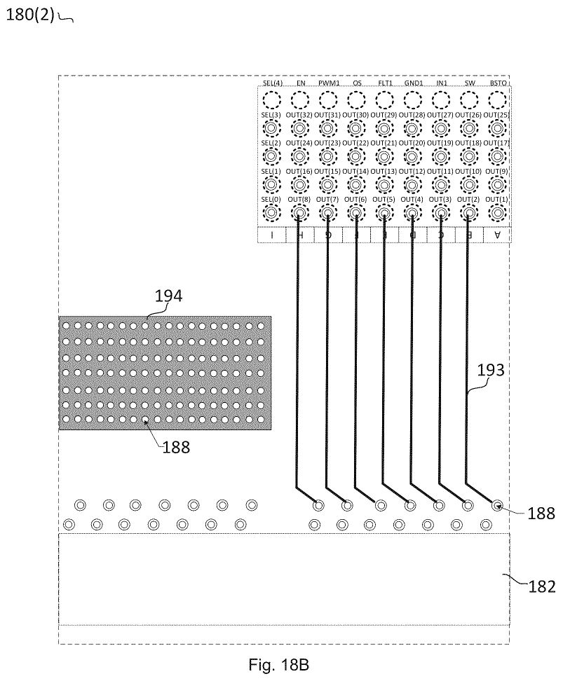

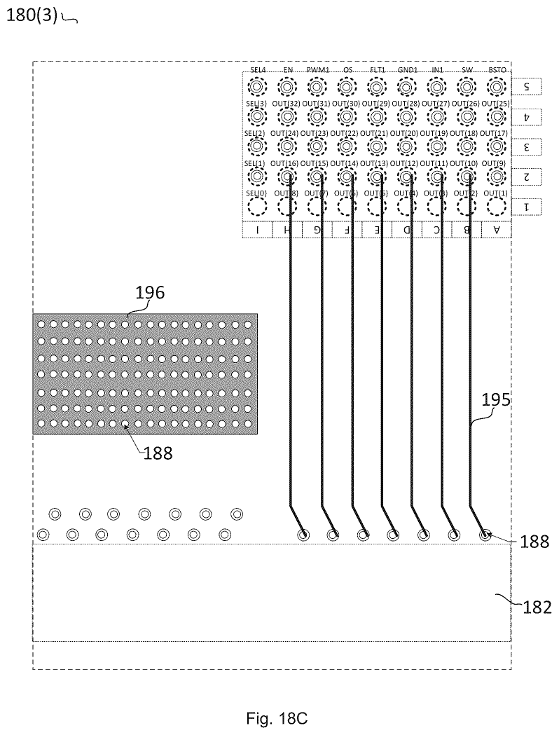

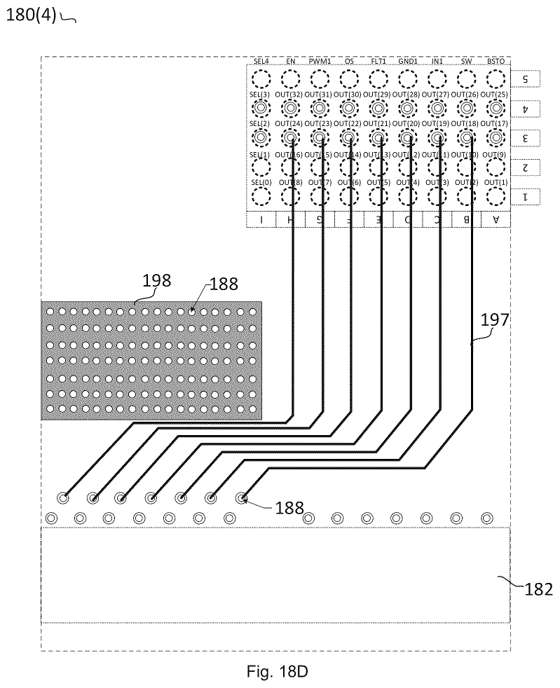

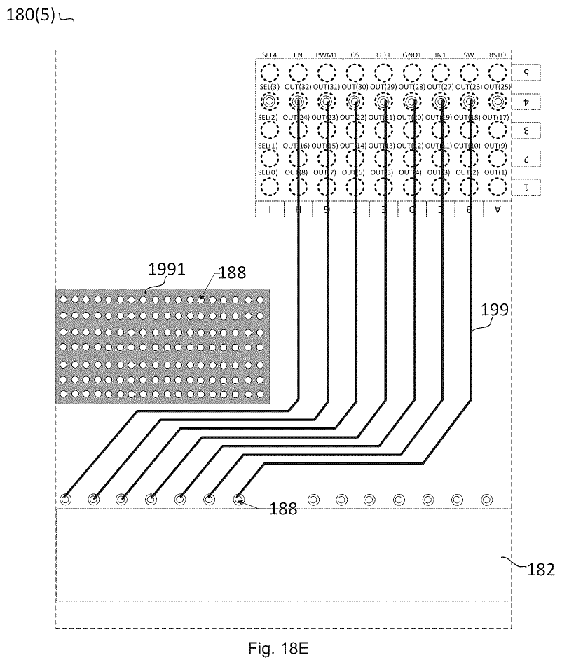

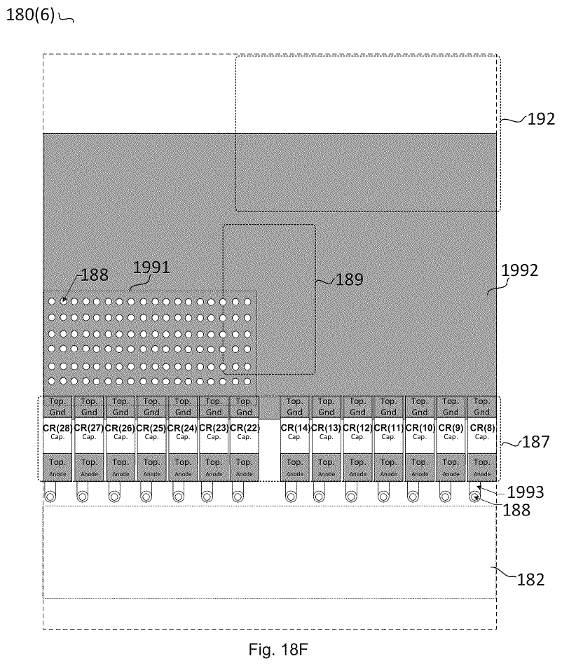

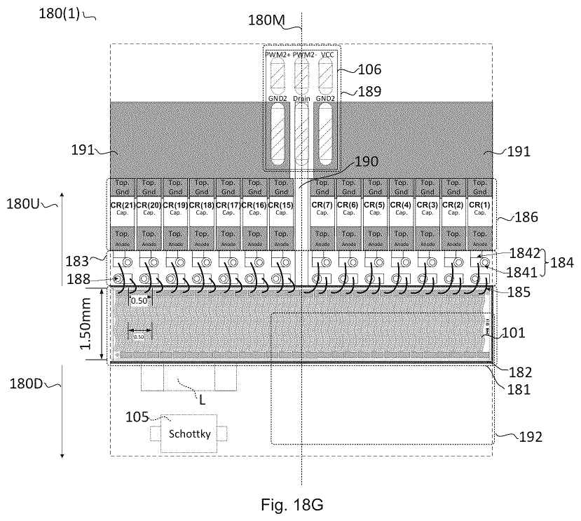

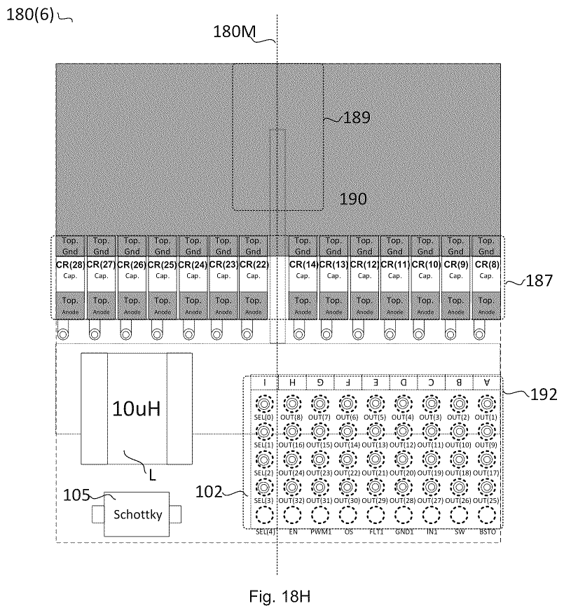

FIG. 18 illustrates an application board level layout diagram corresponding to the driving system 100 of FIG. 1 or 150 of FIG. 11 in accordance with an exemplary embodiment of the present invention. FIG. 18A to FIG. 18F illustrate layer by layer application board level layout diagrams corresponding to the driving system 100 of FIG. 1 or 150 of FIG. 11 in accordance with an exemplary embodiment of the present invention. In an embodiment, the driving system 100 or 150 is implemented and mounted on a multi-layer circuit board such as a printed circuit board (PCB) 1800. Descriptions to the multi-layer circuit board 1800 for the driving system 100 or 150 will now be made with reference to FIG. 18 and FIG. 18A to FIG. 18F. The multi-layer circuit board 1800 may include a plurality of (e.g., represented by an integer variable H) board layers 180(1), 180(2), . . . , 180(H). Herein after, the plurality of (e.g., H) board layers 180(1), 180(2), . . . , 180(H) may be referred to as or represented by {180(h), h=1, 2, . . . , H}. Herein H is an integer variable no less than 1 and represents the total number of board layers 180(1), 180(2), . . . , 180(H) that the multi-layer circuit board 1800 may include, which may be set or determined by customers/users in practical applications depending on real application requirements. That is to say, the index h is a variable traverses the integers from 1 to H. In an embodiment, the plurality of (e.g., H) board layers {180(h), h=1, 2, . . . , H} may be disposed one on top of another following the order from 180(1) to 180(H). That is, the 1^{st} board layer 180(1) can be the topmost layer of the multi-layer circuit board 1800 while the H^{th} board layer 180(H) can be the bottommost layer of the multi-layer circuit board 1800, and the remained board layers 180(2) to 180(H−1) if any may be intermediate board layers sandwiched between the 1^{st} board layer 180(1) and the H^{th} board layer 180(H). For each h from 1 to (H−1), the h^{th} board layer 180(h) is disposed on top of the (h+1)^{th} board layer 180(h+1). In the example illustrated in FIG. 18 and FIG. 18A to FIG. 18F, the multi-layer circuit board 1800 is illustrated to include six board layers {180(h), h=1, 2, . . . , 6}, that is to say, H=6 in this example and a plan view of each one of the six board layers {180(h), h=1, 2, . . . , 6} are respectively illustrated in FIG. 18A to FIG. 18F. However, this is just to provide an example and not intended to be limiting.

In an embodiment, referring to the top plan view illustration of FIG. 18A, the integrated semiconductor laser device 101 may be disposed and mounted on the 1^{st} board layer 180(1) of the multi-layer circuit board 1800 at a predetermined laser device mounting area 181 on a top surface of the 1^{st} board layer 180(1). It can be understood that the top surface of the 1^{st} board layer 180(1) can be alternatively referred to as a top surface of the multi-layer circuit board 1800. The integrated semiconductor laser device 101 is illustrated to have a first plurality of (e.g., N=28) laser cells {101(i), i=1, 2, . . . , 28} as an example here. A corresponding first plurality of (e.g., N=28) electrically conductive connecting structures 184 may be disposed on the top surface of the multi-layer circuit board 1800 at a predetermined connecting structure area 183. In an embodiment, each one of the electrically conductive connecting structures 184 may include a pad portion 1841 connected to an interlayer connecting via 188 which is represented by a small circle in the exemplary illustrative drawings and a connecting trace 1842 connected with the pad portion 1841. The corresponding first plurality of (e.g., N=28) electrically conductive connecting structures 184 may be configured to provide electrical interconnection availability between the integrated semiconductor laser device 101 and other elements such as the first plurality of (e.g., N=28) capacitive energy storage devices {CR(i), i=1, 2, . . . , 28} and the charging unit 102 in the driving system 100 or 150. For example, in an embodiment, the first terminals of the first plurality of (e.g., N=28) laser cells {101(i), i=1, 2, . . . , 28} are respectively connected to the corresponding first plurality of (e.g., N=28) electrically conductive connecting structures 184 in a one-to-one correspondence manner. That is, the first terminal (e.g., anode) of each one of the first plurality of (e.g., N=28) laser cells {101(i), i=1, 2, . . . , 28} is connected to a corresponding one electrically conductive connecting structure 184, for instance through a bond wire 185. In FIG. 18A, the first terminal (e.g., anode) of each one of the first plurality of (e.g., N=28) laser cells {101(i), i=1, 2, . . . , 28} is represented by a small rectangular block in orange. The second terminals (e.g., cathodes) of the first plurality of (e.g., N=28) laser cells {101(i), i=1, 2, . . . , 28} of the integrated semiconductor laser device 101 are electrically connected together by an electrically conductive sheet 182 (illustrated in red in FIG. 18A) placed at the predetermined laser device mounting area 181 on the top surface of the 1^{st} board layer 180(1) and under the integrated semiconductor laser device 101. The corresponding first plurality of (e.g., N=28) electrically conductive connecting structures 184 are separated and electrically isolated from each other and also from the electrically conductive sheet 182.

In an embodiment, a first portion of the corresponding first plurality of (e.g., N=28) capacitive energy storage devices {CR(i), i=1, 2, . . . , 28} may be disposed and mounted on the 1^{st} board layer 180(1) at a predetermined capacitive device mounting area 186 on the top surface of the 1^{st} board layer 180(1) as illustratively shown in FIG. 18A. The predetermined capacitive device mounting area 186 on the top surface of the multi-layer circuit board 1800 may be disposed as close as possible to the predetermined laser device mounting area 181, for instance, at a first side (e.g., an upside in the example of FIG. 18-FIG. 18F indicated by an arrow 180U directed to the upside) of the predetermined laser device mounting area 181 or at a second side (e.g., a downside in the example of FIG. 18-FIG. 18F indicated by an arrow 180D directed to the downside) of the predetermined laser device mounting area 181. The predetermined connecting structure area 183 may be disposed between the predetermined laser device mounting area 181 and the predetermined capacitive device mounting area 186 on the top surface of the multi-layer circuit board 1800. In this fashion, interconnection between the integrated semiconductor laser device 101 and the corresponding first plurality of (e.g., N=28) capacitive energy storage devices {CR(i), i=1, 2, . . . , 28} can be more easily implemented with a reduced interconnection resistance.

Now referring to the illustration in FIG. 18F showing a plan view of a bottom side of the multi-layer circuit board 1800 which may also be considered as a bottom plan view inspected from a bottom surface of the bottommost H^{th} board layer 180(H), H=6 in this example, a second portion of the corresponding first plurality of (e.g., 28) capacitive energy storage devices {CR(i), i=1, 2, . . . , 28} may be disposed and mounted on the H^{th} board layer 180(H) at a predetermined capacitive device mounting area 187 on the bottom surface of the H^{th} board layer 180(H). It can be understood that the bottom surface of the H^{th} board layer 180(H) can be alternatively referred to as a bottom surface of the multi-layer circuit board 1800. This could advantageously help to improve the space utilization and save an overall board size or board area of the multi-layer circuit board 1800 needed to implement and mount the driving system 100 or 150. In an embodiment, a location of the predetermined capacitive device mounting area 187 on the bottom surface of the multi-layer circuit board 1800 may match with that of the predetermined capacitive device mounting area 186 on the top surface of the multi-layer circuit board 1800. For example, a projection of the predetermined capacitive device mounting area 187 on the top surface of the multi-layer circuit board 1800 may coincide with the predetermined capacitive device mounting area 186.

In an embodiment, the first portion of the corresponding first plurality of (e.g., N=28) capacitive energy storage devices {CR(i), i=1, 2, . . . , 28} includes a first number NUM1 of the capacitive energy storage devices among the first plurality of (e.g., N=28) capacitive energy storage devices {CR(i), i=1, 2, . . . , 28}, and the second portion of the corresponding first plurality of (e.g., N=28) capacitive energy storage devices {CR(i), i=1, 2, . . . , 28} includes a second number NUM2 of the capacitive energy storage devices among the first plurality of (e.g., N=28) capacitive energy storage devices {CR(i), i=1, 2, . . . , 28}. In an embodiment, the first number NUM1 and the second number NUM2 may be substantially identical. For example, the first portion may include the 14 capacitive energy storage devices {CR(i), i=1, 2, . . . , 7 and i=15, 16, . . . , 21} while the second portion may include the remained 14 capacitive energy storage devices {CR(i), i=8, 9, . . . , 14 and i=22, 23, . . . , 28} in the particular example where N=28. However, one of ordinary skill in the art would understand that in alternative embodiments, the first number NUM1 and the second number NUM2 may not necessarily be identical and can have other appropriate values set by customers or users. In still an alternative embodiment, all the corresponding first plurality of (e.g., N=28) capacitive energy storage devices {CR(i), i=1, 2, . . . , 28} may be placed on the top surface or on the bottom surface of the multi-layer circuit board 1800.

In an embodiment, the corresponding first plurality of (e.g., N=28) capacitive energy storage devices {CR(i), i=1, 2, . . . , 28} may be electrically coupled to the corresponding first plurality of (e.g., N=28) electrically conductive connecting structures 184 so as to be coupled to the first plurality of (e.g., N=28) laser cells {101(i), i=1, 2, . . . , 28} of the integrated semiconductor laser device 101. That is, each one of the corresponding first plurality of (e.g., N=28) capacitive energy storage devices {CR(i), i=1, 2, . . . , 28} may be electrically coupled to a corresponding one electrically conductive connecting structure 184 among the corresponding first plurality of (e.g., N=28) electrically conductive connecting structures 184. For example, the first terminal of each one of the corresponding first plurality of (e.g., N=28) capacitive energy storage devices {CR(i), i=1, 2, . . . , 28} is electrically coupled to the corresponding one electrically conductive connecting structure 184. For the example shown in FIG. 18-FIG. 18F, the first terminal of each one capacitive energy storage device of the first portion of the corresponding first plurality of (e.g., N=28) capacitive energy storage devices {CR(i), i=1, 2, . . . , 28} may be connected to the connecting trace 1842 of a corresponding one electrically conductive connecting structure 184 within the top surface of the multi-layer circuit board 1800. That is, electrical connection between the first portion of the corresponding first plurality of (e.g., N=28) capacitive energy storage devices {CR(i), i=1, 2, . . . , 28} and the corresponding electrically conductive connecting structures 184 may be realized at the 1^{st} board layer 180(1) within the top surface of the multi-layer circuit board 1800. The first terminal of each one capacitive energy storage device of the second portion of the corresponding first plurality of (e.g., N=28) capacitive energy storage devices {CR(i), i=1, 2, . . . , 28} may be coupled to the connecting trace 1842 of a corresponding one electrically conductive connecting structure 184 through interlayer connecting vias 188 that are formed according to practical connection needs between every two adjacent board layers of the plurality of (e.g., H) board layers {180(h), h=1, 2, . . . , H} with H=6 in the example. That is, electrical connection between the second portion of the corresponding first plurality of (e.g., N=28) capacitive energy storage devices {CR(i), i=1, 2, . . . , 28} that are disposed at the bottom surface of the multi-layer circuit board 1800 and the corresponding electrically conductive connecting structures 184 that are disposed at the top surface of the multi-layer circuit board 1800 may be realized through interlayer connecting vias 188. Hereinafter, it should be understood that interlayer connecting vias 188 can be flexibly formed depending on electrical connections needing to be implemented between the board layers which could be easily understood by those of ordinary skill in the art and need not to be described or specified in more detail here. Each one of the interlayer connecting vias 188 is filled with electrically conductive materials. In the exemplary illustrative drawings of FIG. 18 to FIG. 18F, the interlayer connecting vias 188 formed between each one of the board layers {180(h), h=1, 2, . . . , H} and the one board layer that is disposed immediately above are represented by the small circles in the plan view of each board layer. And a slightly larger circle drawn to be conformal with each of the small circles represents an electrically conductive pad formed on each one of the board layers {180(h), h=1, 2, . . . , H} to receive a corresponding one interlayer connecting via 188.

In an embodiment, the discharging unit 106 may be mounted with its active surface down on the 1st board layer 180(1) at a predetermined discharging unit mounting area 189 on the top surface of the multi-layer circuit board 1800 as illustratively shown in FIG. 18A. The discharging unit 106 may be in the form of a packaged IC as described with reference to FIG. 9 or FIG. 10. Since the active surface having the plurality of terminals including the first input terminal (e.g., the energy input terminal) DRAIN, the reference ground terminal GND2, the second input terminal (e.g., the PWM terminal) PWM2 or the second positive input terminal PWM2+ and the second negative input terminal PWM2−, the third input terminal (e.g., the discharging unit power supply terminal) VCC, and the fault reporting terminal FLT2 (if any) of the discharging unit 106 is facing down to the top surface of the multi-layer circuit board 1800, the plurality of terminals on the active surface of the discharging unit 106 are illustrated in dash line shapes in the illustrative top plan view of FIG. 18A. The predetermined discharging unit mounting area 189 on the top surface of the multi-layer circuit board 1800 may be disposed as close as possible to the predetermined laser device mounting area 181, for instance, either at the first side (e.g., the upside in the example of FIG. 18-FIG. 18F indicated by the arrow 180U directed to the upside) of the predetermined laser device mounting area 181 or at the second side (e.g., the downside in the example of FIG. 18-FIG. 18F indicated by the arrow 180D directed to the downside) of the predetermined laser device mounting area 181. In an embodiment, the predetermined discharging unit mounting area 189 and the predetermined capacitive device mounting area 186 may be disposed at the same side (e.g., the first side in the example shown in FIG. 18-FIG. 18F) on the top surface of the multi-layer circuit board 1800. In this fashion, interconnection between the integrated semiconductor laser device 101, the corresponding first plurality of (e.g., N=28) capacitive energy storage devices {CR(i), i=1, 2, . . . , 28}, and the discharging unit 106 can be more easily implemented with a reduced interconnection resistance.

In an embodiment, the first input terminal DRAIN (the electrically conductive pad of the first input terminal DRAIN) of the discharging unit 106 can be electrically connected to the electrically conductive sheet 182 and thus to the second terminals of the first plurality of (e.g., N=28) laser cells {101(i), i=1, 2, . . . , 28} of the integrated semiconductor laser device 101 through for example an electrically conductive trace 190 (also illustrated in red in FIG. 18A). In an example, the discharging unit 106 can be placed in a symmetrical manner along a middle line 180M of the multi-layer circuit board 1800, that is, the discharging unit 106 is mounted so that a middle line of the discharging unit 106 may be substantially coincide with the middle line 180M of the multi-layer circuit board 1800. This would be beneficial to improving the performance of energy discharging from the integrated semiconductor laser device 101, e.g., from the second terminal of each one of the first plurality of (e.g., N=28) laser cells {101(i), i=1, 2, . . . , 28}, to the discharging unit 106 and then to the reference ground GND. The electrically conductive trace 190 runs from under the first input terminal DRAIN till reaches and connects with the electrically conductive sheet 182.

In an embodiment, the electrically conductive pads of the reference ground terminal GND2 of the discharging unit 106 can be electrically coupled to the second terminals of the corresponding first plurality of (e.g., N=28) capacitive energy storage devices {CR(i), i=1, 2, . . . , 28} by for example electrically conductive sheets 191 that are symmetrically arranged on both sides of the middle line 180M of the multi-layer circuit board 1800 at the top surface of the multi-layer circuit board 1800, referring to the illustration in FIG. 18A. The electrically conductive sheets 191 spreads and extends from under the electrically conductive pads of the reference ground terminal GND2 of the discharging unit 106 till under the second terminals of the corresponding first plurality of (e.g., N=28) capacitive energy storage devices {CR(i), i=1, 2, . . . , 28}. The electrically conductive sheets 191 are separated and electrically isolated from the electrically conductive trace 190. The electrically conductive sheets 191 are configured as the reference ground GND on the 1^{st} board layer 180(1) of the multi-layer circuit board 1800 and may be connected to the reference ground GND of the driving system 100 or 150. In an embodiment, the electrically conductive trace 190 may run substantially along the middle line 180M of the multi-layer circuit board 1800 and between the symmetrically arranged conductive sheets 191 from under the first input terminal DRAIN till reach and connect with the electrically conductive sheet 182.

Electrical connections of other terminals of the discharging unit 106 including the second input terminal (e.g., the PWM terminal) PWM2, the third input terminal (e.g., the discharging unit power supply terminal) VCC, and the fault reporting terminal FLT2 (if any) may be implemented with various printed circuit wiring schemes according to connection needs that should be obvious to one of ordinary skill in the art and need not to be described in more detail here.

In an embodiment, the charging unit 102 may be mounted with its active surface down on the 1st board layer 180(1) at a predetermined charging unit mounting area 192 on the top surface of the multi-layer circuit board 1800 as illustratively shown in FIG. 18A. The charging unit 108 may be in the form of a packaged IC as described with reference to FIG. 8 or FIG. 17. Since the active surface of the discharging unit 102 is facing down to the top surface of the multi-layer circuit board 1800, the terminals including the second plurality of (e.g., M=32 in this example) electrically conductive pads of the second plurality of (e.g., M=32) output terminals {OUT(j), j=1, 2, . . . , 32}, the first input terminal (e.g. the power supply terminal) IN1, the second input terminal (e.g. the enable terminal) EN, the third input terminal (e.g. the PWM terminal) PWM1, the reference ground terminal GND1, the fourth input terminal (e.g. the selection terminal) OS, the indication terminal (e.g. the fault indication terminal) FLT1, the switch terminal SW, the power output terminal BSTO, and the selection pins (if any, e.g., 5 selection pins SEL(0), SEL(1), . . . , SEL(4) are illustrated out in the example of FIG. 18-FIG. 18F) etc. that are formed on the active surface of the charging unit 102 are illustrated in dash line shapes in the illustrative top plan view of FIG. 18A. The predetermined charging unit mounting area 192 on the top surface of the multi-layer circuit board 1800 may be disposed as close as possible to the predetermined capacitive device mounting area 186, for instance, either at the first side (e.g., the upside in the example of FIG. 18-FIG. 18F indicated by the arrow 180U directed to the upside) of the predetermined laser device mounting area 181 or at the second side (e.g., the downside in the example of FIG. 18-FIG. 18F indicated by the arrow 180D directed to the downside) of the predetermined laser device mounting area 181. In an embodiment, the predetermined charging unit mounting area 192 and the predetermined capacitive device mounting area 186 may be disposed at the same side (e.g., the first side indicated by the arrow 180U in the example shown in FIG. 18-FIG. 18F) on the top surface of the multi-layer circuit board 1800. Yet, this is not intended to be limiting. In an alternative embodiment, the predetermined charging unit mounting area 192 may be disposed at the opposite side (e.g., the second side indicated by the arrow 180D in the example shown in FIG. 18-FIG. 18F) to the side (e.g., the first side indicated by the arrow 180U in the example shown in FIG. 18-FIG. 18F) where the predetermined capacitive device mounting area 186 is disposed. Accordingly, in an embodiment, the second power switch 105 and the inductive energy storage device L may be disposed and mounted on the top surface of the multi-layer circuit board 1800 close to the charging unit 102 in this embodiment so that it may be easier to form the power conversion apparatus.

In an embodiment, electrical couplings from the second plurality of (e.g., M=32) output terminals {OUT(j), j=1, 2, . . . , 32} to the first plurality of (e.g., N=28) laser cells {101(i), i=1, 2, . . . , 28} and the corresponding first plurality of (e.g., N=28) capacitive energy storage devices {CR(i), i=1, 2, . . . , 28} may be implemented through the intermediate board layers 180(2) to 180(H−1) that are sandwiched between the 1^{st} board layer 180(1) and the H^{th} board layer 180(H), H=6 in the exemplary drawings of FIG. 18-FIG. 18F. In the plan views of each of the intermediate board layers 180(2) to 180(H−1) respectively illustrated in FIG. 18B to FIG. 18F, the charging unit 102 is shown in dashed line to indicate that the charging unit 102 is not practically mounted on the respective intermediate board layer but just shown to help better understand the relative position and electrical couplings relationships described in the following.

Now referring to the illustration in FIG. 18B showing a plan view of a top side of the 2^{nd} board layer 180(2) which may also be considered as a top plan view inspected from a top surface of the 2^{nd} board layer 180(2) in this example, electrically conductive buses 193 are formed to connect a first set of the output terminals among the second plurality of (e.g., M=32 in this example) output terminals {OUT(j), j=1, 2, . . . , 32} to a corresponding first set of the laser cells among the first plurality of laser cells (e.g., N=28) laser cells {101(i), i=1, 2, . . . , 28} and a corresponding first set of the capacitive energy storage devices among the first plurality of (e.g., N=28) capacitive energy storage devices {CR(i), i=1, 2, . . . , 28}. In this example, the first set of the output terminals are illustrated to include the output terminals OUT(2) to OUT(8) that are selected to be respectively coupled to the first set of laser cells 101(1) to 101(7) and the first set of capacitive energy storage devices CR(1) to CR(7). Thus, the first set of the output terminals OUT(2) to OUT(8) are the reindexed selected output terminals OUT(1) to OUT(7) correspondingly coupled to the first set of laser cells 101(1) to 101(7) in this example. This can help to better understand the descriptions made with reference to FIG. 1 through FIG. 17 regarding how customers can randomly select or choose any first plurality of (e.g., N) output terminals among the second plurality of (e.g., M) output terminals {OUT(j), j=1, 2, . . . , M} to correspondingly drive the first plurality of (e.g., N) laser cells {101(i), i=1, 2, . . . , 28}. In an embodiment, an electrically conductive sheet 195 may be formed on the 2^{nd} board layer 180(2) for receiving and being connected to the interlayer connecting vias 188 that are used to connect the electrically conductive sheet 191 for the reference ground GND on the 1^{st} board layer 180(1).

Now referring to the illustration in FIG. 18C showing a plan view of a top side of the 3^{rd} board layer 180(3) which may also be considered as a top plan view inspected from a top surface of the 3^{rd} board layer 180(3) in this example, electrically conductive buses 195 are formed to connect a second set of the output terminals among the second plurality of (e.g., M=32 in this example) output terminals {OUT(j), j=1, 2, . . . , 32} to a corresponding second set of the laser cells among the first plurality of laser cells (e.g., N=28) laser cells {101(i), i=1, 2, . . . , 28} and a corresponding second set of the capacitive energy storage devices among the first plurality of (e.g., N=28) capacitive energy storage devices {CR(i), i=1, 2, . . . , 28}. In this example, the second set of the output terminals are illustrated to include the output terminals OUT(10) to OUT(16) that are selected to be respectively coupled to the second set of laser cells 101(8) to 101(14) and the second set of capacitive energy storage devices CR(8) to CR(14). Thus, the second set of the output terminals OUT(10) to OUT(16) are the reindexed selected output terminals OUT(8) to OUT(14) correspondingly coupled to the second set of laser cells 101(8) to 101(16) in this example. In an embodiment, an electrically conductive sheet 196 may be formed on the 3^{rd} board layer 180(3) for receiving and being connected to the interlayer connecting vias 188 that are used to connect the electrically conductive sheet 194 for the reference ground GND on the 2^{nd} board layer 180(2).

Now referring to the illustration in FIG. 18D showing a plan view of a top side of the 4^{th} board layer 180(4) which may also be considered as a top plan view inspected from a top surface of the 4^{th} board layer 180(4) in this example, electrically conductive buses 197 are formed to connect a third set of the output terminals among the second plurality of (e.g., M=32 in this example) output terminals {OUT(j), j=1, 2, . . . , 32} to a corresponding third set of the laser cells among the first plurality of laser cells (e.g., N=28) laser cells {101(i), i=1, 2, . . . , 28} and a corresponding third set of the capacitive energy storage devices among the first plurality of (e.g., N=28) capacitive energy storage devices {CR(i), i=1, 2, . . . , 28}. In this example, the third set of the output terminals are illustrated to include the output terminals OUT(18) to OUT(24) that are selected to be respectively coupled to the third set of laser cells 101(15) to 101(21) and the third set of capacitive energy storage devices CR(15) to CR(21). Thus, the third set of the output terminals OUT(18) to OUT(24) are the reindexed selected output terminals OUT(15) to OUT(21) correspondingly coupled to the third set of laser cells 101(15) to 101(21) in this example. In an embodiment, an electrically conductive sheet 198 may be formed on the 4^{th} board layer 180(4) for receiving and being connected to the interlayer connecting vias 188 that are used to connect the electrically conductive sheet 196 for the reference ground GND on the 3^{rd} board layer 180(3).

Now referring to the illustration in FIG. 18E showing a plan view of a top side of the 5^{th} board layer 180(5) which may also be considered as a top plan view inspected from a top surface of the 5^{th} board layer 180(5) in this example, electrically conductive buses 199 are formed to connect a fourth set of the output terminals among the second plurality of (e.g., M=32 in this example) output terminals {OUT(j), j=1, 2, . . . , 32} to a corresponding fourth set of the laser cells among the first plurality of laser cells (e.g., N=28) laser cells {101(i), i=1, 2, . . . , 28} and a corresponding fourth set of the capacitive energy storage devices among the first plurality of (e.g., N=28) capacitive energy storage devices {CR(i), i=1, 2, . . . , 28}. In this example, the fourth set of the output terminals are illustrated to include the output terminals OUT(26) to OUT(32) that are selected to be respectively coupled to the fourth set of laser cells 101(22) to 101(28) and the third set of capacitive energy storage devices CR(22) to CR(28). Thus, the fourth set of the output terminals OUT(26) to OUT(32) are the reindexed selected output terminals OUT(22) to OUT(28) correspondingly coupled to the fourth set of laser cells 101(22) to 101(28) in this example. In an embodiment, an electrically conductive sheet 1991 may be formed on the 5^{th} board layer 180(5) for receiving and being connected to the interlayer connecting vias 188 that are used to connect the electrically conductive sheet 198 for the reference ground GND on the 4^{th} board layer 180(4).

In this fashion, the charging unit 102 with the first plurality of (e.g., N=28) output terminals OUT(2) to OUT(8), OUT(10) to OUT(16), OUT(18) to OUT(24), and OUT(26) to OUT(32) among the second plurality of (e.g., M=32) output terminals {OUT(j), j=1, 2, . . . , 32} selected out to correspondingly drive the first plurality of (e.g., N=28) laser cells (e.g., N=28) laser cells {101(i), i=1, 2, . . . , 28} in the particular example shown in FIG. 18-FIG. 18F can be mounted on the multi-layer circuit board 1800 with electrical couplings from the first plurality of (e.g., N=28) selected output terminals to the first plurality of (e.g., N=28) laser cells {101(i), i=1, 2, . . . , 28} and the corresponding first plurality of (e.g., N=28) capacitive energy storage devices {CR(i), i=1, 2, . . . , 28} implemented through the intermediate board layers formed between the 1^{st} board layer 180(1) and the bottommost H^{th} board layer 180(H), H=6 in this example. Although the first plurality of (e.g., N=28) selected output terminals are divided in four sets in this example, it should be understood that in other embodiments, the first plurality of (e.g., N=28) selected output terminals may be divided in more or less sets and correspondingly more or less intermediate board layers may be formed to implement the electrical couplings from the first plurality of (e.g., N=28) selected output terminals to the first plurality of (e.g., N=28) laser cells {101(i), i=1, 2, . . . , 28} and the corresponding first plurality of (e.g., N=28) capacitive energy storage devices {CR(i), i=1, 2, . . . , 28}. One of ordinary skill in the art would understand that, in alternative embodiments, the number of intermediate board layers 180(2) to 180(H−1) and therefore the total number H of board layers 180(1) to 180(H) that are included in the multi-layer circuit board 1800 may depend on the number N of the first plurality of laser cells {101(i), i=1, 2, . . . , N} to be driven, the number of sets that the first plurality of selected output terminals reindexed with {OUT(i), i=1, 2, . . . , N} are divided in, and/or the number (e.g., X) of rows of the output terminal matrix 801 that the package wrapping the charging unit 102 has etc., as can be understood by those of ordinary skill in the art.

Electrical connections of other terminals of the charging unit 102 including the first input terminal (e.g. the power supply terminal) IN1, the second input terminal (e.g. the enable terminal) EN, the third input terminal (e.g. the PWM terminal) PWM1, the reference ground terminal GND1, the fourth input terminal (e.g. the selection terminal) OS, the indication terminal (e.g. the fault indication terminal) FLT1, the switch terminal SW, the power output terminal BSTO, and the selection pins (if any, e.g., 5 selection pins SEL(0), SEL(1), . . . , SEL(4) are illustrated out in the example of FIG. 18-FIG. 18F) etc. may be implemented with various printed circuit wiring schemes according to connection needs that should be obvious to one of ordinary skill in the art and need not to be described in more detail here.

Now referring to the illustration in FIG. 18F again, an electrically conductive sheet 1992 may be formed and used for the reference ground GND of the bottommost H^{th} board layer 180(H), H=6 in this example. The electrically conductive sheet 1992 may be electrically connected to the electrically conductive sheet 1991 for the reference ground GND on the 5^{th} board layer 180(5) which is disposed immediately above the bottommost 6^{th} board layer 180(6) in this example. The first terminal of each one capacitive energy storage device of the second portion (e.g., including the capacitive energy storage devices CR(15) to CR(28) in this example) of the corresponding first plurality of (e.g., N=28) capacitive energy storage devices {CR(i), i=1, 2, . . . , 28} may be connected to a connecting trace 1993 formed on the bottom surface of the multi-layer circuit board 1800 and then coupled to the connecting trace 1842 of a corresponding one electrically conductive connecting structure 184 on the top surface of the multi-layer circuit board 1800 through interlayer connecting vias 188 that are formed according to practical connection needs between every two adjacent board layers of the plurality of (e.g., H) board layers {180(h), h=1, 2, . . . , H} with H=6 in the example. The second terminal of each one capacitive energy storage device of the second portion (e.g., including the capacitive energy storage devices CR(15) to CR(28) in this example) of the corresponding first plurality of (e.g., N=28) capacitive energy storage devices {CR(i), i=1, 2, . . . , 28} may be connected to the electrically conductive sheet 1992 which connects the reference ground GND of the driving system 100 or 150.

In still an alternative embodiment, the charging unit 102 may be mounted with its active surface down on the bottommost H^{th} board layer 180(H), H=6 in the example shown in FIG. 18G-FIG. 18H. FIG. 18G illustrates a plan view of a top side of the 1^{st} board layer 180(1) which may also be considered as a top plan view inspected from a top surface of the 1^{st} board layer 180(1) in this alternative example. FIG. 18H illustrates a plan view of a bottom side of the multi-layer circuit board 1800 which may also be considered as a bottom plan view inspected from a bottom surface of the bottommost H^{th} board layer 180(H), H=6 in this alternative example. Those of ordinary skill in the art would understand that substantial descriptions made with reference to the example shown in FIG. 18 to FIG. 18F are applicable to the example shown in FIG. 18G-FIG. 18H. Difference may lie in one aspect that, the predetermined charging unit mounting area 192 may be disposed on the bottom surface of the multi-layer circuit board 1800 in this alternative embodiment. Accordingly, in an embodiment, the second power switch 105 and the inductive energy storage device L may be disposed and mounted on the bottom surface of the multi-layer circuit board 1800 close to the charging unit 102 in this alternative embodiment so that it may be easier to form the power conversion apparatus.

It is obvious to those of ordinary skill in the art that illustrations and descriptions of the intermediate board layers 180(2) to 180(5) that are formed between the 1^{st} board layer 180(1) and the bottommost H^{th} board layer 180(H)), H=6 in the alternative example shown in FIG. 18G-FIG. 18H may be analogous to those illustrated and described with reference to FIG. 18B to FIG. 18E except that positions of the electrically conductive buses (e.g., 193, 195, 197 and 199) need to be changed according to the position change in the predetermined charging unit mounting area 192 (and thus the position change in the charging unit 102) and may not need to be illustrated out and described in detail here.

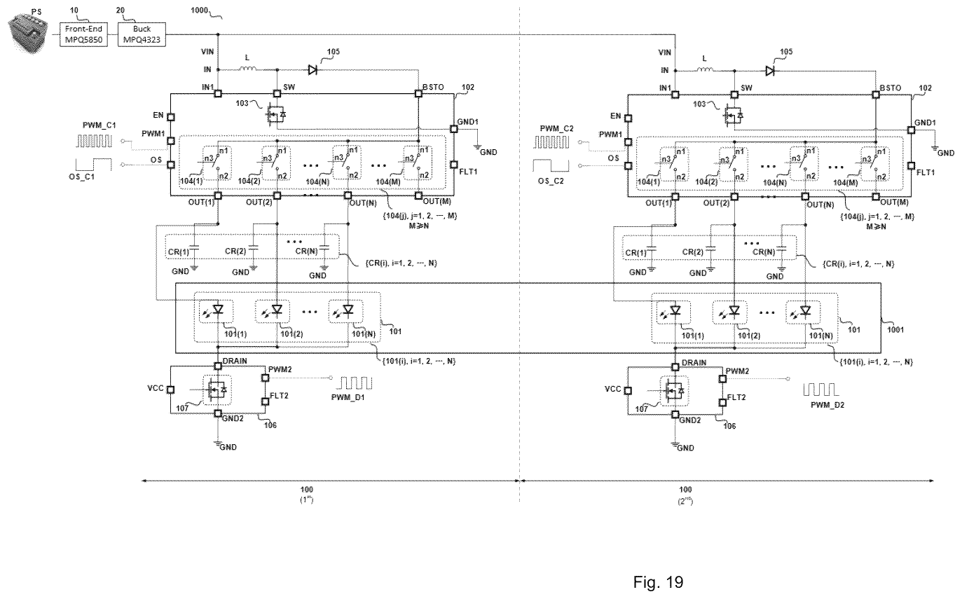

FIG. 19 illustrates a schematic diagram of a driving system 1000 in accordance with an embodiment of the present invention. The driving system 1000 may be considered as including two driving systems 100. The driving system 1000 may be adapted to be configured or used to drive an integrated semiconductor laser device 1001 which may include laser cells of a number (e.g., 2*N) that is twice of the number (e.g., N) of laser cells in the semiconductor laser device 101. The integrated semiconductor laser device 1001 may be deemed as including two semiconductor laser devices 101. In an embodiment, operation order of the two charging units 102, accordingly operation order of the two driving systems 100 in the driving system 1000 may be set via the fourth input terminal (e.g., chip-selection terminal) OS of each of the charging units 102 by customers or users. For instance, when the system 1000 is enabled for operation for example by the enable signal EN_C provided to the enable terminal EN of each of the charging units 102, the first charging unit 102 (e.g., the one at the left side in FIG. 19) may be programmed to be ON first, for example by a chip-selection signal OS_C1 provided to the chip-selection terminal OS of the first charging unit 102, to drive the first N laser cells in the integrated semiconductor laser device 1001. The second charging unit 102 (e.g., the one at the right side in FIG. 19) may be programmed to be ON after the first charging unit 102 is set to be OFF, for example by a chip-selection signal OS_C2 provided to the chip-selection terminal OS of the second charging unit 102, to drive the second N laser cells in the integrated semiconductor laser device 1001. The chip-selection signal OS_C1 and the chip-selection signal OS_C2 may have complimentary logic levels so that the first and the second charging units 102 are not ON at the same time, that is, when the chip-selection signal OS_C1 is at logic high, the chip-selection signal OS_C2 should be at logic low, and vice versa. One of ordinary skill would understand that operations of each of the first and second charging units 102 when being ON may follow the descriptions as addressed above with reference to FIG. 1 to FIG. 17 and there's no need to repeat those descriptions here. A charging control PWM signal PWM_C1 provided to the third input terminal (e.g., the PWM terminal) PWM1 of the first charging unit 102 and a charging control PWM signal PWM_C2 provided to the third input terminal (e.g., the PWM terminal) PWM1 of the second charging unit 102 may come from a same charging control PWM signal PWM_C or may be different. However, the charging control PWM signal PWM_C1 may function just as the charging control PWM signal PWM_C as addressed above with reference to FIG. 1 to FIG. 17 when the first charging unit 102 is ON, so does the charging control PWM signal PWM_C2 when the second charging unit 102 is ON, and there's no need to repeat those descriptions here. A discharging control PWM signal PWM_D1 provided to the second input terminal PWM2 of the first discharging unit 106 and a charging control PWM signal PWM_D2 provided to the second input terminal PWM2 of the second discharging unit 106 may come from a same discharging control PWM signal PWM_D or may be different. However, the discharging control PWM signal PWM_D1 may function just as the discharging control PWM signal PWM_D as addressed above with reference to FIG. 1 to FIG. 18 when the first charging unit 102 (accordingly the first driving system 100) is ON, so does the discharging control PWM signal PWM_D2 when the second charging unit 102 (accordingly the second driving system 100) is ON, and there's no need to repeat those descriptions here.

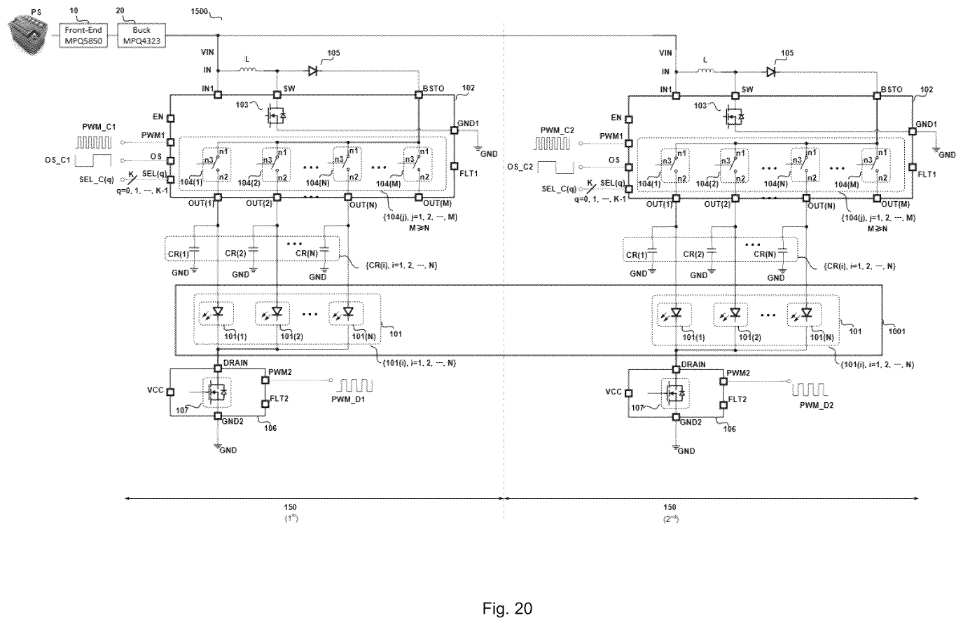

FIG. 20 illustrates a schematic diagram of a driving system 1500 in accordance with an embodiment of the present invention. The driving system 1500 may be considered as including two driving systems 150. The driving system 1500 may be adapted to be configured or used to drive an integrated semiconductor laser device 1001 which may include laser cells of a number (e.g., 2*N) that is twice of the number (e.g., N) of laser cells in the semiconductor laser device 101. The integrated semiconductor laser device 1001 may be deemed as include two semiconductor laser devices 101. In an embodiment, operation order of the two charging units 102, accordingly operation order of the two driving systems 150 in the driving system 1500 may be set via the fourth input terminal (e.g., chip-selection terminal) OS of each of the charging units 102 by customers or users similarly as described above with reference to the exemplary embodiment shown in FIG. 19. For instance, when the system 1500 is enabled for operation for example by the enable signal EN_C provided to the enable terminal EN of each of the charging units 102, the first charging unit 102 (e.g., the one at the left side in FIG. 20) may be programmed to be ON first, for example by the chip-selection signal OS_C1 provided to the chip-selection terminal OS of the first charging unit 102, to drive the first N laser cells in the integrated semiconductor laser device 1001 of the driving system 1500. The second charging unit 102 (e.g., the one at the right side in FIG. 20) may be programmed to be ON after the first charging unit 102 is set to be OFF, for example by the chip-selection signal OS_C2 provided to the chip-selection terminal OS of the second charging unit 102, to drive the second N laser cells in the integrated semiconductor laser device 1001 of the driving system 1500. The chip-selection signal OS_C1 and the chip-selection signal OS_C2 may have complimentary logic levels. One of ordinary skill would understand that operations of each of the first and second charging units 102 when being ON may follow the descriptions as addressed above with reference to FIG. 11 to FIG. 18 and there's no need to repeat those descriptions here. A charging control PWM signal PWM_C1 provided to the third input terminal (e.g., the PWM terminal) PWM1 of the first charging unit 102 and a charging control PWM signal PWM_C2 provided to the third input terminal (e.g., the PWM terminal) PWM1 of the second charging unit 102 may come from a same charging control PWM signal PWM_C or may be different. However, the charging control PWM signal PWM_C1 may function just as the charging control PWM signal PWM_C as addressed above with reference to FIG. 11 to FIG. 17 when the first charging unit 102 (accordingly the first driving system 150) is ON, so does the charging control PWM signal PWM_C2 when the second charging unit 102 (accordingly the second driving system 150) is ON, and there's no need to repeat those descriptions here. A discharging control PWM signal PWM_D1 provided to the second input terminal PWM2 of the first discharging unit 106 and a charging control PWM signal PWM_D2 provided to the second input terminal PWM2 of the second discharging unit 106 may come from a same discharging control PWM signal PWM_D or may be different. However, the discharging control PWM signal PWM_D1 may function just as the discharging control PWM signal PWM_D as addressed above with reference to FIG. 11 to FIG. 17 when the first charging unit 102 (accordingly the first driving system 150) is ON, so does the discharging control PWM signal PWM_D2 when the second charging unit 102 (accordingly the second driving system 150) is ON, and there's no need to repeat those descriptions here.

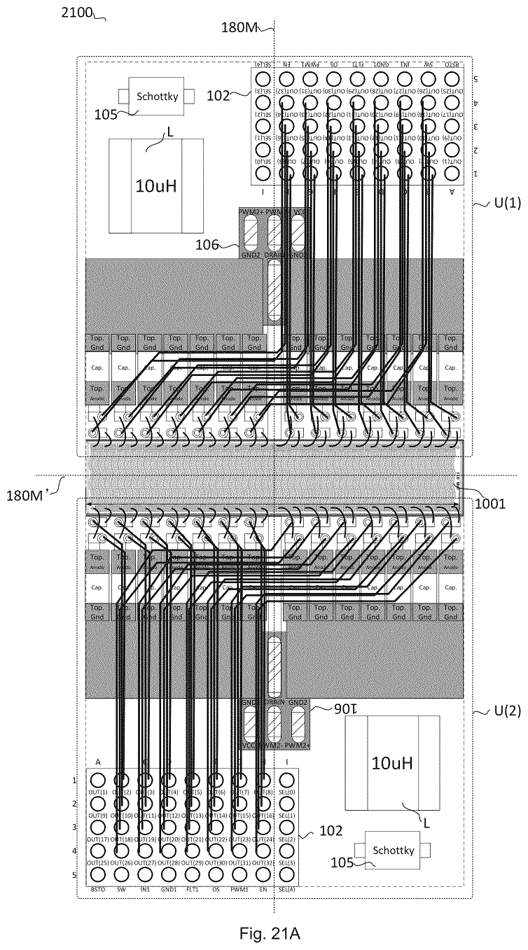

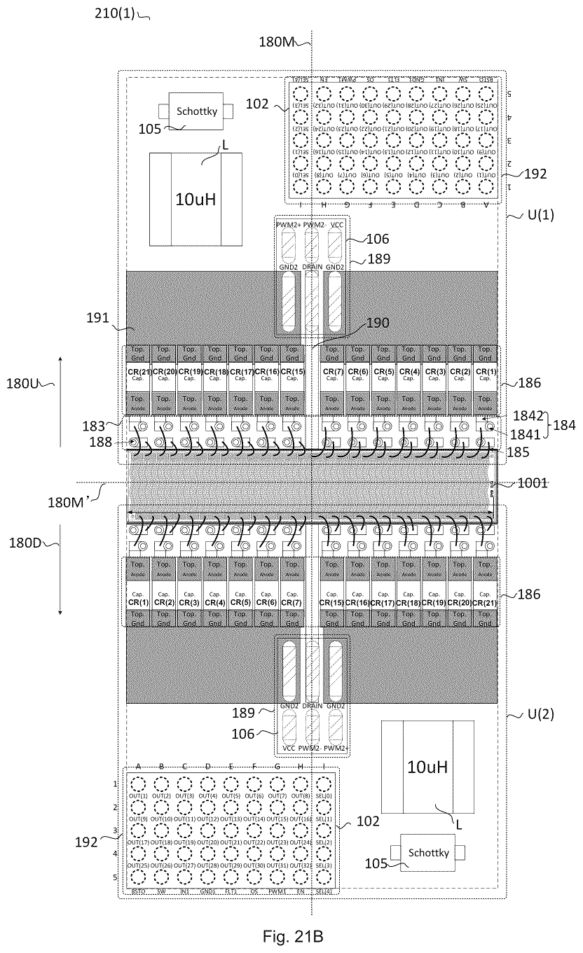

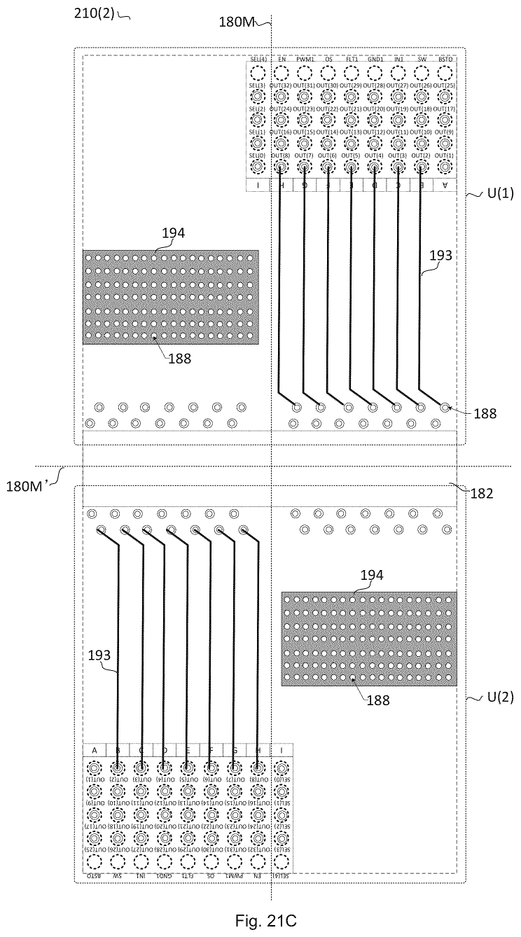

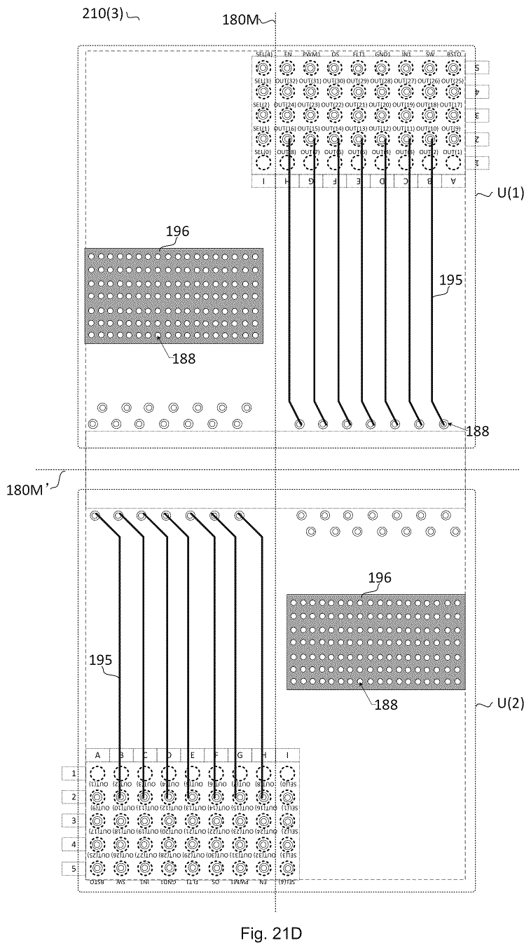

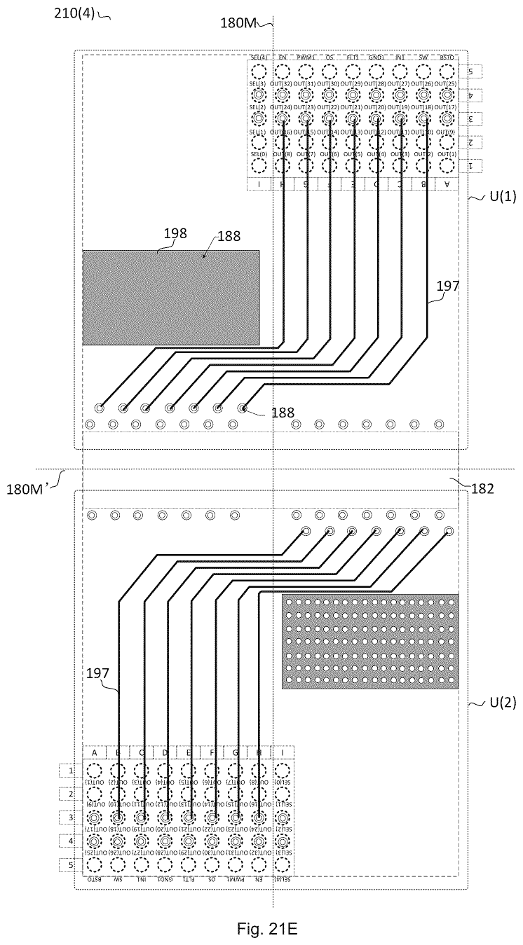

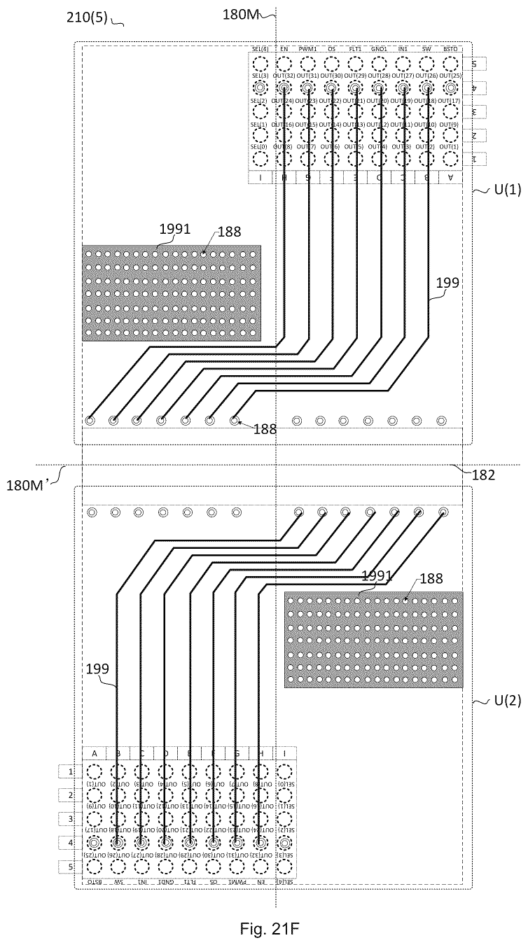

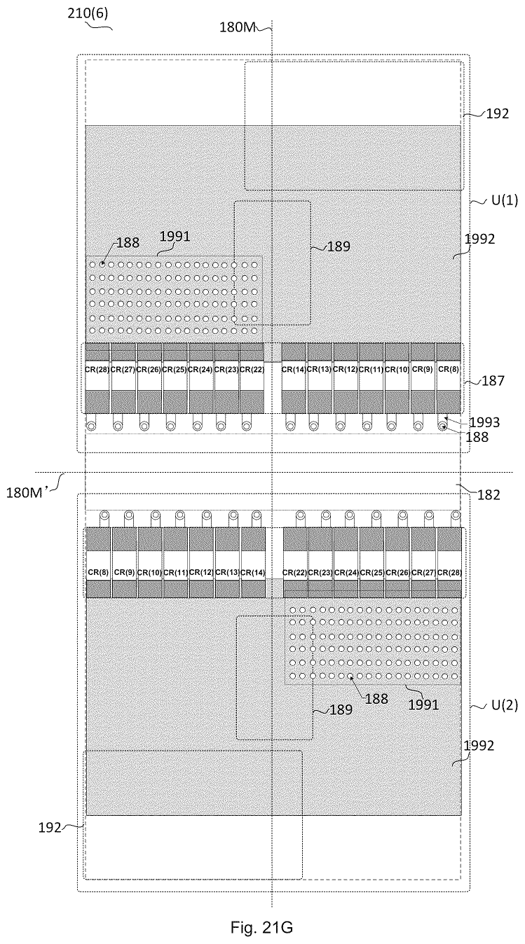

FIG. 21A illustrates an application board level layout diagram corresponding to the driving system 1000 of FIG. 19 or the driving system 1500 of FIG. 20 in accordance with an exemplary embodiment of the present invention.

FIG. 21B to FIG. 21G illustrate layer by layer application board level layout diagrams corresponding to the driving system 1000 of FIG. 19 or the driving system 1500 of FIG. 20 in accordance with an exemplary embodiment of the present invention.

In an embodiment, the driving system 1000 or 1500 is implemented and mounted on a multi-layer circuit board such as a printed circuit board (PCB) 2100. Descriptions to the multi-layer circuit board 2100 for the driving system 1000 or 1500 will now be made with reference to FIG. 21A to FIG. 21G. The multi-layer circuit board 2100 may include a plurality of (e.g., represented by an integer variable H) board layers 210(1), 210(2), . . . , 210(H). Herein after, the plurality of (e.g., H) board layers 210(1), 210(2), . . . , 210(H) may be referred to as or represented by {210(h), h=1, 2, . . . , H}. Herein H is an integer variable no less than 1 and represents the total number of board layers 210(1), 210(2), . . . , 210(H) that the multi-layer circuit board 2100 may include, which may be set or determined by customers/users in practical applications depending on real application requirements. That is to say, the index h is a variable traverses the integers from 1 to H. In an embodiment, the plurality of (e.g., H) board layers {210(h), h=1, 2, . . . , H} may be disposed one on top of another following the order from 210(1) to 210(H). That is, the 1^{st} board layer 210(1) can be the topmost layer of the multi-layer circuit board 2100 while the H^{th} board layer 210(H) can be the bottommost layer of the multi-layer circuit board 2100, and the remained board layers 210(2) to 210(H−1) if any may be intermediate board layers sandwiched between the 1^{st} board layer 210(1) and the H^{th} board layer 210(H). For each h from 1 to (H−1), the h^{th} board layer 210(h) is disposed on top of the (h+1)^{th} board layer 210(h+1). In the example illustrated in FIG. 21A to FIG. 21G, the multi-layer circuit board 2100 is illustrated to include six board layers {210(h), h=1, 2, . . . , 6}, that is to say, H=6 in this example and a plan view of each one of the six board layers {210(h), h=1, 2, . . . , 6} are respectively illustrated in FIG. 21B to FIG. 21G. However, this is just to provide an example and not intended to be limiting.

In an embodiment, referring to the top plan view illustration of FIG. 21B, the integrated semiconductor laser device 1001 may be disposed and mounted on the 1^{st} board layer 210(1) of the multi-layer circuit board 2100 at a predetermined laser device mounting area 181 on a top surface of the 1^{st} board layer 210(1). It can be understood that the top surface of the 1^{st} board layer 210(1) can be alternatively referred to as a top surface of the multi-layer circuit board 2100. As already described with reference to FIG. 19 and FIG. 20 that the integrated semiconductor laser device 1001 may be deemed as including two semiconductor laser devices 101, the integrated semiconductor laser device 1001 is illustrated to have twice of the number of the first plurality of (e.g., N=28) laser cells {101(i), i=1, 2, . . . , 28} included in the semiconductor laser device 101, for example 2*N=56 laser cells 2*{101(i), i=1, 2, . . . , 28} as an example here, compared to the example shown in FIG. 18-FIG. 18H. The predetermined laser device mounting area for receiving the integrated semiconductor laser device 1001 on the top surface of the 1^{st} board layer 210(1) is still labeled with 181 for ease of description.

Those of ordinary skill in the art would easily understand that the board level layout diagrams corresponding to the driving system 1000 of FIG. 19 or the driving system 1500 of FIG. 20 implemented on the multi-layer circuit board 2100 as illustratively shown in FIG. 21A to FIG. 21G may be considered as modified from the board level layout diagrams corresponding to the driving system 100 of FIG. 1 or the driving system 150 of FIG. 11 implemented on the multi-layer circuit board 1800 as illustratively shown in FIG. 18 to FIG. 18H, for example, by including two of the layouts (including the layer by layer layouts and electrical couplings) of the driving system 100 of FIG. 1 or the driving system 150 of FIG. 11 implemented on the multi-layer circuit board 1800, except that the integrated laser device 101 mounted at the predetermined laser device mounting area 181 is replaced by the integrated semiconductor laser device 1001. Hereinafter, for ease of description and understanding, the board level layouts (including the layer-by-layer layouts and electrical couplings implemented within each board layer and between every two board layers) of the driving system 100 of FIG. 1 or the driving system 150 of FIG. 11 implemented on the multi-layer circuit board 1800 may be referred to as an N-laser-cell driving system layout unit. That is, the board level layouts implemented in the multi-layer circuit board 2100 may be considered to include two such N-laser-cell driving system layout units, respectively referred to as a first N-laser-cell driving system layout unit U(1) and a second N-laser-cell driving system layout unit U(2) here. Each one of the two N-laser-cell driving system layout units may be flexibly arranged within the multi-layer circuit board 2100 according to practical design considerations. The first N-laser-cell driving system layout unit U(1) is at least configured to implement mounting and electrical couplings of the first charging unit 102 and the first discharging unit 106 to co-work with the first N capacitive energy storage devices {CR(i), i=1, 2, . . . , N} in the driving system 1000 or 1500 to drive the first N laser cells {101(i), i=1, 2, . . . , N} of the integrated semiconductor laser device 1001. The second N-laser-cell driving system layout unit U(2) is at least configured to implement mounting and electrical couplings of the second charging unit 102 and the second discharging unit 106 to co-work with the second N capacitive energy storage devices {CR(i), i=1, 2, . . . , N} in the driving system 1000 or 1500 to drive the second N laser cells {101(i), i=1, 2, . . . , N} of the integrated semiconductor laser device 1001, N=28 in the example shown in FIG. 21A to FIG. 21G.

For instance, as illustratively shown in FIG. 21A to FIG. 21G, the first N-laser-cell driving system layout unit U(1) and the second N-laser-cell driving system layout unit U(2) are disposed respectively on the first side 180U and the second side 180D of the predetermined laser device mounting area 181 for receiving and mounting the integrated semiconductor laser device 1001 which can be deemed as including two semiconductor laser devices 101 in this example. One of ordinary skill in the art would understand that the descriptions made with reference to FIG. 18A to FIG. 18H are substantially applicable to each of the first N-laser-cell driving system layout unit U(1) and the second N-laser-cell driving system layout unit U(2) and thus will not need to be repeated here.

In the example shown in FIG. 21A to FIG. 21G, each of the first N-laser-cell driving system layout unit U(1) and the second N-laser-cell driving system layout unit U(2) is illustrated as a duplicate of the layouts shown in FIG. 18 to FIG. 18F, and the second N-laser-cell driving system layout unit U(2) is arranged so that it coincides with the first N-laser-cell driving system layout unit U(1) when being rotated by 180° with reference to the middle line 180M of the multi-layer circuit board 2100. In an alternative embodiment, the first N-laser-cell driving system layout unit U(1) and the second N-laser-cell driving system layout unit U(2) may be disposed and arranged symmetrically with reference to another middle line 180M′ that is perpendicular to the middle line 180M of the multi-layer circuit board 2100. In still an alternative embodiment, each of the first N-laser-cell driving system layout unit U(1) and the second N-laser-cell driving system layout unit U(2) may not be an exact duplicate of the layouts shown in FIG. 18 to FIG. 18F. For example, in an embodiment, the first discharging unit 106 and the corresponding first N capacitive energy storage devices {CR(i), i=1, 2, . . . , N} in the first N-laser-cell driving system layout unit U(1) and the second discharging unit 106 and the corresponding second N capacitive energy storage devices {CR(i), i=1, 2, . . . , N} in the second N-laser-cell driving system layout unit U(2) may be disposed and arranged symmetrically with reference to the another middle line 180M′ of the multi-layer circuit board 2100, while the first charging unit 102 in the first N-laser-cell driving system layout unit U(1) and the second charging unit 102 in the second N-laser-cell driving system layout unit U(2) may not be necessarily arranged symmetrically with reference to the another middle line 180M′ of the multi-layer circuit board 2100.

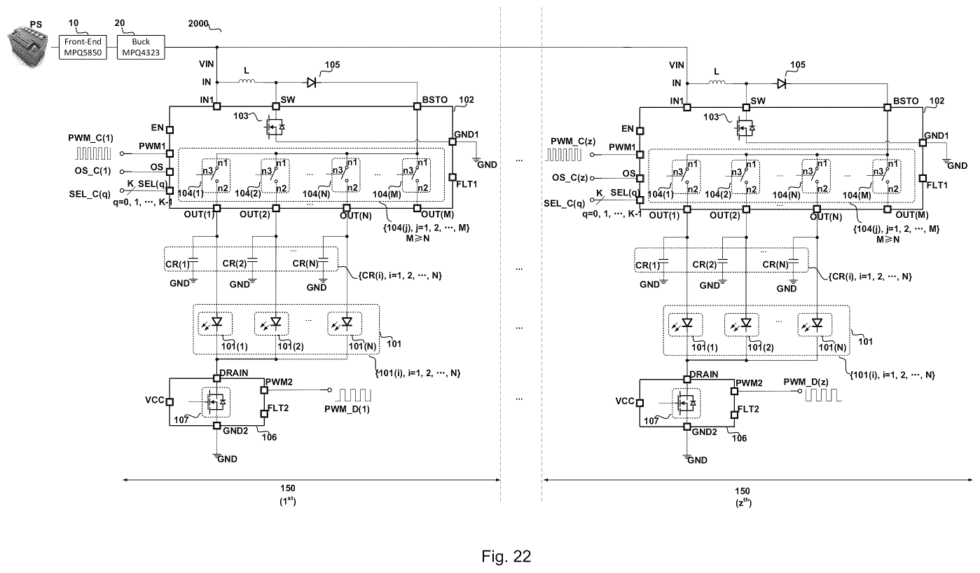

FIG. 22 illustrates a schematic diagram of a driving system 2000 in accordance with an embodiment of the present invention. The driving system 2000 may be considered as including a plurality of (e.g., z) driving systems 150 (or 100). Although the example of FIG. 22 illustrates z driving systems 150, one of ordinary skill in the art would understand that in an alternative embodiment, the driving system 2000 may include z driving systems 100 and substantial descriptions here apply to the case of including z driving systems 100. Herein z is an integer variable no less than 1 and represents the total number of driving systems 150 (or 100) that the driving system 2000 may include, which may be set or determined by customers/users in practical applications depending on real application requirements. The driving system 2000 may be adapted to be configured or used to drive integrated semiconductor laser device(s) which may include laser cells of a number (e.g., z*N) that is z times of the number (e.g., N) of laser cells in the semiconductor laser device 101. Thus, it may be deemed that the driving system 2000 is adapted to be configured to drive a plurality of (e.g., z) semiconductor laser devices 101. In an embodiment, operation order of the plurality of (e.g., z) charging units 102, accordingly operation order of the plurality of (e.g., z) driving systems 150 (or 100) in the driving system 2000 may be set via the fourth input terminal (e.g., chip-selection terminal) OS of each of the charging units 102 by customers or users. For instance, when the system 2000 is enabled for operation for example by the enable signal EN_C provided to the enable terminal EN of each of the charging units 102, the z charging units 102 (accordingly the z driving systems 150 or 100) may be programmed to be ON one by one, for example by setting the chip-selection signal (e.g., labeled with OS_C(r)) provided to the chip-selection terminal OS of the one charging unit 102 (e.g., the r^{th} charging unit 102 among the z charging units 102) to be ON at logic high while setting the chip-selection signals provided to the chip-selection terminals OS of the rest of the charging units 102 to be OFF at logic low. The index r is a variable traverses the integers from 1 to z. One of ordinary skill would understand that operations of each of the z charging units 102 when being ON may follow the descriptions as addressed above with reference to FIG. 1 to FIG. 17 and there's no need to repeat those descriptions here. For each r varying from 1 to z, a charging control PWM signal PWM_C(r) provided to the third input terminal (e.g., the PWM terminal) PWM1 of the r^{th} charging unit 102 come from a same charging control PWM signal PWM_C or may be different. However, the charging control PWM signal PWM_C(r) may function just as the charging control PWM signal PWM_C as addressed above with reference to FIG. 1 to FIG. 17 when the r^{th} charging unit 102 (accordingly the r^{th} driving system 150 or 100) is ON, and there's no need to repeat those descriptions here. For each r varying from 1 to z, a discharging control PWM signal PWM_D(r) provided to the second input terminal PWM2 of the r^{th} discharging unit 106 may come from a same discharging control PWM signal PWM_D or may be different. However, the discharging PWM signal PWM_D(r) may function just as the discharging control PWM signal PWM_D as addressed above with reference to FIG. 1 to FIG. 17 when the r^{th} charging unit 102 (accordingly the r^{th} driving system 150 or 100) is ON, and there's no need to repeat those descriptions here.

One of ordinary skill in the art would understand that the driving system 2000 may be implemented and mounted on a multi-layer circuit board such as a printed circuit board (PCB) in an analogous manner that the driving system 100 or 150 is implemented and mounted on the multi-layer circuit board 1800 and that the driving system 1000 or 1500 is implemented and mounted on the multi-layer circuit board 2100 as described above. The multi-layer circuit board for implementing the driving system 2000 may be considered as to include a plurality of (e.g., z) N-laser-cell driving system layout units.

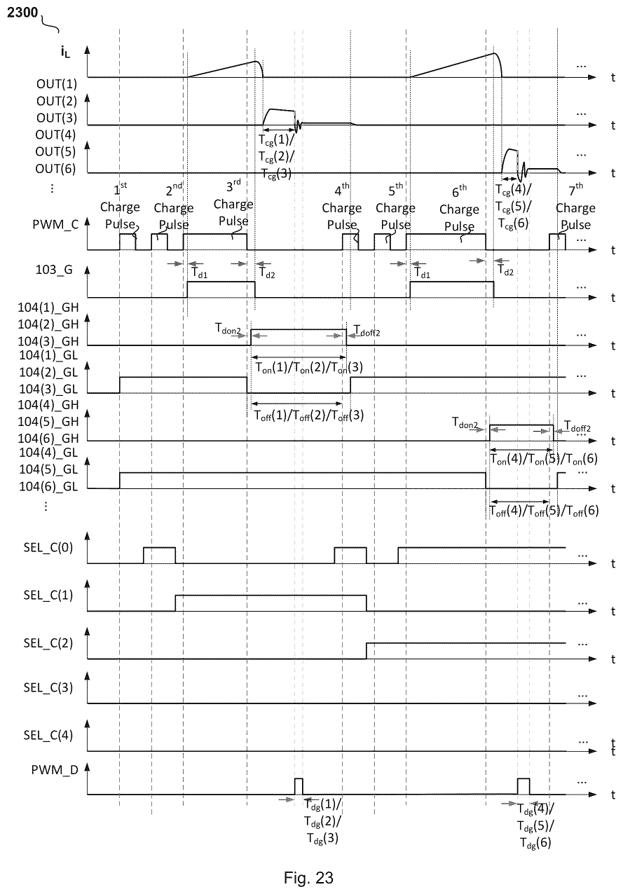

FIG. 23 shows an illustrative waveform diagram 2300 illustrating operation waveforms of several signals of the driving system 150 of FIG. 11 when operated in a parallel output mode in accordance with an exemplary embodiment of the present invention. In the parallel output mode, a group of every T output terminals among the second plurality of (e.g., M) output terminals {OUT(j), j=1, 2, . . . , M} may be programmed to be switched ON simultaneously in parallel each time, for instance at every T operation cycles or at every T charge pulses of the charging control PWM signal PWM_C. The variable T is an integer variable no less than 1 and no greater than M, and represents the total number of output terminals that would be programmed to be switched ON simultaneously in parallel each time. In the example of FIG. 23, it is illustrated that a group of every three output terminals among the second plurality of (e.g., M) output terminals {OUT(j), j=1, 2, . . . , M} may be programmed to be switched ON simultaneously in parallel each time, for instance at every three operation cycles or at every three charge pulses of the charging control PWM signal PWM_C, i.e., M=3 in this example. However, this is not intended to be limiting, one of ordinary skill in the art would understand that the variable T can be set to other values such as four or five etc. depending on practical application needs.

To help understand the parallel output mode, descriptions will be made with reference to the exemplary illustration in FIG. 23 with T=3. In the parallel output mode, at the beginning of each charge pulse of the charging control PWM signal PWM_C, the charging unit 102 may check logic status of the plurality of (e.g., K) selection control signals {SEL_C(q), q=0, 1, . . . , K−1} and determine according to the equation (1) which of the second plurality of (e.g., M) output terminals {OUT(j), j=1, 2, . . . , M} or which of the second plurality of (e.g., M) charging path control circuits {104(j), j=1, 2, . . . , M} would be programmed to be in the current group of T (e.g., T=3) output terminals to be switched ON simultaneously in parallel. That is, at the beginning of each charge pulse of the charging control PWM signal PWM_C, the s^{th} output terminal OUT(s) or the s^{th} charging path control circuits 104(s) according to the equation (1) would be programmed to be in the current group of T (e.g., T=3) output terminals to be switched ON simultaneously in parallel and would be recorded. When all the current group of T (e.g., T=3) output terminals are recorded, the recorded current group of T (e.g., T=3) output terminals may be switched ON simultaneously in parallel based on the every T^{th} (e.g., the every 3^{rd}, that is the first 3^{rd} the second 3^{rd} which is the 6^{th}, the third 3^{rd} which is the 9^{th} and so on) charge pulse of the charging control PWM signal PWM_C in an analogous manner as described with reference to the examples of FIG. 12 to FIG. 16 for controlling the programmed s^{th} output terminal OUT(s) and the s^{th} charging path control circuit 104(s), which can be apparently and easily understood in conjunction with the illustration in FIG. 23 by those of ordinary skill in the art and need not to be repeated again here in detail.

It can be seen from FIG. 23 that, at the 1^{st} charge pulse of the charging control PWM signal PWM_C, the selection control signals {SEL_C(0), SEL_C(1), SEL_C(2), SEL_C (3), SEL_C (4)}respectively provided to the selection terminals {SEL(0), SEL(1), SEL(2), SEL(3), SEL(4)}respectively have the logic status {0, 0, 0, 0, 0}, which means that s=1+0*2⁰+0*2¹+0*2²+0*2³+0*2⁴=1. Therefore, in this example, the 1^{st} output terminal OUT(1) is programmed to be in the current group of T (e.g., T=3) output terminals to be switched ON simultaneously in parallel and recorded at the 1^{st} charge pulse. At the 2^{nd} charge pulse of the charging control PWM signal PWM_C, the selection control signals {SEL_C(0), SEL_C(1), SEL_C(2), SEL_C (3), SEL_C (4)} respectively provided to the selection terminals {SEL(0), SEL(1), SEL(2), SEL(3), SEL(4)} respectively have the logic status {1, 0, 0, 0, 0}, which means that s=1+1*2⁰+0*2¹+0*2²+0*2³+0*2⁴=2. Therefore, in this example, the 2^{nd} output terminal OUT(2) is programmed to be in the current group of T (e.g., T=3) output terminals to be switched ON simultaneously in parallel and recorded at the 2^{nd} charge pulse. At the 3^{rd} charge pulse of the charging control PWM signal PWM_C, the selection control signals {SEL_C(0), SEL_C(1), SEL_C(2), SEL_C (3), SEL_C (4)} respectively provided to the selection terminals {SEL(0), SEL(1), SEL(2), SEL(3), SEL(4)} respectively have the logic status {0, 1, 0, 0, 0}, which means that s=1+0*2⁰+1*2¹+0*2²+0*2³+0*2⁴=3. Therefore, in this example, the 3^{rd} output terminal OUT(3) is programmed to be in the current group of T (e.g., T=3) output terminals to be switched ON simultaneously in parallel and recorded at the 3^{rd} charge pulse.

And at the 3^{rd} charge pulse of the charging control PWM signal PWM_C, all the current group of T (e.g., T=3) programmed output terminals OUT(1), OUT(2) and OUT(3) are recorded and thus are turned ON simultaneously in parallel during the charging time window T_{cg}(1)/T_{cg}(2)/T_{cg}(3) following the 3^{rd} charge pulse. It should be understood that, for this situation, the charging time window T_{cg}(1) of the associated output terminal OUT(1), the charging time window T_{cg}(2) of the associated output terminal OUT(2) and the charging time window T_{cg}(3) of the associated output terminal OUT(3) are identical and coincide with each other. Then following the end of the charging time window T_{cg}(1)/T_{cg}(2)/T_{cg}(3), the discharging unit 106 may be configured to sink or discharge energy from the output terminals OUT(1), OUT(2) and OUT(3) of the integrated semiconductor laser device 101 simultaneously in parallel to the reference ground GND during the discharging time window T_{dg}(1)/T_{dg}(2)/T_{dg}(3).

Similarly, at the next three charge pulses, that is the 4^{th} charge pulse, the 5^{th} charge pulse and the 6^{th} charge pulse of the charging control PWM signal PWM_C, according to the selection control signals {SEL_C(0), SEL_C(1), SEL_C(2), SEL_C (3), SEL_C (4)}, the 4^{th} output terminal OUT(4), the 5^{th} output terminal OUT(5) and the 6^{th} output terminal OUT(6) are respectively programmed and recorded to be in the next group of T (e.g., T=3) output terminals to be switched ON simultaneously in parallel. Therefore, in this example, at the 6^{th} charge pulse of the charging control PWM signal PWM_C, all the next group of T (e.g., T=3) programmed output terminals OUT(4), OUT(5) and OUT(6) are recorded and thus are turned ON simultaneously in parallel during the charging time window T_{cg}(4)/T_{cg}(5)/T_{cg}(6) following the 6^{th} charge pulse. It should be understood that, for this situation, the charging time window T_{cg}(4) of the associated output terminal OUT(4), the charging time window T_{cg}(5) of the associated output terminal OUT(5) and the charging time window T_{cg}(6) of the associated output terminal OUT(6) are identical and coincide with each other. Then following the end of the charging time window T_{cg}(4)/T_{cg}(5)/T_{cg}(6), the discharging unit 106 may be configured to sink or discharge energy from the output terminals OUT(4), OUT(5) and OUT(6) of the integrated semiconductor laser device 101 simultaneously in parallel to the reference ground GND during the discharging time window T_{dg}(4)/T_{dg}(5)/T_{dg}(6). Analogous descriptions are applicable to the rest of every group of T (e.g., T=3) programmed output terminals to be switched ON simultaneously in parallel and to be discharged simultaneously in parallel.

The advantages of the various embodiments of the present invention are not confined to those described above. These and other advantages of the various embodiments of the present invention will become more apparent upon reading the whole detailed descriptions and studying the various figures of the drawings.

From the foregoing, it will be appreciated that specific embodiments of the present invention have been described herein for purposes of illustration, but that various modifications may be made without deviating from the technology. Many of the elements of one embodiment may be combined with other embodiments in addition to or in lieu of the elements of the other embodiments. Accordingly, the present invention is not limited except as by the appended claims.

What is claimed is:

1. A charging unit adapted to be used for driving an integrated semiconductor laser device, comprising:
a first input terminal, adapted to receive an input driving energy;
a second input terminal, adapted to be configured to enable operation or disable operation of the charging unit;
a third input terminal, adapted to be configured to receive a charging control PWM signal; and
a second plurality of output terminals;
the charging unit is adapted to be configured to switch ON or switch OFF the second plurality of output terminals based on the charging control PWM signal PWM_C in a predetermined pattern.
